(19) United States
(12) Patent Application Publication
(10) Pub. No.: US 2011/0241908 A1
(43) Pub. Date: Oct. 6, 2011

(54) System and method for processing sensory effect

(75) Inventors: Seung Ju Han, Seoul (KR); Jae Joon Han, Seoul (KR); Won Chul Bang, Seongnam-si (KR); Do Kyoon Kim, Seongnam-si (KR)

(73) Assignee: SAMSUNG ELECTRONICS CO., LTD., Suwon-si (KR)

(21) Appl. No.: 13/064,592

(22) Filed: Apr. 1, 2011

(30) Foreign Application Priority Data
Apr. 2, 2010 (KR) 10-2010-0030569
Apr. 12, 2010 (KR) 10-2010-0033300

(51) Int. Cl. H03K 17/94

(52) U.S. Cl. 341/20

(57) ABSTRACT

A sensory effect processing system and method are disclosed. Sensory effects contained in contents may be embodied in a real world, by generating command information for controlling a sensory device based on sensory effect information and sensory device capability information. In addition, data transmission rate may be increased by encoding metadata into binary metadata, encoding metadata into extensible mark-up language (XML) metadata, or encoding metadata into XML metadata and further encoding the XML metadata into binary metadata. Also, a bandwidth may be reduced.

### CROSS-REFERENCE TO RELATED APPLICATIONS

This application claims the priority benefit of Korean Patent Application Nos. 10-2010-0030569 and 10-2010-0033300, filed on Apr. 2, 2010 and Apr. 12, 2010 respectively, with the Korean Intellectual Property Office, the disclosures of which are incorporated herein by reference.

### BACKGROUND

1. Field

Embodiments of the following description relate to a system and method for processing sensory effects, and more particularly, to a system and method for quickly processing sensory effects contained in contents.

2. Description of the Related Art

Recently, beyond simply displaying content information, content reproducing devices also supply various effects to users, and supply the content information by using an actuator. For example, a 4-dimensional (4D) movie theater, which is trendy these days, displays a film image and also supplies various effects such as a vibration effect of a theater seat, a windy effect, a water splash effect, and the like, corresponding to contents of the film. Therefore, users may enjoy the contents in a more immersive manner.

Thus, the content reproducing device and a content driving device that provide a sensory effect to users are being applied to various areas of life. For example, a game machine having a vibration joystick, a smell emitting TV, and the like are being studied and placed on the market.

However, research into a device and method for controlling efficient implementation of effect information contained in contents has been lacking. Therefore, the effect information cannot be efficiently implemented in the real world.

Accordingly, there is a desire for a device and method for controlling an operation to implement the effect information with an actuator of the real world.

### SUMMARY

In accordance with aspects of one or more embodiments, there is provided a device for controlling sensory effects, including a decoding unit to decode sensory effect metadata (SEM) and sensory device capability (SDCap) metadata using at least one processor, a generation unit to generate command information which controls a sensory device based on the decoded SEM and the decoded SDCap metadata, and an encoding unit to encode the command information into sensory device command (SDCmd) metadata.

In accordance with aspects of one or more embodiments, there is provided a sensory device including a decoding unit to decode SDCmd metadata containing at least one sensory effect information, and a drive unit to execute an effect event corresponding to the at least one sensory effect information.

In accordance with aspects of one or more embodiments, there is provided a method which controls sensory effects, including decoding SEM and SDCap metadata, generating command information which controls a sensory device based on the decoded SEM and the decoded SDCap metadata, and encoding the command information into SDCmd metadata.

In accordance with aspects of one or more embodiments, there is provided a method for operating a sensory device, including decoding SDCmd metadata containing at least one sensory effect information, and executing an effect event corresponding to the at least one sensory effect information.

According to another aspect of one or more embodiments, there is provided at least one non-transitory computer readable recording medium storing program instructions that control at least one processor to implement methods of one or more embodiments.

### BRIEF DESCRIPTION OF THE DRAWINGS

These and/or other aspects will become apparent and more readily appreciated from the following description of embodiments, taken in conjunction with the accompanying drawings of which:

FIG. 1 illustrates a diagram of a sensory effect processing system according to one or more embodiments;

FIGS. 2 through 4 illustrate a sensory effect processing system according to one or more embodiments;

FIG. 5 illustrates a structure of a sensory device according to one or more embodiments;

FIG. 6 illustrates a structure of a sensory effect controlling device according to one or more embodiments; and

FIG. 7 illustrates a method of operating a sensory effect processing system according to one or more embodiments.

### DETAILED DESCRIPTION

Reference will now be made in detail to embodiments, examples of which are illustrated in the accompanying drawings, wherein like reference numerals refer to the like elements throughout. Embodiments are described below to explain the present disclosure by referring to the figures.

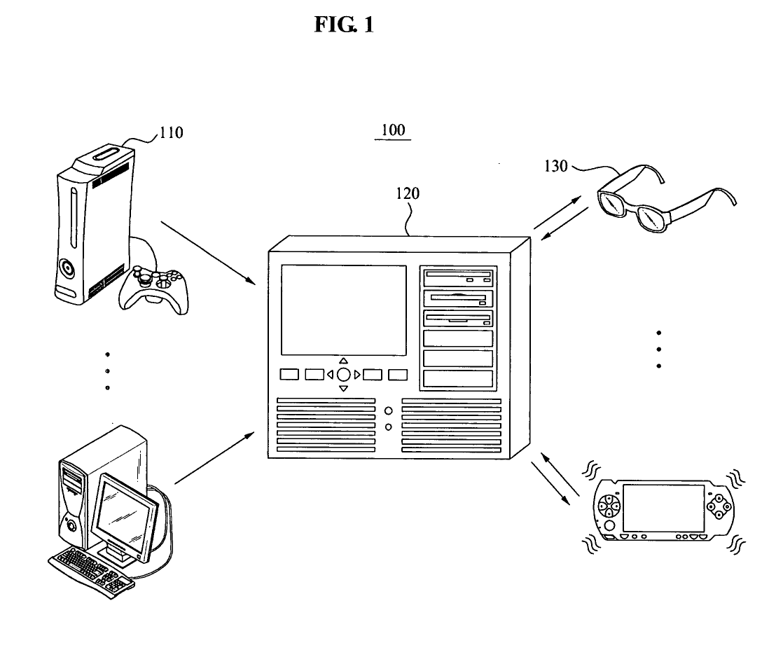

FIG. 1 illustrates a diagram of a sensory effect processing system 100 according to embodiments.

Referring to FIG. 1, the sensory effect processing system 100 includes a sensory media reproducing device 110, a sensory effect controlling device 120, and a sensory device 130.

The sensory media reproducing device 110 reproduces contents containing at least one sensory effect information. The sensory media reproducing device 110 may include a digital versatile disc (DVD) player, a movie player, a personal computer (PC), a game machine, a virtual world processing device, and the like.

The sensory effect information denotes information on a predetermined effect implemented in a real world corresponding to contents being reproduced by the sensory media reproducing device 110. For example, the sensory effect information may be information on a vibration effect for vibrating a joystick of a game machine when an earthquake occurs in a virtual world being reproduced by the game machine.

The sensory media reproducing device 110 may encode the sensory effect information into sensory effect metadata (SEM). That is, the sensory media reproducing device 110 may generate the SEM by encoding the sensory effect information.

The sensory media reproducing device 110 may transmit the generated SEM to the sensory effect controlling device 120.

The sensory device 130 is adapted to execute an effect event corresponding to the sensory effect information. According to embodiments, the sensory device 130 may be an actuator that implements the effect event in a real world. The sensory device 130 may include a vibration joystick, a 4-dimensional (4D) theater seat, virtual world goggles, and the like.

The effect event may denote an event implemented corresponding to the sensory effect information in the real world by the sensory device 130. For example, the effect event may be an event for operating a vibration unit of a game machine corresponding to sensory effect information that commands vibration of a joystick of the game machine.

The sensory device 130 may encode capability information regarding capability of the sensory device 130 into sensory device capability (SDCap) metadata. In other words, the sensory device 130 may generate the SDCap metadata by encoding the capability information. The capability information related to the sensory device 130 will be described in further detail hereinafter.

In addition, the sensory device 130 may transmit the generated SDCap metadata to the sensory effect controlling device 120.

The sensory device 130 may encode preference information, that is, information on a user preference with respect to a sensory effect, into user sensory preference (USP) metadata. In other words, the sensory device 130 may generate the USP metadata by encoding the preference information with respect to the sensory effect.

The preference information may denote information on a degree of user preference with respect to respective sensory effects. Also, the preference information may denote information on a level of the effect event executed corresponding to the sensory effect information. For example, regarding an effect event for vibrating a joystick, when the user does not want the vibration effect, the preference information may be information that sets a level of the effect event to 0. The preference information of the user regarding the sensory effect will be described in further detail hereinafter.

The sensory device 130 may be input with the preference information by the user.

In addition, the sensory device 130 may transmit the generated USP metadata to the sensory effect controlling device 120.

The sensory effect controlling device 120 may receive the SEM from the sensory media reproducing device 110 and also receive the SDCap metadata from the sensory device 130.

Also, the sensory effect controlling device 120 may decode the SEM and the SDCap metadata.

The sensory effect controlling device 120 may extract metadata effect information by decoding the SEM. Also, the sensory effect controlling device 120 may extract the capability information regarding capability of the sensory device 130 by decoding the SDCap metadata.

The sensory effect controlling device 120 may generate command information for controlling the sensory device 130 based on the decoded SEM and the decoded SDCap metadata. Accordingly, the sensory effect controlling device 120 may generate the command information for controlling the sensory device 130 such that the sensory device 130 executes the effect event corresponding to the capability of the sensory device 130.

The command information may be information for controlling execution of the effect event by the sensory device 130. Depending on embodiments, the command information may include the sensory effect information.

The sensory effect controlling device 120 may receive the SDCap metadata and the USP metadata from the sensory device 130.

Here, the sensory effect controlling device 120 may extract the preference information with respect to the sensory effect, by decoding the USP metadata.

Also, the sensory effect controlling device 120 may generate command information based on the decoded SEM, the decoded SDCap metadata, and the decoded USP metadata. Depending on embodiments, the command information may include the sensory effect information. Accordingly, the sensory effect controlling device 120 may generate the command information for controlling the sensory device 130 such that the sensory device 130 executes the effect event according to the degree of user preference and corresponding to the capability of the sensory device 130.

The sensory effect controlling device 120 may encode the generated command information into sensory device command (SDCmd) metadata. That is, the sensory effect controlling device 120 may generate the SDCmd metadata by encoding the generated command information.

Also, the sensory effect controlling device 120 may transmit the SDCmd metadata to the sensory device 130.

The sensory device 130 may receive the SDCmd metadata from the sensory effect controlling device 120 and decode the received SDCmd metadata.

In other words, the sensory device 130 may extract the sensory effect information by decoding the SDCmd metadata. Here, the sensory device 130 may execute the effect event corresponding to the sensory effect information.

The sensory device 130 may extract the command information by decoding the SDCmd metadata. In this case, the sensory device 130 may execute the effect event corresponding to the sensory effect information based on the command information.

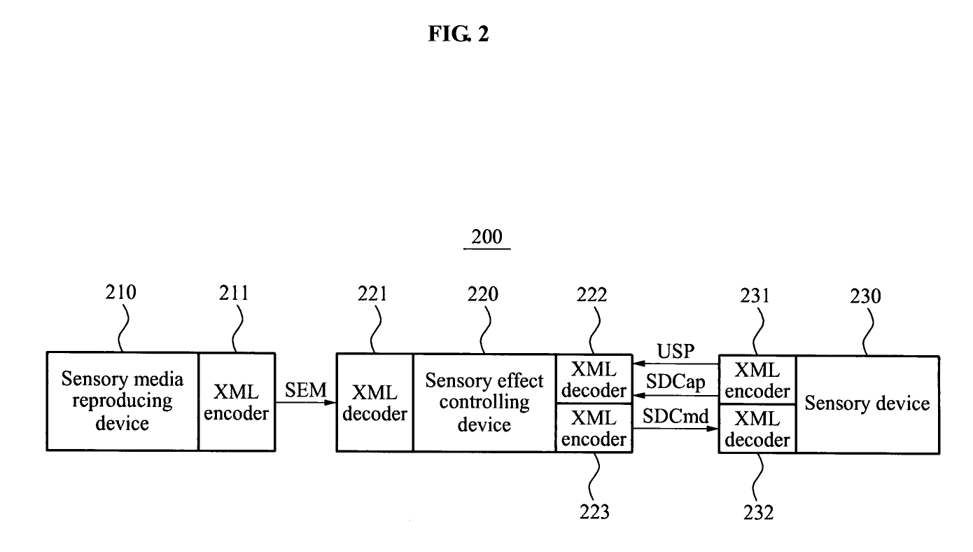

FIGS. 2 through 4 illustrate a sensory effect processing system 200 according to embodiments.

Referring to FIG. 2, the sensory effect processing system 200 may include a sensory media reproducing device 210, a sensory effect controlling device 220, and a sensory device 230.

The sensory media reproducing device 210 may include an extensible mark-up language (XML) encoder 211.

The XML encoder 211 may generate SEM by encoding sensory effect information into XML metadata. Here, the sensory media reproducing device 210 may transmit the SEM encoded in the form of the XML metadata to the sensory effect controlling device 220.

The sensory effect controlling device 220 may include an XML decoder 221.

The XML decoder 221 may decode the SEM received from the sensory media reproducing device 210. The XML decoder 221 may extract the sensory effect information by decoding the SEM.

The sensory device 230 may include an XML encoder 231.

The XML encoder 231 may generate SDCap metadata by encoding capability information regarding capability of the sensory device 230 into XML metadata. Here, the sensory device 230 may transmit the SDCap metadata encoded in the form of XML metadata to the sensory effect controlling device 220.

The XML encoder 231 may generate USP metadata by encoding preference information, that is, information on a user preference with respect to a sensory effect, into XML metadata. Here, the sensory device 230 may transmit the USP metadata encoded in the form of the XML metadata to the sensory effect controlling device 220.

The sensory effect controlling device 220 may include an XML decoder 222.

The XML decoder 222 may decode the SDCap metadata received from the sensory device 230. The XML decoder 222 may extract capability information regarding capability of the sensory device 230 by decoding the SDCap metadata.

In addition, the XML decoder 222 may decode the USP metadata received from the sensory device 230. The XML decoder 222 may extract the preference information regarding the sensory effect by decoding the USP metadata.

The sensory effect controlling device 220 may include an XML encoder 223.

The XML encoder 223 may generate SDCmd metadata by encoding command information for controlling execution of an effect event by the sensory device 230 into XML metadata. Here, the sensory effect controlling device 220 may transmit the SDCmd metadata encoded in the form of the XML metadata to the sensory device 230.

The sensory device 230 may include an XML decoder 232.

The XML decoder 232 may decode the SDCmd metadata received from the sensory effect controlling device 220. The XML decoder 232 may extract the command information by decoding the SDCmd metadata.

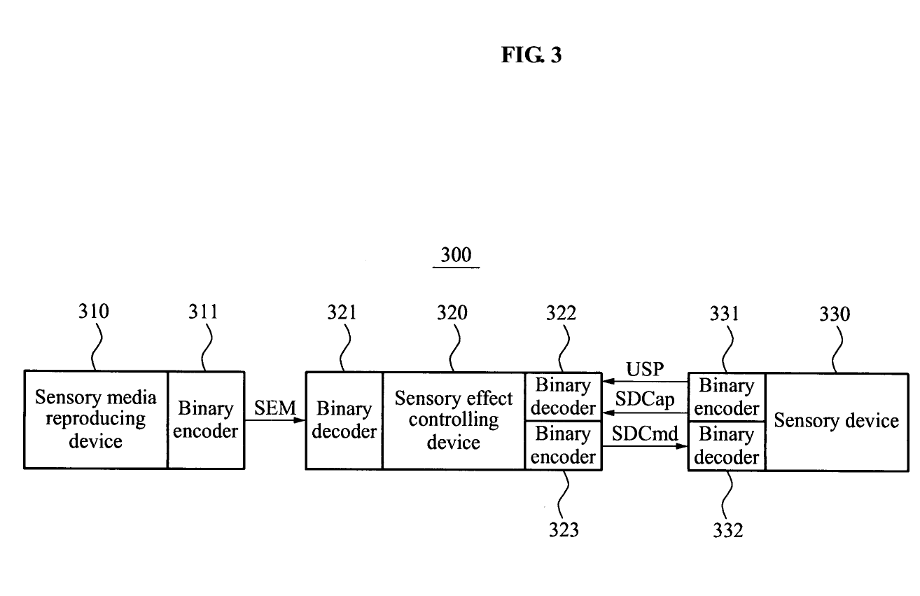

Referring to FIG. 3, a sensory effect processing system 300 may include a sensory media reproducing device 310, a sensory effect controlling device 320, and a sensory device 330.

The sensory media reproducing device 310 may include a binary encoder 311.

The binary encoder 311 may generate SEM by encoding sensory effect information into binary metadata. Here, the sensory media reproducing device 310 may transmit the SEM encoded in the form of the binary metadata to the sensory effect controlling device 320.

The sensory effect controlling device 320 may include a binary decoder 321.

The binary decoder 321 may decode the SEM received from the sensory media reproducing device 310. According to embodiments, the binary decoder 321 may extract the sensory effect information by decoding the SEM.

The sensory device 330 may include a binary encoder 331.

The binary encoder 331 may generate SDCap metadata encoded in the form of the binary metadata to the sensory effect controlling device 320.

The binary encoder 331 may generate USP metadata by encoding preference information, that is, information on a user preference with respect to a sensory effect, into binary metadata. Here, the binary encoder 330 may transmit the USP metadata encoded in the form of the binary metadata to the sensory effect controlling device 320.

The sensory effect controlling device 320 may include a binary decoder 322.

The binary decoder 322 may decode the SDCap metadata received from the sensory device 330. The binary decoder 322 may extract capability information regarding capability of the sensory device 330, by decoding the SDCap metadata.

The binary decoder 322 may decode the USP metadata received from the sensory device 330. The binary decoder 322 may extract the preference information regarding the sensory effect by decoding the USP metadata.

The sensory effect controlling device 320 may include a binary encoder 323.

The binary encoder 323 may generate SDCmd metadata by encoding command information for controlling execution of an effect event by the sensory device 330 into binary metadata. Here, the sensory effect controlling device 320 may transmit the SDCmd metadata encoded in the form of the binary metadata to the sensory device 330.

The sensory device 330 may include a binary decoder 332.

The binary decoder 332 may decode the SDCmd metadata received from the sensory effect controlling device 320. The binary decoder 332 may extract the command information by decoding the SDCmd metadata.

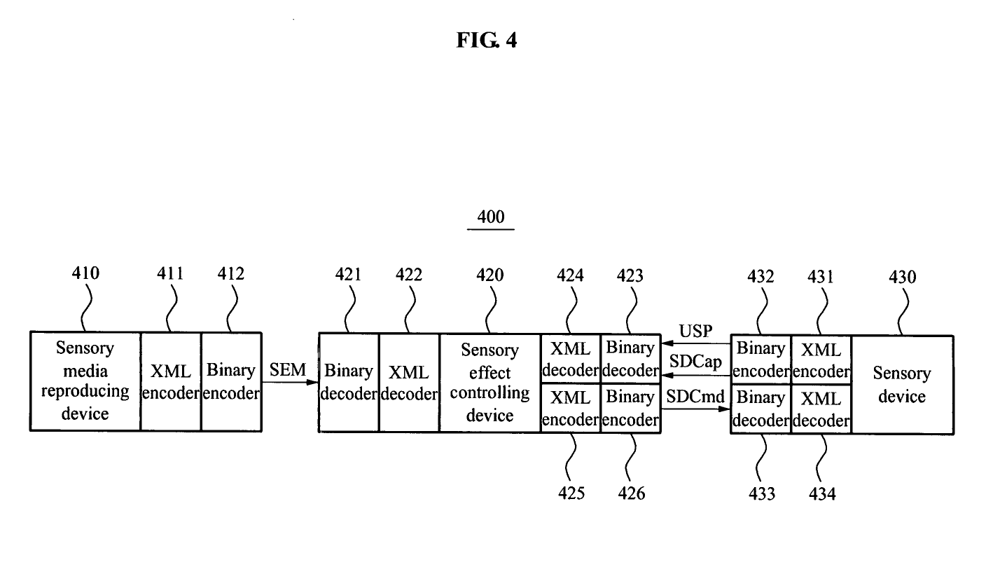

Referring to FIG. 4, a sensory effect processing system 400 may include a sensory media reproducing device 410, a sensory effect controlling device 420, and a sensory device 430.

The sensory media reproducing device 410 may include an XML encoder 411 and a binary encoder 412.

The XML encoder 411 may generate third metadata by encoding sensory effect information into XML metadata. The binary encoder 412 may generate SEM by encoding the third metadata into binary metadata. The sensory media reproducing device 410 may transmit the SEM to the sensory effect controlling device 420.

The sensory effect controlling device 420 may include a binary decoder 421 and an XML decoder 422.

The binary decoder 421 may extract the third metadata by decoding the SEM received from the sensory media reproducing device 410. The XML decoder 422 may extract the sensory effect information by decoding the third metadata.

The sensory device 430 may include an XML encoder 431 and a binary encoder 432.

The XML encoder 431 may generate second metadata by encoding capability information regarding capability of the sensory device 430 into XML metadata. The binary encoder 432 may generate SDCap metadata by encoding the second metadata into binary metadata. Here, the sensory device 430 may transmit the SDCap metadata to the sensory effect controlling device 420.

The XML encoder 431 may generate fourth metadata by encoding preference information, that is, information on a user preference with respect to a sensory effect, into XML metadata. The binary encoder 432 may generate USP metadata by encoding the fourth metadata into binary metadata. Here, the sensory device 430 may transmit the USP metadata to the sensory effect controlling device 420.

The sensory effect controlling device 420 may include a binary decoder 423 and an XML decoder 424.

The binary decoder 423 may extract the second metadata by decoding the SDCap metadata received from the sensory device 430. The XML decoder 424 may extract the capability information regarding the sensory device 430 by decoding the second metadata.

In addition, the binary decoder 423 may extract the fourth metadata by decoding the USP metadata received from the sensory device 430. The XML decoder 424 may extract the preference information regarding the sensory effect by decoding the fourth metadata.

The sensory effect controlling device 420 may include an XML encoder 425 and a binary encoder 426.

The XML encoder 425 may generate first metadata by encoding command information for controlling execution of an effect event by the sensory device 430. The binary encoder 426 may generate SDCmd metadata by encoding the first metadata into binary metadata. Here, the sensory effect controlling device 420 may transmit the SDCmd metadata to the sensory device 430.

The sensory device 430 may include a binary decoder 433 and an XML decoder 434.

The binary decoder 433 may extract the first metadata by decoding the SDCmd metadata received from the sensory effect controlling device 420. The XML decoder 434 may extract the command information by decoding the first metadata.

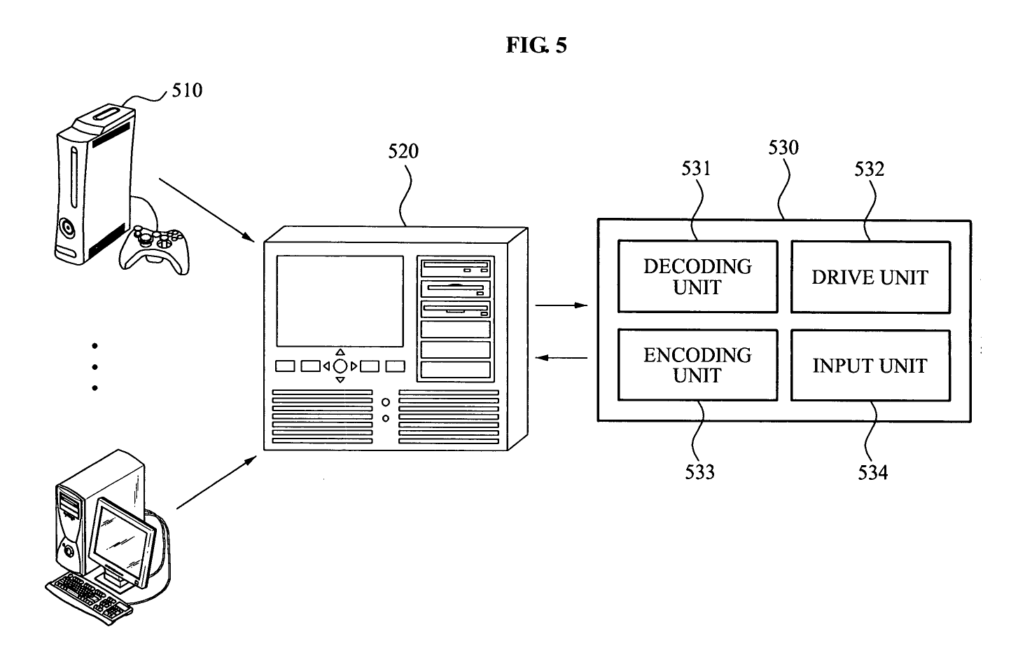

FIG. 5 illustrates a structure of a sensory device 530 according to embodiments.

Referring to FIG. 5, the sensory device 530 includes a decoding unit 531 and a drive unit 532.

The decoding unit 531 may decode SDCmd metadata containing at least one sensory effect information. In other words, the decoding unit 531 may extract at least one sensory effect information by decoding the SDCmd metadata.

The SDCmd metadata may be received from a sensory effect controlling device 520. Depending on embodiments, the SDCmd metadata may include command information.

The decoding unit 531 may extract the command information by decoding the SDCmd metadata.

The drive unit 532 may execute an effect event corresponding to the at least one sensory effect information. According to embodiments, the drive unit 532 may execute the effect event based on the command information.

Contents reproduced by the sensory media reproducing device 510 may include at least one sensory effect information.

The sensory device 530 may further include an encoding unit 533.

The encoding unit 533 may encode capability information regarding capability of the sensory device 530 into SDCap metadata. In other words, the encoding unit 533 may generate the SDCap metadata by encoding the capability information. The encoding unit 533 may include at least one of an XML encoder and a binary encoder.

The encoding unit 533 may generate the SDCap metadata by encoding the capability information into XML metadata.

In addition, the encoding unit 533 may generate the SDCap metadata by encoding the capability information into binary metadata.

In addition, the encoding unit 533 may generate second metadata by encoding the capability information into XML metadata, and generate the SDCap metadata by encoding the second metadata into binary metadata.

The capability information may be information on capability of the sensory device 530.

The SDCap metadata may include a sensory device capability base type which denotes basic capability information regarding the sensory device 530. The sensory device capability base type may be metadata regarding the capability information commonly applied to all types of the sensory device 530.

Table 1 shows an XML representation syntax regarding the sensory device capability base type according to embodiments.

```
TABLE 1
<!-- ################################################-->
<!-- Sensory Device capability base type -->
<!-- ################################################-->
<complexType name=“SensoryDeviceCapabilityBaseType” abstract=“true”>
  <complexContent>
    <extension base=“dia:TerminalCapabilityBaseType”>
      <attributeGroup ref=“cidl:sensoryDeviceCapabilityAttributes”/>
    </extension>
  </complexContent>
</complexType>
```

Table 2 shows a binary representation syntax regarding the sensory device capability base type according to embodiments.

TABLE 2

| SensoryDeviceCapabilityBaseType{ | Number of bits | Mnemonic |
|---|---|---|
| TerminalCapabilityBase | | TerminalCapabilityBaseType |
| sensoryDeviceCapabilityAttributes | | sensoryDeviceCapabilityAttributesType |
| } | | |

Table 3 shows descriptor components semantics regarding the sensory device capability base type according to embodiments.

TABLE 3

| Names, | Description, |
|---|---|
| SensoryDeviceCapabilityBaseType, | SensoryDeviceCapabilityBaseType |
| | extends |
| | dia:TeminalCapabilityBaseType |
| | and provides a base abstract type |
| | for a subset of types defined as part |
| | of the sensory device capability |
| | metadata types. For details of |
| | dia:TerminalCapabilityBaseType, |
| | refer to the Part 7 of |
| | ISO/IEC 21000, |
| TerminalCapabilityBaseType, | [symbol] |
| sensoryDeviceCapabilityAttributes, | Describes a group of attributes |
| | for the device capabilities, |

The SDCap metadata may include sensory device capability base attributes that denote groups regarding common attributes of the sensory device 530.

Table 4 shows an XML representation syntax regarding the sensory device capability base type according to embodiments.

```
TABLE 4
<!-- ################################################ -->
<!-- Definition of Sensory Device Capability Attributes -->
<!-- ################################################ -->
<attributeGroup name=“sensoryDeviceCapabilityAttributes”>
  <attribute name=“zerothOrderDelayTime” type=“nonNegativeInteger”
use=“optional”/>
  <attribute name=“firstOrderDelayTime” type=“nonNegativeInteger”
use=“optional”/>
  <attribute name=“location” type=“mpeg7:termReferenceType” use=“optional”/>
</attributeGroup>
```

Table 5 shows a binary representation syntax regarding the sensory device capability base type according to embodiments.

TABLE 5

| sensoryDeviceCapabilityAttributes { | Number of bits | Mnemonic |
|---|---|---|
| zerothOrderDelayTimeFlag | 1 | bslbf |
| firstOrderDelayTimeFlag | 1 | bslbf |
| locationFlag | 1 | bslbf |
| if(zerothOrderDelayTimeFlag){ | | |
| zerothOrderDelayTime | 16 | uimsbf |
| } | | |
| firstOrderDelayTimeFlag){ | | |
| firstOrderDelayTime | 16 | uimsbf |
| } | | |
| if(locationFlag){ | | |
| location | | locationType |
| } | | |
| } | | |

Table 6 shows a binary representation syntax regarding a location type of the sensory device capability base type according to embodiments.

TABLE 6

| locationType, | Term ID of location, |
|---|---|
| 0000, | left, |
| 0001, | centerleft, |
| 0010, | center, |
| 0011, | centerright, |
| 0100, | right, |
| 0101, | bottom, |
| 0110, | middle, |
| 0111, | top, |
| 1000, | back, |
| 1001, | midway, |
| 1010, | front, |
| 1011-1111, | Reserved, |

Table 7 shows descriptor components semantics regarding the sensory device capability base type according to embodiments.

TABLE 7

| Names, | Description, |
|---|---|
| sensoryDeviceCapabilityAttributes, | Describes a group of attributes for the sensory device |
| | capabilities., |
| zerothOrderDelayTimeFlag, | This field, which is only present in the binary representation, |
| | signals the presence of the activation attribute. A value of “1” |
| | means the attribute shall be used and “0” means the attribute |
| | shall not be used., |
| firstOrderDelayTimeFlag, | This field, which is only present in the binary representation, |
| | signals the presence of the activation attribute. A value of “1” |
| | means the attribute shall be used and “0” means the attribute |
| | shall not be used., |
| locationFlag, | This field, which is only present in the binary representation, |
| | signals the presence of the activation attribute. A value of “1” |
| | means the attribute shall be used and “0” means the attribute |
| | shall not be used., |
| zerothOrderDelayTime, | Describes required preparation time of a sensory device to be |
| | activated since it receives a command in the unit of millisecond |
| | (ms)., |
| firstOrderDelayTime, | Describes the delay time for a device to reach the target |
| | intensity since it receives a command and is activated in the unit |
| | of millisecond (ms)., |
| location, | Describes the position of the device from the user's perspective |
| | according to the x-, y-, and z-axis as a reference to the |
| | LocationCS as defined in Annex 2.3 of ISO/IEC 23005-6. The |
| | location attribute is defined in mpeg7:termReferenceType |
| | and is defined in Part 5 of ISO/IEC 15938., |

The sensory effect processing system may include MPEG-V information.

Table 7-1 shows a binary representation syntax regarding the MPEG-V information, according to embodiments.

TABLE 7-1

| Names [symbol] | Description [symbol] | | |
|---|---|---|---|
| TypeOfMetadata [symbol] | This field, which is only present in the binary | | |
| | representation, indicates the type of the | | |
| | MPEGVINFO element. [symbol] | | |
| | [symbol] | | |
| | Binary representation | | |
| | for metadata (4 bits) [symbol] | Term of Sensor [symbol] | [symbol] |
| | 0 [symbol] | SEM [symbol] | [symbol] |
| | 1 [symbol] | InteractionInfo [symbol] | [symbol] |
| | 2 [symbol] | ControlInfo [symbol] | [symbol] |
| | 3 [symbol] | VWOC [symbol] | [symbol] |
| | 4-15 [symbol] | Reserved [symbol] | [symbol] |

| | |
|---|---|
| SEM [symbol] | The binary representation of the root element of |
| | sensory effect metadata. [symbol] |
| InteractionInfo [symbol] | The binary representation of the root element of |
| | interaction information. [symbol] |
| ControlInfo [symbol] | The binary representation of the root element of |
| | control information metadata. [symbol] |
| VWOC [symbol] | The binary representation of the root element of virtual |
| | world object characteristics metadata. [symbol] |

Table 7-2 shows descriptor components semantics regarding the MPEG-V information according to embodiments.

TABLE 7-2

| Names [symbol] | Description [symbol] | | |
|---|---|---|---|
| TypeOfMetadata [symbol] | This field, which is only present in the binary | | |
| | representation, indicates the type of the | | |
| | MPEGVINFO element. [symbol] | | |
| | [symbol] | | |
| | Binary representation | | |
| | for metadata (4 bits) [symbol] | Term of Sensor [symbol] | [symbol] |
| | 0 [symbol] | SEM [symbol] | [symbol] |
| | 1 [symbol] | InteractionInfo [symbol] | [symbol] |
| | 2 [symbol] | ControlInfo [symbol] | [symbol] |
| | 3 [symbol] | VWOC [symbol] | [symbol] |
| | 4-15 [symbol] | Reserved [symbol] | [symbol] |

| | |
|---|---|
| SEM [symbol] | The binary representation of the root element of |
| | sensory effect metadata. [symbol] |
| InteractionInfo [symbol] | The binary representation of the root element of |
| | interaction information. [symbol] |
| ControlInfo [symbol] | The binary representation of the root element of |
| | control information metadata. [symbol] |
| VWOC [symbol] | The binary representation of the root element of virtual |
| | world object characteristics metadata. [symbol] |

Table 7-3 shows an XML representation syntax regarding a root element of control information of command information according to embodiments.

```
TABLE 7-3
  <!-- ################################################ -->
  <!-- Root Element -->
  <!-- ################################################ -->
  <element name=“ControlInfo” type=“cidl:ControlInfoType”/>
  <complexType name=“ControlInfoType”>
    <sequence>
      <element name=“SensoryDeviceCapabilityList”
  type=“cidl:SensoryDeviceCapabilityListType” minOccurs=“0”/>
      <element name=“SensorCapabilityList”
  type=“cidl:SensorCapabilityListType” minOccurs=“0”/>
      <element name=“UserSensoryPreferenceList”
  type=“cidl:UserSensoryPreferenceListType” minOccurs=“0”/>
    </sequence>
  </complexType>
  <complexType name=“SensoryDeviceCapabilityListType”>
    <sequence>
      <element name=“SensoryDeviceCapability”
  type=“cidl:SensoryDeviceCapabilityBaseType”
  maxOccurs=“unbounded”/>
    </sequence>
  </complexType>
  <complexType name=“SensorCapabilityListType”>
    <sequence>
      <element name=“SensorCapability”
  type=“cidl:SensorCapabilityBaseType” maxOccurs=“unbounded”/>
    </sequence>
  </complexType>
  <complexType name=“UserSensoryPreferenceListType”>
    <sequence>
      <element name=“USPreference”
type=“cidl:UserSensoryPreferenceBaseType”
  maxOccurs=“unbounded”/>
    </sequence>
  </complexType>
```

Table 7-4 shows a binary representation syntax regarding the root element of control information, according to embodiments.

TABLE 7-4

| | (Number of | |
|---|---|---|
| | bits) | (Mnemonic) |
| ControlInfo { | | |
| ControlInfoType | 2 | bslbf |
| If (ControlInfoType=’00’){ | | |
| SensoryDeviceCapabilityList | | SensoryDeviceCapabilityListType |
| }else if (ControlInfoType=’01’){ | | |
| SensorCapabilityList | | SensorCapabilityListType |
| }else if (ControlInfoType=’02’){ | | |
| UserSensoryPreferenceList | | UserSensoryPreferenceListType |
| } | | |
| } | | |
| SensoryDeviceCapabilityListType { | | |
| NumOfSensoryDevCap | 32 | uimsbf |
| for(i=1;i<NumOfSensoryDevCap;i++){ | | |
| IndividualSensoryDevCapType | 5 | bslbf |
| SensoryDeviceCapability | | SensoryDeviceCapabilityType |
| | | specified |
| | | by IndividualSensoryDevCapType |
| } | | |
| } | | |
| SensorCapabilityListType { | | |
| NumOfSensorCap | 32 | uimsbf |
| for(i=1;i<NumOfSensorCap;i++){ | | |
| IndividualSensorCapType | 5 | bslbf |
| SensorCapability | | SensorCapabilityType specified |
| | | by IndividualSensorCapType |
| } | | |
| } | | |
| UserSensoryPreferenceListType { | | |
| NumOfUserSensoryPref | 32 | uimsbf |
| for(i=1;i<NumOfUserSensoryPref;i++){ | | |
| IndividualUserSensoryPrefType | 8 | bslbf |
| USPreference | | USPreferenceType specified |
| | | by IndividualUserSensoryPrefType |
| } | | |
| } | | |

Table 7-5 shows descriptor components semantics regarding the root element of control information, according to embodiments.

TABLE 7-5

| Names | Description |
|---|---|
| ControlInfoType | This field, which is only present in the binary representation, |
| | indicates the type of the ControlInfo element. The mapping |
| | table for the type is as follows, |

| | Binary value (2 bits) | Term of control information |
|---|---|---|
| | 0 | SensoryDeviceCapabilityList |
| | 1 | SensorCapabilityList |
| | 2 | UserSensoryPreferenceList |
| | 3 | Reserved |
| SensoryDeviceCapabilityList | Optional wrapper element that serves as the placeholder for the | |
| | sequence of sensory device capabilities. | |
| SensorCapabilityList | Optional wrapper element that serves as the placeholder for the | |
| | sequence of sensor capabilities. | |
| UserSensoryPreferenceList | Optional wrapper element that serves as the placeholder for the | |
| | sequence of user sensory preference. | |
| SensoryDeviceCapabilityListType | A type that serves as the placeholder for the sequence of | |
| | sensory device capabilities. | |
| NumOfSensoryDevCap | This field, which is only present in the binary representation, specifies | |
| | the number of SensoryDeviceCapability instances accommodated | |
| | in the SensoryDeviceCapabilityList. | |
| IndividualSensoryDevCapType | This field, which is only present in the binary representation, | |
| | describes which SensoryDeviceCapability type shall be | |
| | used. | |
| | In the binary description, the following mapping table is used, | |
| | | Binary representation |
| | Terms of Device | for device type (5 bits) |
| | Light device | 00000 |
| | Flash device | 00001 |
| | Heating device | 00010 |
| | Cooling device | 00011 |
| | Wind device | 00100 |
| | Vibration device | 00101 |
| | Sprayer device | 00110 |
| | Scent device | 00111 |
| | Fog device | 01000 |
| | Color correction device | 01001 |
| | Initialize color correction | 01010 |
| | parameter device | |
| | Rigid body motion device | 01011 |
| | Tactile device | 01100 |
| | Kinesthetic device | 01101 |
| | Reserved | 01110-11111 |
| SensoryDeviceCapability | Specifies single device capability for a certain device. The list of single | |
| | device capabilities are as follows | |
| | Terms of Device | Device capability type |
| | Light device | LightCapabilityType |
| | Flash device | FlashCapabilityType |
| | Heating device | HeatingCapabilityType |
| | Cooling device | CoolingCapabilityType |
| | Wind device | WindCapabilityType |
| | Vibration device | VibrationCapabilityType |
| | Sprayer device | SprayerCapabilityType |
| | Scent device | ScentCapabilityType |
| | Fog device | FogCapabilityType |
| | Color correction device | ColorCorrectionCapability Type |
| | Initialize color correction | InitializeColorCorrectionParameterCapabilityType |
| | parameter device | |
| | Rigid body motion device | RigidBodyMotionCapabilityType |
| | Tactile device | TactileCapabilityType |
| | Kinesthetic device | KinestheticCapabilityType |
| SensorCapabilityListType | A type that serves as the placeholder for the list of sensor capabilities. | |
| NumOfSensorCap | This field, which is only present in the binary representation, | |
| | specifies the number of SensorCapability instances | |
| | accommodated in the SensorCapabilityList. | |
| IndividualSensorCapType | This field, which is only present in the binary representation, | |
| | describes which SensorCapability type shall be used. | |
| | In the binary description, the following mapping table is used, | |
| | | Binary representation |
| | Term of sensor capability | for sensor type (5 bits) |
| | Light sensor capability | 00000 |
| | Ambient noise sensor capability | 00001 |
| | Temperature sensor capability | 00010 |
| | Humidity sensor capability | 00011 |
| | Distance sensor capability | 00100 |
| | Atmospheric pressure Sensor | 00101 |
| | capability | |
| | Position sensor capability | 00110 |
| | Velocity sensor capability | 00111 |
| | Acceleration sensor capability | 01000 |
| | Orientation sensor capability | 01001 |
| | Angular velocity sensor capability | 01010 |
| | Angular acceleration sensor | 01011 |
| | capability | |
| | Force sensor capability | 01100 |
| | Torque sensor capability | 01101 |
| | Pressure sensor capability | 01110 |
| | Motion sensor capability | 01111 |
| | Intelligent camera sensor | 10000 |
| | capability | |
| | Reserved | 10001-11111 |
| SensorCapability | Specifies single description of information acquired through a | |
| | sensor. The list of single commands are as follows, | |
| | Term of Sensor | Sensor capability type |
| | Light sensor | LightSensorCapabilityType |
| | Ambient noise sensor | AmbientNoiseSensorCapabilityType |
| | Temperature sensor | TemperatureSensorCapabilityType |
| | Humidity sensor | HumiditySensorCapabilityType |
| | Distance sensor | DistanceSensorCapabilityType |
| | Atmospheric pressure Sensor | AtmosphericPressureSensorCapabilityType |
| | Position sensor | PositionSensorCapabilityType |
| | Velocity sensor | VelocitySensorCapabilityType |
| | Acceleration sensor | AccelerationSensorCapabilityType |
| | Orientation sensor | OrientationSensorCapabilityType |
| | Angular velocity sensor | AngularVelocitySensorCapabilityType |
| | Angular acceleration sensor | AngularAccelerationSensorCapabilityType |
| | Force sensor | ForceSensorCapabilityType |
| | Torque sensor | TorqueSensorCapabilityType |
| | Pressure sensor | PressureSensorCapabilityType |
| | Motion sensor | MotionSensorCapabilityType |
| | Intelligent camera sensor | IntelligentCameraCapabilityType |
| UserSensoryPreferenceListType | A type that serves as the placeholder for the list of user sensory preferences. | |
| NumOfUserSensoryPref | This field, which is only present in the binary representation, specifies the number of | |
| | USPreference instances accommodated in the UserSensoryPreferenceList. | |
| IndividualUserSensoryPrefType | This field, which is only present in the binary representation, describes which | |
| | USPreference type shall be used. | |
| | In the binary description, the following mapping table is used, | |
| | | Binary representation |
| | Terms of Effect | for effect type (5 bits) |
| | Light effect | 00000 |
| | Flash effect | 00001 |
| | Heating effect | 00010 |
| | Cooling effect | 00011 |
| | Wind effect | 00100 |
| | Vibration effect | 00101 |
| | Sprayer effect | 00110 |
| | Scent effect | 00111 |
| | Fog effect | 01000 |
| | Color correction effect | 01001 |
| | Initialize color correction effect | 01010 |
| | Rigid body motion effect | 01011 |
| | Tactile effect | 01100 |
| | Kinesthetic effect | 01101 |
| | Reserved | 01110-11111 |
| USPreference | Specifies a single device capability for a certain device. The list | |
| | of single device capabilities are as follows | |
| | Terms of Effect | Terms of user preference |
| | Light effect | LightPrefType |
| | Flash effect | FlashPrefType |
| | Heating effect | HeatingPrefType |
| | Cooling effect | CoolingPrefType |
| | Wind effect | WindPrefType |
| | Vibration effect | VibrationPrefType |
| | Scent effect | ScentPrefType |
| | Fog effect | FogPrefType |
| | Spraying effect | SprayingPrefType |
| | Color correction effect | ColorCorrectionPrefType |
| | Rigid body motion effect | RigidBodyMotionPrefType |
| | Tactile effect | TactilePrefType |
| | Kinesthetic effect | KinestheticPrefType |

Table 7-6 shows an XML representation syntax regarding the root element of control information of interaction information, according to embodiments.

```
TABLE 7-6
  <!-- ################################################ -->
  <-- Root and Top-Level Elements -->
  <!-- ################################################ -->
  <element name=“InteractionInfo” type=“iidl:InteractionInfoType”/>
  <complexType name=“InteractionInfoType”>
    <choice>
      <element name=“DeviceCommandList”
type=“iidl:DeviceCmdListType”/>
      <element name=“SensedInfoList”type=“iidl:SensedlnfoListType”/>
    </choice>
  </complexType>
  <complexType name=“SensedInfoListType”>
    <sequence>
      <element name=“SensedInfo” type=“iidl:SensedInfoBaseType”
maxOccurs=“unbounded”/>
    </sequence>
  </complexType>
  <complexType name=“DeviceCmdListType”>
    <sequence>
      <element name=“DeviceCommand”
type=“iidl:DeviceCommandBaseType” maxOccurs=“unbounded”/>
    </sequence>
  </complexType>
```

Table 7-7 shows a binary representation syntax regarding the root element of control information of the interaction information, according to embodiments.

TABLE 7-7

| | (Number | |
|---|---|---|
| | of | |
| | bits) | (Mnemonic) |
| InteractionInfo { | | |
| InteractionType | 1 | bslbf |
| If (InteractionType){ | | |
| DeviceCommandList | | DeviceCmdListType |
| }else{ | | |
| SensedInfoList | | SensedInfoListType |
| } | | |
| } | | |
| SensedInfoListType{ | | |
| NumOfSensedInfo | 32 | uimsbf |
| for(i=1;i<NumOfSensedInfo;i++){ | | |
| IndividualSensedInfoType | 8 | bslbf |
| SensedInfo | | SensedInfoType specified |
| | | by IndividualSensedInfoType |
| } | | |
| } | | |
| } | | |
| DeviceCmdListType{ | | |
| NumOfDeviceCmd | 32 | uimsbf |
| for(i=1;i<NumOfDeviceCmd;i++){ | | |
| IndividualDeviceCmdType | 8 | bslbf |
| DeviceCmd | | DeviceCmdType |
| | | specified by IndividualDeviceCmdType |
| } | | |
| } | | |

Table 7-8 shows descriptor components semantics regarding the root element of control information of the interaction information, according to embodiments.

TABLE 7-8

| Names | Description |
|---|---|
| InteractionType | This field, which is only present in the binary representation, |
| | indicates the type of the InteractionInfo element. If it is 1 |
| | then the DeviceCommandList element is present, otherwise |
| | the SensedInfoList element is present. |
| DeviceCommandList | Optional wrapper element that serves as the placeholder for the |
| | sequence of device commands. |
| SensedInfoList | Optional wrapper element that serves as the placeholder for the |
| | list of information acquired through sensors. |
| SensedInfoListType | A type that serves as the placeholder for the list of information |
| | acquired through sensors. |
| NumOfSensedInfo | This field, which is only present in the binary representation, |
| | specifies the number of SensedInfo instances accommodated |
| | in the SensedInfoList. |
| IndividualSensedInfoType | This field, which is only present in the binary representation, |
| | describes which SenseInfo type shall be used. |
| | In the binary description, the following mapping table is used, |

| | | Binary representation |
|---|---|---|
| | Term of Sensor | for sensor type (5 bits) |
| | Light sensor | 00000 |
| | Ambient noise sensor | 00001 |
| | Temperature sensor | 00010 |
| | Humidity sensor | 00011 |
| | Distance sensor | 00100 |
| | Atmospheric pressure Sensor | 00101 |
| | Position sensor | 00110 |
| | Velocity sensor | 00111 |
| | Acceleration sensor | 01000 |
| | Orientation sensor | 01001 |
| | Angular velocity sensor | 01010 |
| | Angular acceleration sensor | 01011 |
| | Force sensor | 01100 |
| | Torque sensor | 01101 |
| | Pressure sensor | 01110 |
| | Motion sensor | 01111 |
| | Intelligent camera sensor | 10000 |
| | Reserved | 10001-11111 |
| SensedInfo | Specifies single description of information acquired through a | |
| | sensor. The list of single commands are as follows, | |
| | Term of Sensor | Sensed info. type |
| | Light sensor | LightSensorType |
| | Ambient noise sensor | AmbientNoiseSensorType |
| | Temperature sensor | TemperatureSensorType |
| | Humidity sensor | HumiditySensorType |
| | Distance sensor | DistanceSensorType |
| | Atmospheric pressure Sensor | AtmosphericPressureSensorType |
| | Position sensor | PositionSensorType |
| | Velocity sensor | VelocitySensorType |
| | Acceleration sensor | AccelerationSensorType |
| | Orientation sensor | OrientationSensorType |
| | Angular velocity sensor | AngularVelocitySensorType |
| | Angular acceleration sensor | AngularAccelerationSensorType |
| | Force sensor | ForceSensorType |
| | Torque sensor | TorqueSensorType |
| | Pressure sensor | PressureSensorType |
| | Motion sensor | MotionSensorType |
| | Intelligent camera sensor | IntelligentCameraType |
| DeviceCommandListType | A type that serves as the placeholder for the sequence of | |
| | device commands. | |
| NumOfDeviceCmd | This field, which is only present in the binary representation, | |
| | specifies the number of DeviceCmd instances accommodated | |
| | in the DeviceCommandList. | |
| IndividualDeviceCmdType | This field, which is only present in the binary representation, | |
| | describes which DeviceCmd type shall be used. | |
| | In the binary description, the following mapping table is used, | |
| | | Binary representation |
| | Terms of Device | for device type (5 bits) |
| | Light device | 00000 |
| | Flash device | 00001 |
| | Heating device | 00010 |
| | Cooling device | 00011 |
| | Wind device | 00100 |
| | Vibration device | 00101 |
| | Sprayer device | 00110 |
| | Scent device | 00111 |
| | Fog device | 01000 |
| | Color correction device | 01001 |
| | Initialize color correction | 01010 |
| | parameter device | |
| | Rigid body motion device | 01011 |
| | Tactile device | 01100 |
| | Kinesthetic device | 01101 |
| | Reserved | 01110-11111 |
| DeviceCmd | Specifies single command for a certain device. The list of single | |
| | commands are as follows | |
| | Terms of Device | Device command type |
| | Light device | LightType |
| | Flash device | FlashType |
| | Heating device | HeatingType |
| | Cooling device | CoolingType |
| | Wind device | WindType |
| | Vibration device | VibrationType |
| | Sprayer device | SprayerType |
| | Scent device | ScentType |
| | Fog device | FogType |
| | Color correction device | ColorCorrectionType |
| | Initialize color correction | InitializeColorCorrectionParameterType |
| | parameter device | |
| | Rigid body motion device | RigidBodyMotionType |
| | Tactile device | TactileType |
| | Kinesthetic device | KinestheticType |

The sensory device 530 may be classified into a plurality of types depending on types of the drive unit 532 that executes the effect event.

For example, the sensory device 530 may include a light type, a flash type, a heat type, a cooling type, a wind type, a vibration type, a scent type, a fog type, a sprayer type, a color correction type, a tactile type, a kinesthetic type, and a rigid body motion type.

Table 7-2 shows a binary representation syntax regarding each type of the sensory device 530.

TABLE 7-2

| Binary Representation | |
|---|---|
| for Actuator Type | Term of Actuator |
| 00000 | Light type |
| 00001 | Flash type |
| 00010 | Heating type |
| 00011 | Cooling type |
| 00100 | Wind type |
| 00101 | Vibration type |
| 00110 | Sprayer type |
| 00111 | Fog type |
| 01000 | Color correction type |
| 01001 | Initialize color correction parameter type |
| 01010 | Rigid body motion type |
| 01011 | Tactile type |
| 01100 | Kinesthetic type |
| 01101-1111 | Reserved |

Hereinafter, the respective capability information regarding the sensory device will be described in detail.

Table 8 shows an XML representation syntax regarding the light type sensory device.

TABLE 8

```
  <!-- ################################################ -->
  <!-- Light capability type -->
  <!-- ################################################ -->
  <complexType name=“LightCapabilityType”>
    <complexContent>
      <extension base=“cidl:SensoryDeviceCapabilityBaseType”>
        <sequence>
          <element name=“Color” type=“mpegvct:colorType”
minOccurs=“0” maxOccurs=“unbounded”/>
```

Table 9 shows a binary representation syntax regarding the light type sensory device.

TABLE 9

| LightCapabilityType { | Number of bits | Mnemonic |
|---|---|---|
| ColorFlag | 1 | bslbf |
| unitFlag | 1 | bslbf |
| maxIntensityFlag | 1 | bslbf |
| numOfLightLevelsFlag | 1 | bslbf |
| SensoryDeviceCapabilityBase | | SensoryDeviceCapabilityBaseType |
| if(ColorFlag){ | | |
| LoopColor | | vluimsbf5 |
| for(k=0;k<LoopColor;k++){ | | |
| Color[k] | | ColorType |
| } | | |
| } | | |
| if(unitFlag){ | | |
| unit | | unitType |
| } | | |
| if(maxIntensityFlag){ | | |
| maxIntensity | 8 | uimsbf |
| } | | |
| if(numOfLightLevelsFlag){ | | |
| numOfLightLevels | 8 | uimsbf |
| } | | |
| } | | |

Table 10 shows descriptor components semantics regarding the light type sensory device.

TABLE 10

| Names, | Descrption, |
|---|---|
| LightCapabilityType, | Tool for describing a light capability., |
| ColorFlag, | This field, which is only present in the binary representation, |
| | signals the presence of the activation attribute. A value of “1” |
| | means the attribute shall be used and “0” means the attribute |
| | shall not be used., |
| unitFlag, | This field, which is only present in the binary representation, |
| | signals the presence of the activation attribute. A value of “1” |
| | means the attribute shall be used and “0” means the attribute |
| | shall not be used., |
| maxIntensityFlag, | This field, which is only present in the binary representation, |
| | signals the presence of the activation attribute. A value of “1” |
| | means the attribute shall be used and “0” means the attribute |
| | shall not be used., |
| numOfLightLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| LoopColor, | This field, which is only present in the binary representation, |
| | specifies the number of Color contained in the description., |
| Color, | Describes the list of colors which the lighting device can provide |
| | as a reference to a classification scheme term or as RGB value. |
| | A CS that may be used for this purpose is the ColorCS defined |
| | in A.2.2 of ISO/IEC 23005-6., |
| unit, | Specifies the unit of the maxIntensity if a unit other than the |
| | default unit is used, as a reference to a classification scheme |
| | term provided by UnitTypeCS defined in A.2.1 of ISO/IEC |
| | 23005-6., |
| maxIntensity, | Describes the maximum intensity that the lighting device can |
| | provide in terms of LUX., |
| numOfLightLevels, | Describes the number of intensity levels that the device can |
| | provide in between maximum and minimum intensity of light., |

Table 11 shows an XML representation syntax regarding the flash type sensory device.

TABLE 11

```
  <!-- ################################################ -->
  <!-- Flash capability type -->
  <!-- ################################################ -->
  <complexType name=“FlashCapabilityType”>
    <complexContent>
      <extension base=“dcdv:LightCapabilityType”>
        <attribute name=“maxFrequency” type=“positiveInteger”
use=“optional”/>
        <attribute name=“numOfFreqLevels” type=
“nonNegativeInteger” use=“optional”/>
      </extension>
    </complexContent>
  </complexType>
```

Table 12 shows a binary representation syntax regarding the flash type sensory device.

TABLE 12

| | Number of bits | Mnemonic |
|---|---|---|
| FlashCapabilityType { | | |
| maxFrequencyFlag | 1 | bslbf |
| numOfFreqLevelsFlag | 1 | bslbf |
| LightCapability | | LightCapabilityType |
| if(maxFrequencyFlag){ | | |
| maxFrequency | 8 | uimsbf |
| } | | |
| if(numOfFreqLevelsFlag){ | | |
| numOfFreqLevels | 8 | uimsbf |
| } | | |
| } | | |

Table 13 shows descriptor components semantics regarding the flash type sensory device.

TABLE 13

| Names, | Description, |
|---|---|
| FlashCapabilityType, | Tool for describing a flash capability. It is |
| | extended from the light capability type., |
| maxFrequencyFlag, | This field, which is only present in the binary |
| | representation, signals the presence of the |
| | activation attribute. A value of “1” means the |
| | attribute shall be used and “0” means the |
| | attribute shall not be used., |
| numOfFreqLevelsFlag, | This field, which is only present in the binary |
| | representation, signals the presence of the |
| | activation attribute. A value of “1” means the |
| | attribute shall be used and “0” means the |
| | attribute shall not used., |
| LightCapability, | Describes a light capability., |
| maxFrequency, | Describes the maximum number of flickering in |
| | times per second., |
| numOfFreqLevels, | Describes the number of frequency levels that |
| | the device can provide in between maximum and |
| | minimum frequency., |

Table 14 shows an XML representation syntax regarding the heating type sensory device.

```
TABLE 14
  <!-- ################################################ -->
  <!-- Heating capability type -->
  <!-- ################################################ -->
  <complexType name=“HeatingCapabilityType”>
    <complexContent>
      <extension base=“cidl:SensoryDeviceCapabilityBaseType”>
        <attribute name=“maxIntensity” type=“nonNegativeInteger”
use=“optional”/>
        <attribute name=“minIntensity” type=“integer” use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 15 shows a binary representation syntax regarding the heating type sensory device.

TABLE 15

| | Number | |
|---|---|---|
| | of | |
| | bits | Mnemonic |
| HeatingCapabilityType { | | |
| maxIntensityFlag | 1 | bslbf |
| minIntensityFlag | 1 | bslbf |
| unitFlag | 1 | bslbf |
| numOfLevelsFlag | 1 | bslbf |
| SensoryDeviceCapabilityBase | | SensoryDeviceCapability- |
| | | BaseType |
| if(maxIntensityFlag){ | | |
| maxIntensity | 8 | uimsbf |
| } | | |
| if(minIntensityFlag){ | | |
| minIntensity | 10 | simsbf |
| } | | |
| if(unitFlag){ | | |
| unit | | unitType |
| } | | |
| if(numOfLevelsFlag){ | | |
| numOfLevels | 8 | uimsbf |
| } | | |
| } | | |

Table 16 shows descriptor components semantics regarding the heating type sensory device.

TABLE 16

| Names, | Description, |
|---|---|
| HeatingCapabilityType, | Tool for describing the capability of a device which can increase |
| | the room temperature., |
| maxIntensityFlag, | This field, which is only present in the binary representation, |
| | signals the presence of the activation attribute. A value of “1” |
| | means the attribute shall be used and “0” mean the attribute |
| | shall not be used., |
| minIntensityFlag, | This field, which is only present in the binary representation, |
| | signals the presence of the activation attribute. A value of “1” |
| | means the attribute shall be used and “0” mean the attribute |
| | shall not be used., |
| unitFlag, | This field, which is only present in the binary representation, |
| | signals the presence of the activation attribute. A value of “1” |
| | means the attribute shall be used and “0” means the attritute |
| | shall not be used., |
| numOfLevelsFlag, | This field, which is only present in the binary representation, |
| | signals the presence of the activation attribute. A value of “1” |
| | means the attribute shall be used and “0” means the attritute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| maxIntensity, | Describes the highest temperature that the heating device can |
| | provide in terms of Celsius (or Fahrenheit)., |
| minIntensity, | Describes the lowest temperature that the heating device can |
| | provide in terms of Celsius (or Fahrenheit)., |
| unit, | Specifies the unit of the intensity, as a reference to a |
| | classification scheme term provided by UnitTypeCS defined in |
| | A.2.1 or ISO/IEC 23005-6 (it shall be a reference to either |
| | Celsius or Fahrenheit) If the unit is not specified, the default |
| | unit is Celsius., |
| numOfLevels, | Describes the number of temperature levels that the device can |
| | provide in between maximum and minimum temperature., |

Table 17 shows an XML representation syntax regarding the cooling type sensory device.

```
TABLE 17
  <!-- ################################################ -->
  <!-- Cooling capability type -->
  <!-- ################################################ -->
  <complexType name=“CoolingCapabilityType”>
    <complexContent>
      <extension base=“cidl:SensoryDeviceCapabilityBaseType”>
        <attribute name=“minIntensity” type=“integer” use=“optional”/>
        <attribute name=“maxIntensity” type=“nonNegativeInteger”
use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 18 shows a binary representation syntax regarding the cooling type sensory device.

TABLE 18

| | Number | |
|---|---|---|
| | of bits | Mnemonic |
| CoolingCapabilityType { | | |
| maxIntensityFlag | 1 | bslbf |
| minIntensityFlag | 1 | bslbf |
| unitFlag | 1 | bslbf |
| numOfLevelsFlag | 1 | bslbf |
| SensoryDeviceCapabilityBase | | SensoryDeviceCapability- |
| | | BaseType |
| if(maxIntensityFlag){ | | |
| maxIntensity | 8 | uimsbf |
| } | | |
| if(minIntensityFlag){ | | |
| minIntensity | 10 | simsbf |
| } | | |
| if(unitFlag){ | | |
| unit | | unitType |
| } | | |
| if(numOfLevelsFlag){ | | |
| numOfLevels | 8 | uimsbf |
| } | | |
| } | | |

Table 19 shows descriptor components semantics regarding the cooling type sensory device.

TABLE 19

| Names, | Description, |
|---|---|
| CoolingCapabilityType, | Tool for describing the capability of a device which can |
| | decrease the room temperature., |
| maxIntensityFlag, | This field, which is only present in the binary representation, |
| | signals the presence of the activation attribute. A value of “1” |
| | means the attribute shall be used and “0” mean the attribute |
| | shall not be used., |
| minIntensityFlag, | This field, which is only present in the binary representation, |
| | signals the presence of the activation attribute. A value of “1” |
| | means the attribute shall be used and “0” mean the attribute |
| | shall not be used., |
| unitFlag, | This field, which is only present in the binary representation, |
| | signals the presence of the activation attribute. A value of “1” |
| | means the attribute shall be used and “0” means the attritute |
| | shall not be used., |
| numOfLevelsFlag, | This field, which is only present in the binary representation, |
| | signals the presence of the activation attribute. A value of “1” |
| | means the attribute shall be used and “0” means the attritute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| maxIntensity, | Describes the lowest temperature that the cooling device can |
| | provide in terms of Celsius., |
| minIntensity, | Describes the highest temperature that the cooling device can |
| | provide in terms of Celsius., |
| unit, | Specifies the unit of the intensity, as a reference to a |
| | classification scheme term provided by UnitTypeCS defined in |
| | A.2.1 or ISO/IEC 23005-6 (it shall be a reference to either |
| | Celsius or Fahrenheit) If the unit is not specified, the default |
| | unit is Celsius., |
| numOfLevels, | Describes the number of temperature levels that the device can |
| | provide in between maximum and minimum temperature., |

Table 20 shows an XML representation syntax regarding the wind type sensory device.

```
TABLE 20
  <!-- ################################################ -->
  <!-- Wind type -->
  <!-- ################################################ -->
  <complexType name=“WindCapabilityType”>
    <complexContent>
      <extension base=“cidl:SensoryDeviceCapabilityBaseType”>
        <attribute name=“maxWindSpeed” type=“nonNegativeInteger”
use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 21 shows a binary representation syntax regarding the wind type sensory device.

TABLE 21

| | | Number | |
|---|---|---|---|
| WindCapabilityType { | | of bits | Mnemonic |
| maxWindSpeedFlag | | 1 | bslbf |
| | unitFlag | 1 | bslbf |
| | numOfLevelsFlag | 1 | bslbf |

| | |
|---|---|
| SensoryDeviceCapabilityBase | SensoryDeviceCapabilityBaseType |
| if(maxWindSpeedFlag){ | |

| | | |
|---|---|---|
| maxWindSpeed | 8 | uimsbf |

}
if(unitFlag){

| | |
|---|---|
| unit | unitType |

}
if(numOfLevelsFlag){

| | | |
|---|---|---|
| numOfLevels | 8 | uimsbf |

}

}

Table 22 shows descriptor components semantics regarding the wind type sensory device.

TABLE 22

| Names, | Description, |
|---|---|
| WindCapabilityType, | Tool for describing a wind capability., |
| maxWindSpeedFlag, | This field, which is only present in the binary representation, |
| | signals the presence of the activation attribute. A value of “1” |
| | means the attribute shall be used and “0” means the attribute |
| | shall not be used., |
| unitFlag, | This field, which is only present in the binary representation, |
| | signals the presence of the activation attribute. A value of “1” |
| | means the attribute shall be used and “0” means the attribute |
| | shall not be used., |
| numOfLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| maxWindSpeed, | Describes the maximum wind speed that the fan can provide in |
| | terms of Meter per second., |
| unit, | Specifies the unit of the intensity, if a unit other than the default |
| | unit specified in the semantics of the maxWindSpeed is used, as |
| | a reference to a classification scheme term provided by |
| | UnitTypeCS defined in A.2.1 of ISO/IEC 23005-6., |
| numOfLevels, | Describes the number of wind speed levels that the device can |
| | provide in between maximum and minimum speed., |

Table 23 shows an XML representation syntax regarding the vibration type sensory device.

```
TABLE 23
  <!-- ################################################ -->
  <!-- Vibration capability type -->
  <!-- ################################################ -->
  <complexType name=“VibrationCapabilityType”>
    <complexContent>
      <extension base=“cidl:SensoryDeviceCapabilityBaseType”>
        <attribute name=“maxIntensity” type=“nonNegativeInteger”
use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 24 shows a binary representation syntax regarding the vibration type sensory device.

TABLE 24

| | | Number | |
|---|---|---|---|
| VibrationCapabilityType { | | of bits | Mnemonic |
| maxIntensityFlag | | 1 | bslbf |
| | unitFlag | 1 | bslbf |
| | numOfLevelsFlag | 1 | bslbf |

| | |
|---|---|
| SensoryDeviceCapabilityBase | SensoryDeviceCapabilityBaseType |
| if(maxIntensityFlag){ | |

| | | |
|---|---|---|
| maxIntensity | 8 | uimsbf |

}
if(unitFlag){

| | |
|---|---|
| unit | unitType |

}
if(numOfLevelsFlag){

| | | |
|---|---|---|
| numOfLevels | 8 | uimsbf |

}

}

Table 25 shows descriptor components semantics regarding the vibration type sensory device.

TABLE 25

| Names, | Description, |
|---|---|
| VibrationCapabilityType, | Tool for describing a vibration capability., |
| maxIntensity Flag, | This field, which is only present in the binary representation, |
| | signals the presence of the activation attribute. A value of “1” |
| | means the attribute shall be used and “0” means the attribute |
| | shall not be used., |
| unitFlag, | This field, which is only present in the binary representation, |
| | signals the presence of the activation attribute. A value of “1” |
| | means the attribute shall be used and “0” means the attribute |
| | shall not be used., |
| numOfLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| maxIntensity, | Describes the maximum intensity that the vibrator device can |
| | provide in terms of Richter magnitude., |
| unit, | Specifies the unit of the intensity, if a unit other than the default |
| | unit specified in the semantics of the maxIntensity is used, as a |
| | reference to a classification scheme term provided by |
| | UnitTypeCS defined in A.2.1 of ISO/IEC 23005-6., |
| numOfLevels, | |
| | provide in between zero and maximum intensity., |

Table 26 shows an XML representation syntax regarding the scent type sensory device.

```
TABLE 26
  <!-- ################################################ -->
  <!-- Scent capability type -->
  <!-- ################################################ -->
  <complexType name=“ScentCapabilityType”>
    <complexContent>
      <extension base=“cidl:SensoryDeviceCapabilityBaseType”>
        <sequence>
          <element name=“Scent” type=“mpeg7:termReferenceType”
minOccurs=“0” maxOccurs=“unbounded”/>
        </sequence>
        <attribute name=“maxIntensity” type=“nonNegativeInteger”
use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 27 shows a binary representation syntax regarding the scent type sensory device.

TABLE 27

| | | Number | |
|---|---|---|---|
| ScentCapabilityType { | | of bits | Mnemonic |
| ScentFlag | | 1 | bslbf |
| maxIntensityFlag | | 1 | bslbf |
| | unitFlag | 1 | bslbf |
| | numOfLevelsFlag | 1 | bslbf |

| | |
|---|---|
| SensoryDeviceCapabilityBase | SensoryDeviceCapabilityBaseType |
| if(ScentFlag){ | |

| | |
|---|---|
| LoopScent | vluimsbf5 |

for(k=0;k<LoopScent;k++){

| | |
|---|---|
| Scent[k] | ScentType |

}

}
if(maxIntensityFlag){

| | | |
|---|---|---|
| maxIntensity | 8 | uimsbf |

}
if(unitFlag){

| | |
|---|---|
| unit | unitType |

}
if(numOfLevelsFlag){

| | | |
|---|---|---|
| numOfLevels | 8 | uimsbf |

}

}

Table 28 shows a binary representation syntax regarding the scent type sensory device.

TABLE 28

| scentType, | Term ID of scent, |
|---|---|
| 0000, | rose, |
| 0001, | acacia, |
| 0010, | chrysanthemum, |
| 0011, | lilac, |
| 0100, | mint, |
| 0101, | jasmine, |
| 0110, | pine_tree, |
| 0111, | orange, |
| 1000, | grape, |
| 1001-1111, | Reserved, |

Table 29 shows descriptor components semantics regarding the scent type sensory device.

TABLE 29

| Names, | Description, |
|---|---|
| ScentCapabilityType, | Tool for describing a scent capability., |
| ScentFlag, | This field, which is only present in the binary representation, |
| | signals the presence of the activation attribute. A value of “1” |
| | means the attribute shall be used and “0” means the attribute |
| | shall not be used., |
| maxIntensityFlag, | This field, which is only present in the binary representation, |
| | signals the presence of the activation attribute. A value of “1” |
| | means the attribute shall be used and “0” means the attribute |
| | shall not be used., |
| unitFlag, | This field, which is only present in the binary representation, |
| | signals the presence of the activation attribute. A value of “1” |
| | means the attribute shall be used and “0” means the attribute |
| | shall not be used., |
| numOfLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| LoopScent, | This field, which is only present in the binary representation, |
| | specifies the number of Scent contained in the description., |
| Scent, | Describes the list of scent that the perfumer can provide. A CS |
| | that may be used for this purpose is the ScentCS defined in |
| | A.2.4 of ISO/IEC 23005-6., |
| maxIntensity, | Describes the maximum intensity that the perfumer can provide |
| | in terms of ml/h., |
| maxIntensity, | Describes the maximum intensity that the perfumer can provide |
| | in terms of ml/h., |
| unit, | Specifies the unit of the intensity, if a unit other than the default |
| | unit specified in the semantics of the maxIntensity is used, as a |
| | reference to a classification scheme term provided by |
| | UnitTypeCS defined in A.2.1 of ISO/IEC 23005-6., |
| numOfLevels, | Describes the number of intensity levels of the scent that the |
| | device can provide in between zero and maximum intensity., |

Table 30 shows an XML representation syntax regarding the fog type sensory device.

```
TABLE 30
  <!-- ################################################ -->
  <!-- Fog capability type -->
  <!-- ################################################ -->
  <complexType name=“FogCapabilityType”>
    <complexContent>
      <extension base=“cidl:SensoryDeviceCapabilityBaseType”>
        <attribute name=“maxIntensity” type=“nonNegativeInteger”
use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 31 shows a binary representation syntax regarding the fog type sensory device.

TABLE 31

| | | Number | |
|---|---|---|---|
| FogCapabilityType { | | of bits | Mnemonic |
| maxIntensityFlag | | 1 | bslbf |
| | unitFlag | 1 | bslbf |
| | numOfLevelsFlag | 1 | bslbf |

| | |
|---|---|
| SensoryDeviceCapabilityBase | SensoryDeviceCapabilityBaseType |
| if(maxIntensityFlag){ | |

| | | |
|---|---|---|
| maxIntensity | 8 | uimsbf |

}
if(unitFlag){

| | |
|---|---|
| unit | unitType |

}
if(numOfLevelsFlag){

| | | |
|---|---|---|
| numOfLevels | 8 | uimsbf |

}

}

Table 32 shows descriptor components semantics regarding the fog type sensory device.

TABLE 32

| Names, | Description, |
|---|---|
| FogCapabilityType, | Tool for describing a fog capability., |
| maxIntensityFlag, | This field, which is only present in the binary representation, |
| | signals the presence of the activation attribute. A value of “1” |
| | means the attribute shall be used and “0” means the attribute |
| | shall not be used., |
| unitFlag, | This field, which is only present in the binary representation, |
| | signals the presence of the activation attribute. A value of “1” |
| | means the attribute shall be used and “0” means the attribute |
| | shall not be used., |
| numOfLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| maxIntensity, | Describes the maximum intensity that the fog device can provide |
| | in terms of ml/h., |
| unit, | Specifies the unit of the intensity, if a unit other than the default |
| | unit specified in the semantics of the maxIntensity is used, as a |
| | reference to a classification scheme term provided by |
| | UnitTypeCS defined A.2.1 of ISO/IEC 23005-6., |
| numOfLevels, | Describes the number of intensity levels of the fog that the |
| | device can provide in between zero and maximum intensity., |

Table 33 shows an XML representation syntax regarding the sprayer type sensory device.

```
TABLE 33
  <!-- ################################################ -->
  <!-- Sprayer capability type -->
  <!-- ################################################ -->
  <complexType name=“SprayerCapabilityType”>
    <complexContent>
      <extension base=“cidl:SensoryDeviceCapabilityBaseType”>
        <attribute name=“sprayingType” type=
        “mpeg7:termReferenceType”/>
        <attribute name=“maxIntensity” type=“nonNegativeInteger”
use=“optional”/>
        <attribute name=“unit” type=“mpegvct:unitType”
use=“optional”/>
        <attribute name=“numOfLevels” type=“nonNegativeInteger”
use=“optional”/>
      </extension>
    </complexContent>
  </complexType>
```

Table 34 shows a binary representation syntax regarding the sprayer type sensory device.

TABLE 34

| | | Number | |
|---|---|---|---|
| SprayerCapabilityType { | | of bits | Mnemonic |
| | sprayingFlag | 1 | bslbf |

| maxIntensityFlag | | 1 | bslbf |
|---|---|---|---|
| | unitFlag | 1 | bslbf |
| | numOfLevelsFlag | 1 | bslbf |

| | |
|---|---|
| SensoryDeviceCapabilityBase | SensoryDeviceCapabilityBaseType |
| if(sprayingFlag) { | |

| | |
|---|---|
| spraying | SprayingType |

}
if(maxIntensityFlag){

| | | |
|---|---|---|
| maxIntensity | 8 | uimsbf |

}
if(unitFlag){

| | |
|---|---|
| unit | unitType |

}
if(numOfLevelsFlag){

| | | |
|---|---|---|
| numOfLevels | 8 | uimsbf |

}

}

Table 35 shows a binary representation syntax regarding the sprayer type sensory device.

TABLE 35

| SprayingType, | Term ID of Spraying, |
|---|---|
| 00, | water, |
| 01-11, | Reserved, |

Table 36 shows descriptor components semantics regarding the sprayer type sensory device.

TABLE 36

| Names, | Description, |
|---|---|
| SprayerCapabilityType, | Tool for describing a fog capability., |
| sprayingFlag, | This field, which is only present in the binary representation, |
| | signals the presence of the activation attribute. A value of “1” |
| | means the attribute shall be used and “0” means the attribute |
| | shall not be used., |
| maxIntensityFlag, | This field, which is only present in the binary representation, |
| | signals the presence of the activation attribute. A value of “1” |
| | means the attribute shall be used and “0” means the attribute |
| | shall not be used., |
| unitFlag, | This field, which is only present in the binary representation, |
| | signals the presence of the activation attribute. A value of “1” |
| | means the attribute shall be used and “0” means the attribute |
| | shall not be used., |
| numOfLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| spraying, | Describes the type of the sprayed material as a reference to a |
| | classification scheme term. A CS that may be used for this |
| | purpose is the SprayingTypeCS defined in Annex A.2.7 of |
| | ISO/IEC 23005-6., |
| maxIntensity, | Describes the maximum intensity that the water sprayer can |
| | provide in terms of ml/h., |
| unit, | Specifies the unit of the intensity, if a unit other than the default |
| | unit specified in the semantics of the maxIntensity is used, as a |
| | reference to a classification scheme term provided by |
| | UnitTypeCS defined in A.2.1 of ISO/IEC 23005-6., |
| numOfLevels, | Describes the; number of intensity levels of the fog that the |
| | device canprovide in between zero and maximum intensity., |

Table 37 shows an XML representation syntax regarding the color correction type sensory device.

TABLE 37

```
<!-- ################################################ -->
<!-- Definition of Color Correction Type -->
<!-- ################################################ -->
<complexType name=“ColorCorrectionCapabilityType”>
  <complexContent>
    <extension base=“cidl:SensoryDeviceCapabilityBaseType”>
      <attribute name=“flag” type=“boolean” use=“optional”/>
    </extension>
  </complexContent>
</complexType>
```

Table 38 shows a binary representation syntax regarding the color correction type sensory device.

TABLE 38

| | | Number | |
|---|---|---|---|
| ColorCorrectionCapabilityType { | | of bits | Mnemonic |
| | flagFlag | 1 | bslbf |
| | SensoryDeviceCapabilityBase | | SensoryDeviceCapabilityBaseType |
| | if(flagFlag) { | | |

| | | |
|---|---|---|
| flag | 1 | bslbf |

}

}

Table 39 shows descriptor components semantics regarding the color correction type sensory device.

TABLE 39

| Names, | Description, |
|---|---|
| ColorCorrectionCapabilityType, | Tool for describing a fog capability., |
| flagFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| flag, | Describes the existence of the color correction capability of the |
| | given device in terms of “true” and “false”., |

Table 40 shows an XML representation syntax regarding the tactile type sensory device.

```
TABLE 40
  <!-- ################################################ -->
  <!-- Tactile capability type -->
  <!-- ################################################ -->
  <complexType name=“TactileCapabilityType”>
    <complexContent>
      <extension base=“cidl:SensoryDeviceCapabilityBaseType”>
        <attribute name=“intensityUnit” type=“mpegvct:unitType”
use=“optional”/>
        <attribute name=“maxValue” type=“nonNegativeInteger”
use=“optional”/>
        <attribute name=“minValue” type=“nonNegativeInteger”
use=“optional”/>
        <attribute name=“arraysizeX” type=“integer”/>
        <attribute name=“arraysizeY” type=“integer”/>
        <attribute name=“gapX” type=“float” use=“optional”/>
        <attribute name=“gapY” type=“float” use=“optional”/>
        <attribute name=“gapUnit” type=“mpegvct:unitType”
use=“optional”/>
        <attribute name=“maxUpdateRate” type=“integer”
use=“optional”/>
        <attribute name=“updateRateUnit” type=“mpegvct:unitType”
use=“optional”/>
        <attribute name=“actuatorType”
type=“mpeg7:termReferenceType” use=“optional”/>
        <attribute name=“numOfLevels” type=“nonNegativeInteger”
use=“optional”/>
      </extension>
    </complexContent>
  </complexType>
```

Table 41 shows a binary representation syntax regarding the tactile type sensory device.

TABLE 41

| | | Number | |
|---|---|---|---|
| TactileCapabilityType { | | of bits | Mnemonic |
| | intensityUnitFlag | 1 | bslbf |

| maxValueFlag | | 1 | bslbf |
|---|---|---|---|
| | minValueFlag | 1 | bslbf |
| | arraysizeXFlag | 1 | bslbf |
| | arraysizeYFlag | 1 | bslbf |
| | gapXFlag | 1 | bslbf |
| | gapYFlag | 1 | bslbf |
| | gapUnitFlag | 1 | bslbf |
| | maxUpdateRateFlag | 1 | bslbf |
| | updateRateUnitFlag | 1 | bslbf |

| | | |
|---|---|---|
| actuatorTypeFlag | 1 | bslbf |

| | | |
|---|---|---|
| numOfLevelsFlag | 1 | bslbf |

| | |
|---|---|
| SensoryDeviceCapabilityBase | SensoryDeviceCapabilityBaseType |
| if(intensityUnitFlag) { | |

| | |
|---|---|
| intensityUnit | unitType |

}
if(maxValueFlag){

| | | |
|---|---|---|
| maxValue | 8 | uimsbf |

}

if(minValueFlag){

| | | |
|---|---|---|
| minValue | 8 | uimsbf |

}

if(arraysizeXFlag){

| | | |
|---|---|---|
| arraysizeX | 10 | simsbf |

}

if(arraysizeYFlag){

| | | |
|---|---|---|
| arraysizeY | 10 | simsbf |

}

if(gapXFlag){

| | | |
|---|---|---|
| gapX | 32 | fsbf |

}

if(gapYFlag){

| | | |
|---|---|---|
| gapY | 32 | fsbf |

}
if(gapUnitFlag){

| | |
|---|---|
| gapUnit | unitType |

}

if(maxUpdateRateFlag){

| | | |
|---|---|---|
| maxUpdateRate | 10 | simsbf |

}
if(updateRateUnitFlag){

| | |
|---|---|
| updateRateUnit | unitType |

}

if(actuatorTypeFlag){

| | |
|---|---|
| actuatorType | TactileDisplayCSType |

}
if(numOfLevelsFlag){

| | | |
|---|---|---|
| numOfLevels | 8 | uimsbf |

}

}

Table 42 shows a binary representation syntax regarding a tactile display type according to example embodiments.

TABLE 42

| TactileDisplayCSType, | Term ID of TactileDisplay, |
|---|---|
| 000, | vibrotactile, |
| 001, | electrotactile, |
| 010, | pneumatictactile, |
| 011, | piezoelectrictactile, |
| 100, | thermal, |
| 101-111, | Reserved, |

Table 43 shows descriptor components semantics regarding the tactile type sensory device.

TABLE 43

| Names, | Description, |
|---|---|
| TactileCapabilityType, | Tool for describing a tactile capability., |
| intensityUnitFlag, | This field, which is only present in the binary representation, |
| | signals the presence of the activation attribute. A value of “1” |
| | means the attribute shall be used and “0” means the attribute |
| | shall not be used., |
| maxValueFlag, | This field, which is only present in the binary representation, |
| | signals the presence of the activation attribute. A value of “1” |
| | means the attribute shall be used and “0” means the attribute |
| | shall not be used., |
| minValueFlag, | This field, which is only present in the binary representation, |
| | signals the presence of the activation attribute. A value of “1” |
| | means the attribute shall be used and “0” means the attribute |
| | shall not be used., |
| arraysizeXFlag, | This field, which is only present in the binary representation, |
| | signals the presence of the activation attribute. A value of “1” |
| | means the attribute shall be used and “0” means the attribute |
| | shall not be used., |
| arraysizeYFlag, | This field, which is only present in the binary representation, |
| | signals the presence of the activation attribute. A value of “1” |
| | means the attribute shall be used and “0” means the attribute |
| | shall not be used., |
| gapXFlag, | This field, which is only present in the binary representation, |
| | signals the presence of the activation attribute. A value of “1” |
| | means the attribute shall be used and “0” means the attribute |
| | shall not be used., |
| gapYFlag, | This field, which is only present in the binary representation, |
| | signals the presence of the activation attribute. A value of “1” |
| | means the attribute shall be used and “0” means the attribute |
| | shall not be used., |
| gapUnitFlag, | This field, which is only present in the binary representation, |
| | signals the presence of the activation attribute. A value of “1” |
| | means the attribute shall be used and “0” means the attribute |
| | shall not be used., |
| maxUpdateRateFlag, | This field, which is only present in the binary representation, |
| | signals the presence of the activation attribute. A value of “1” |
| | means the attribute shall be used and “0” means the attribute |
| | shall not be used., |
| updateRateUnitFlag, | This field, which is only present in the binary representation, |
| | signals the presence of the activation attribute. A value of “1” |
| | means the attribute shall be used and “0” means the attribute |
| | shall not be used., |
| actuatorTypeFlag, | This field, which is only present in the binary representation, |
| | signals the presence of the activation attribute. A value of “1” |
| | means the attribute shall be used and “0” means the attribute |
| | shall not be used., |
| numOfLevelsFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| intensityUnit, | Specifies the unit of the intensity for maxValue and minValue as |
| | a reference to a classification scheme term provided by |
| | UnitTypeCS defined in A.2.1 of ISO/IEC 23005-6. There is no |
| | default unit specified as the intensityUnit may vary depending on |
| | the type of the actuator used for the Tactile device. For |
| | example, when an electrotactile device is selected the unit can |
| | be mA. For a pneumatic tactile device, the unit may be either psi |
| | or Pa; for a vibrotactile device, the unit may be hz (frequency), |
| | or mm (amplitude); for a thermal display, the unit may be either |
| | Celsius or Fahrenheit., |
| maxValue, | Describes the maximum intensity that a tactile device can drive |
| | in the unit specified by the intensityUnit attribute., |
| minValue, | Describes the minimum intensity that a tactile device can drive |
| | in the unit specified by the intensityUnit attribute., |
| arraysizeX, | Describes a number of actuators in X (horizontal) direction since |
| | a tactile device is formed as m-by-n array types (integer)., |
| arraysizeY, | Describes a number of actuators in Y (vertical) direction since a |
| | tactile device is formed as m-by-n array types (integer)., |
| gapX, | Describes the X directional gap space between actuators in a |
| | tactile device (mm)., |
| gapY, | Describes the Y directional gap space between actuators in a |
| | tactile device (mm)., |
| gapUnit, | Specifies the unit of the description of gapX and gapY attributes |
| | as a reference to a classification scheme term provided by |
| | UnitTypeCS defined in A.2.1 of ISO/IEC 23005/6, if any unit |
| | other than the default unit of mm is used., |
| maxUpdateRate, | Describes a maximum update rate that a tactile device can drive., |
| updateRateUnit, | Specifies the unit of the description of maxUpdateRate as a |
| | reference to a classification scheme term provided by |
| | UnitTypeCS defined in A.2.1 of ISO/IEC 23005/6, if any unit |
| | other than the default unit of Hz is used., |
| actuatorType, | Describes a type of tactile device (e.g. vibrating motor, |
| | electrotactile device, pneumatic device, piezoelectric device, |
| | thermal device, etc). A CS that may be used for this purpose is |
| | the TactileDisplayCS defined in A.2.11 of ISO/IEC 23005-6., |
| numOfLevels, | Describes the number of intensity levels that a tactile device can |
| | drive., |

Table 44 shows an XML representation syntax regarding the kinesthetic type sensory device.

```
TABLE 44
  <!-- ################################################ -->
  <!-- Kinesthetic capability type -->
  <!-- ################################################ -->
  <complexType name=“KinestheticCapabilityType”>
    <complexContent>
      <extension base=“cidl:SensoryDeviceCapabilityBaseType”>
        <sequence>
          <element name=“maximumForce”
type=“mpegvct:Float3DVectorType”/>
          <element name=“maximumTorque”
type=“mpegvct:Float3DVectorType” minOccurs=“0”/>
          <element name=“maximumStiffness”
type=“mpegvct:Float3DVectorType” minOccurs=“0”/>
          <element name=“DOF” type=“dcdv:DOFType”/>
          <element name=“workspace” type=“dcdv:workspaceType”/>
        </sequence>
        <attribute name=“forceUnit” type=“mpegvct:unitType”
        use=“optional”/>
        <attribute name=“torqueUnit” type=“mpegvct:unitType”
        use=“optional”/>
        <attribute name=“stiffnessUnit” type=“mpegvct:unitType”
        use=“optional”/>
      </extension>
    </complexContent>
  </complexType>
  <complexType name=“DOFType”>
    <sequence>
      <element name=“Tx” type=“boolean”/>
      <element name=“Ty” type=“boolean”/>
      <element name=“Tz” type=“boolean”/>
      <element name=“Rx” type=“boolean”/>
      <element name=“Ry” type=“boolean”/>
      <element name=“Rz” type=“boolean”/>
    </sequence>
  </complexType>
  <complexType name=“workspaceType”>
    <sequence>
      <element name=“Width” type=“float”/>
      <element name=“Height” type=“float”/>
      <element name=“Depth” type=“float”/>
      <element name=“RotationX” type=“float”/>
      <element name=“RotationY” type=“float”/>
      <element name=“RotationZ” type=“float”/>
    </sequence>
  </complexType>
```

Table 45 shows a binary representation syntax regarding the kinesthetic type sensory device.

TABLE 45

| KinestheticCapabilityType { | Number of bits | Mnemonic |
|---|---|---|
| maximumTorqueFlag | 1 | bslbf |
| maximumStiffnessFlag | 1 | bslbf |
| forceUnitFlag | 1 | bslbf |
| torqueUnitFlag | 1 | bslbf |
| stiffnessUnitFlag | 1 | bslbf |
| SensoryDeviceCapabilityBase | | SensoryDeviceCapabilityBaseType |
| maximumForce | | Float3DVectorType |
| if(maximumTorqueFlag){ | | |
| maximumTorque | | Float3DVectorType |
| } | | |
| if(maximumStiffnessFlag){ | | |
| maximumStiffness | | Float3DVectorType |
| } | | |
| DOF | | DOFType |
| workspace | | workspaceType |
| if(forceUnitFlag) { | | |
| forceUnit | | unitType |
| } | | |
| if(torqueUnitFlag) { | | |
| torqueUnit | | unitType |
| } | | |
| if(stiffnessUnitFlag) { | | |
| stiffnessUnit | | unitType |
| } | | |
| } | | |
| Float3DVectorType { | | |
| X | 32 | fsbf |
| Y | 32 | fsbf |
| Z | 32 | fsbf |
| } | | |
| DOFType { | | |
| Tx | 1 | bslbf |
| Ty | 1 | bslbf |
| Tz | 1 | bslbf |
| Rx | 1 | bslbf |
| Ry | 1 | bslbf |
| Rz | 1 | bslbf |
| } | | |
| workspaceType{ | | |
| Width | 32 | fsbf |
| Height | 32 | fsbf |
| Depth | 32 | fsbf |
| RotationX | 32 | fsbf |
| RotationY | 32 | fsbf |
| RotationZ | 32 | fsbf |
| } | | |

Table 46 shows descriptor components semantics regarding the kinesthetic type sensory device.

TABLE 46

| Names, | Description, |
|---|---|
| KinestheticCapabilityType, | Tool for describing a tactile capability., |
| maximumTorqueFlag, | This field, which is only present in the binary representation, |
| | signals the presence of the activation attribute. A value of “1” |
| | means the attribute shall be used and “0” means the attribute |
| | shall not be used., |
| maximumStiffnessFlag, | This field, which is only present in the binary representation, |
| | signals the presence of the activation attribute. A value of “1” |
| | means the attribute shall be used and “0” means the attribute |
| | shall not be used., |
| forceUnitFlag, | This field, which is only present in the binary representation, |
| | signals the presence of the activation attribute. A value of “1” |
| | means the attribute shall be used and “0” means the attribute |
| | shall not be used., |
| torqueUnitFlag, | This field, which is only present in the binary representation, |
| | signals the presence of the activation attribute. A value of “1” |
| | means the attribute shall be used and “0” means the attribute |
| | shall not be used., |
| stiffnessUnitFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| maximumForce, | Describes the maximum force that the device can provide stably |
| | for each axis (N)., |
| maximumTorque, | Describes the maximum torque referring maximum rotational |
| | force that the device can generate stably for each axis (Nmm)., |
| maximumStiffness, | Describes the maximum stiffness (rigidity) that the device can |
| | generate stably for each axis (N/mm)., |
| DOF, | Describes the DOF (degree of freedom) of the device., |
| workspace, | Describes the workspace of the device (e.g. Width × Height × |
| | Depth (mm) 3 angles(degree))., |
| forceUnit, | Specifies the unit of the description of maximumForce attribute |
| | as a reference to a classification scheme term provided by |
| | UnitTypeCS defined in A.2.1 of ISO/IEC 23005-6, if any unit |
| | other than N(Newton) is used. 1 N refers a force that produces |
| | an acceleration of 1 m/s² for 1 kg mass. , |
| torqueUnit, | Specifies the unit of the description of maximumTorque attribute |
| | as a reference to a classification scheme term provided by |
| | UnitTypeCS defined in A.2.1 of ISO/IEC 23005-6, if any unit |
| | other than Nmm (Newton-millimeter) is used. , |
| stiffnessUnit, | Specifies the unit of the description of maximumTorque attribute |
| | as a reference to a classification scheme term provided by |
| | UnitTypeCS defined in A.2.1 of ISO/IEC 23005-6, if any unit |
| | other than N/mm (Newton per millimeter) is used., |
| Float3DVectorType, | Tool for describing a 3D position vector., |
| X, | Describes the sensed value in x-axis in the unit., |
| Y, | Describes the sensed value in y-axis in the unit., |
| Z, | Describes the sensed value in z-axis in the unit., |
| DOFType, | Defines a degree of freedom that shows a kinesthetic device |
| | provides several single (independent) movements. , |
| Tx, | A Boolean values whether a kinesthetic device allows x |
| | directional independent translation or not. , |
| Ty, | A Boolean values whether a kinesthetic device allows y |
| | directional independent translation or not., |
| Tz, | A Boolean values whether a kinesthetic device allows z |
| | directional independent translation or not., |
| Rx, | A Boolean values whether a kinesthetic device allows x |
| | directional independent rotation or not., |
| Ry, | A Boolean values whether a kinesthetic device allows y |
| | directional independent rotation or not., |
| Rz, | A Boolean values whether a kinesthetic device allows z |
| | directional independent rotation or not., |
| workspaceType, | Defines ranges where a kinesthetic device can translate and |
| | rotate. According to DOF (degree of freedom), three |
| | translational values(width, height, and depth) in mm(millimeter) |
| | and three rotational values(roll, pitch, and yaw) in degree are |
| | defined. , |
| Width, | Defines a maximum range in the unit of mm (millimeter) that a |
| | kinesthetic device can translate in x-axis., |
| Height, | Defines a maximum range in the unit of mm (millimeter) that a |
| | kinesthetic device can translate in y-axis., |
| Depth, | Defines a maximum range in the unit of mm (millimeter) that a |
| | kinesthetic device can translate in z-axis., |
| RotationX, | Defines a maximum range that a kinesthetic device can rotate in |
| | x-axis, φ (roll)., |
| RotationY, | Defines a maximum range that a kinesthetic device can rotate in |
| | y-axis, Θ(pitch)., |
| RotationZ, | Defines a maximum range that a kinesthetic device can rotate in |
| | z-axis, Ψ(yaw)., |

Table 47 shows an XML representation syntax regarding the rigid body motion type sensory device.

```
TABLE 47
  <!-- ################################################ -->
  <!-- Rigid Body Motion capability type -->
  <!-- ################################################ -->
  <complexType name=“RigidBodyMotionCapabilityType”>
    <complexContent>
      <extension base=“cidl:SensoryDeviceCapabilityBaseType”>
        <sequence>
          <element name=“MoveTowardCapability”
type=“dcdv:MoveTowardCapabilityType” minOccurs=“0”/>
          <element name=“InclineCapability”
type=“dcdv:InclineCapabilityType” minOccurs=“0”/>
        </sequence>
      </extension>
    </complexContent>
  </complexType>
  <!-- ################################################ -->
  <!-- MoveToward Capability type -->
  <!-- ################################################ -->
  <complexType name=“MoveTowardCapabilityType”>
    <attribute name=“MaxXDistance” type=“float” use=“optional”/>
    <attribute name=“MaxYDistance” type=“float” use=“optional”/>
    <attribute name=“MaxZDistance” type=“float” use=“optional”/>
    <attribute name=“distanceUnit” type=“mpegvct:unitType” use=“optional”/>
    <attribute name=“MaxXSpeed” type=“float” use=“optional”/>
    <attribute name=“MaxYSpeed” type=“float” use=“optional”/>
    <attribute name=“MaxZSpeed” type=“float” use=“optional”/>
    <attribute name=“speedUnit” type=“mpegvct:unitType” use=“optional”/>
    <attribute name=“MaxXAccel” type=“float” use=“optional”/>
    <attribute name=“MaxYAccel” type=“float” use=“optional”/>
    <attribute name=“MaxZAccel” type=“float” use=“optional”/>
    <attribute name=“accelUnit” type=“mpegvct:unitType” use=“optional”/>
    <attribute name=“XDistanceLevels” type=“nonNegativeInteger” use=“optional”/>
    <attribute name=“YDistanceLevels” type=“nonNegativeInteger” use=“optional”/>
    <attribute name=“ZDistanceLevels” type=“nonNegativeInteger” use=“optional”/>
    <attribute name=“XSpeedLevels” type=“nonNegativeInteger” use=“optional”/>
    <attribute name=“YSpeedLevels” type=“nonNegativeInteger” use=“optional”/>
    <attribute name=“ZSpeedLevels” type=“nonNegativeInteger” use=“optional”/>
    <attribute name=“XAccelLevels” type=“nonNegativeInteger” use=“optional”/>
    <attribute name=“YAccelLevels” type=“nonNegativeInteger” use=“optional”/>
    <attribute name=“ZAccelLevels” type=“nonNegativeInteger” use=“optional”/>
  </complexType>
  <!-- ################################################ -->
  <!-- Incline Capability type -->
  <!-- ################################################ -->
  <complexType name=“InclineCapabilityType”>
    <attribute name=“MaxPitchAngle” type=“mpegvct:InclineAngleType” use=“optional”/>
    <attribute name=“MaxYawAngle” type=“mpegvct:InclineAngleType” use=“optional”/>
    <attribute name=“MaxRollAngle” type=“mpegvct:InclineAngleType” use=“optional”/>
    <attribute name=“MaxPitchSpeed” type=“float” use=“optional”/>
    <attribute name=“MaxYawSpeed” type=“float” use=“optional”/>
    <attribute name=“MaxRollSpeed” type=“float” use=“optional”/>
    <attribute name=“speedUnit” type=“mpegvct:unitType” use=“optional”/>
    <attribute name=“MaxPitchAccel” type=“float” use=“optional”/>
    <attribute name=“MaxYawAccel” type=“float” use=“optional”/>
    <attribute name=“MaxRollAccel” type=“float” use=“optional”/>
    <attribute name=“accelUnit” type=“mpegvct:unitType” use=“optional”/>
    <attribute name=“PitchAngleLevels” type=“nonNegativeInteger” use=“optional”/>
    <attribute name=“YawAngleLevels” type=“nonNegativeInteger” use=“optional”/>
    <attribute name=“RollAngleLevels” type=“nonNegativeInteger” use=“optional”/>
    <attribute name=“PitchSpeedLevels” type=“nonNegativeInteger” use=“optional”/>
    <attribute name=“YawSpeedLevels” type=“nonNegativeInteger” use=“optional”/>
    <attribute name=“RollSpeedLevels” type=“nonNegativeInteger” use=“optional”/>
    <attribute name=“PitchAccelLevels” type=“nonNegativeInteger” use=“optional”/>
    <attribute name=“YawAccelLevels” type=“nonNegativeInteger” use=“optional”/>
    <attribute name=“RollAccelLevels” type=“nonNegativeInteger” use=“optional”/>
  </complexType>
```

Table 48 shows a binary representation syntax regarding the rigid body motion type sensory device.

TABLE 48

| RigidBodyMotionCapabilityType { | Number of bits | Mnemonic |
|---|---|---|
| MoveTowardCapabilityFlag | 1 | bslbf |
| InclineCapabilityFlag | 1 | bslbf |
| SensoryDeviceCapabilityBase | | SensoryDeviceCapabilityBaseType |
| if(MoveTowardCapabilityFlag){ | | |
| MoveTowardCapability | | MoveTowardCapabilityType |
| } | | |
| if(InclineCapabilityFlag){ | | |
| InclineCapability | | InclineCapabilityType |
| } | | |
| } | | |
| MoveTowardCapabilityType { | | |
| MaxXDistanceFlag | 1 | bslbf |
| MaxYDistanceFlag | 1 | bslbf |
| MaxZDistanceFlag | 1 | bslbf |
| distanceUnitFlag | 1 | bslbf |
| MaxXSpeedFlag | 1 | bslbf |
| MaxYSpeedFlag | 1 | bslbf |
| MaxZSpeedFlag | 1 | bslbf |
| speedUnitFlag | 1 | bslbf |
| MaxXAccelFlag | 1 | bslbf |
| MaxYAccelFlag | 1 | bslbf |
| MaxZAccelFlag | 1 | bslbf |
| accelUnitFlag | 1 | bslbf |
| XDistanceLevelsFlag | 1 | bslbf |
| YDistanceLevelsFlag | 1 | bslbf |
| ZDistanceLevelsFlag | 1 | bslbf |
| XSpeedLevelsFlag | 1 | bslbf |
| YSpeedLevelsFlag | 1 | bslbf |
| ZSpeedLevelsFlag | 1 | bslbf |
| XAccelLevelsFlag | 1 | bslbf |
| YAccelLevelsFlag | 1 | bslbf |
| ZAccelLevelsFlag | 1 | bslbf |
| if(MaxXDistanceFlag){ | | |
| MaxXDistance | 32 | fsbf |
| } | | |
| if(MaxYDistanceFlag){ | | |
| MaxYDistance | 32 | fsbf |
| } | | |
| if(MaxZDistanceFlag){ | | |
| MaxZDistance | 32 | fsbf |
| } | | |
| if(distanceUnitFlag){ | | |
| distanceUnit | | unitType |
| } | | |
| if(MaxXSpeedFlag){ | | |
| MaxXSpeed | 32 | fsbf |
| } | | |
| if(MaxYSpeedFlag){ | | |
| MaxYSpeed | 32 | fsbf |
| } | | |
| if(MaxZSpeedFlag){ | | |
| MaxZSpeed | 32 | fsbf |
| } | | |
| if(speedUnitFlag){ | | |
| speedUnit | | unitType |
| } | | |
| if(MaxXAccelFlag){ | | |
| MaxXAccel | 32 | fsbf |
| } | | |
| if(MaxYAccelFlag){ | | |
| MaxYAccel | 32 | fsbf |
| } | | |
| if(MaxZAccelFlag){ | | |
| MaxZAccel | 32 | fsbf |
| } | | |
| if(accelUnitFlag){ | | |
| accelUnit | | unitType |
| } | | |
| if(XDistanceLevelsFlag){ | | |
| XDistanceLevels | 8 | uimsbf |
| } | | |
| if(YDistanceLevelsFlag){ | | |
| YDistanceLevels | 8 | uimsbf |
| } | | |
| if(ZDistanceLevelsFlag){ | | |
| ZDistanceLevels | 8 | uimsbf |
| } | | |
| if(XSpeedLevelsFlag){ | | |
| XSpeedLevels | 8 | uimsbf |
| } | | |
| if(YSpeedLevelsFlag){ | | |
| YSpeedLevels | 8 | uimsbf |
| } | | |
| if(ZSpeedLevelsFlag){ | | |
| ZSpeedLevels | 8 | uimsbf |
| } | | |
| if(XAccelLevelsFlag){ | | |
| XAccelLevels | 8 | uimsbf |
| } | | |
| if(YAccelLevelsFlag){ | | |
| YAccelLevels | 8 | uimsbf |
| } | | |
| if(ZAccelLevelsFlag){ | | |
| ZAccelLevels | 8 | uimsbf |
| } | | |
| } | | |
| InclineCapabilityType { | | |
| MaxPitchAngleFlag | 1 | bslbf |
| MaxYawAngleFlag | 1 | bslbf |
| MaxRollAngleFlag | 1 | bslbf |
| MaxPitchSpeedFlag | 1 | bslbf |
| MaxYawSpeedFlag | 1 | bslbf |
| MaxRollSpeedFlag | 1 | bslbf |
| speedUnitFlag | 1 | bslbf |
| MaxPitchAccelFlag | 1 | bslbf |
| MaxYawAccelFlag | 1 | bslbf |
| MaxRollAccelFlag | 1 | bslbf |
| accelUnitFlag | 1 | bslbf |
| PitchAngleLevelsFlag | 1 | bslbf |
| YawAngleLevelsFlag | 1 | bslbf |
| RollAngleLevelsFlag | 1 | bslbf |
| PitchSpeedLevelsFlag | 1 | bslbf |
| YawSpeedLevelsFlag | 1 | bslbf |
| RollSpeedLevelsFlag | 1 | bslbf |
| PitchAccelLevelsFlag | 1 | bslbf |
| YawAccelLevelsFlag | 1 | bslbf |
| RollAccelLevelsFlag | 1 | bslbf |
| if(MaxPitchAngleFlag){ | | |
| MaxPitchAngle | | InclineAngleType |
| } | | |
| if(MaxYawAngleFlag){ | | |
| MaxYawAngle | | InclineAngleType |
| } | | |
| if(MaxRollAngleFlag){ | | |
| MaxRollAngle | | InclineAngleType |
| } | | |
| if(MaxPitchSpeedFlag){ | | |
| MaxPitchSpeed | 32 | fsbf |
| } | | |
| if(MaxYawSpeedFlag){ | | |
| MaxYawSpeed | 32 | fsbf |
| } | | |
| if(MaxRollSpeedFlag){ | | |
| MaxRollSpeed | 32 | fsbf |
| } | | |
| if(speedUnitFlag){ | | |
| speedUnit | | unitType |
| } | | |
| if(MaxPitchAccelFlag){ | | |
| MaxPitchAccel | 32 | fsbf |
| } | | |
| if(MaxYawAccelFlag){ | | |
| MaxYawAccel | 32 | fsbf |
| } | | |
| if(MaxRollAccelFlag){ | | |
| MaxRollAccel | 32 | fsbf |
| } | | |
| if(accelUnitFlag){ | | |
| accelUnit | | unitType |
| } | | |
| if(PitchAngleLevelsFlag){ | | |
| PitchAngleLevels | 8 | uimsbf |
| } | | |
| if(YawAngleLevelsFlag){ | | |
| YawAngleLevels | 8 | uimsbf |
| } | | |
| if(RollAngleLevelsFlag){ | | |
| RollAngleLevels | 8 | uimsbf |
| } | | |
| if(PitchSpeedLevelsFlag){ | | |
| PitchSpeedLevels | 8 | uimsbf |
| } | | |
| if(YawSpeedLevelsFlag){ | | |
| YawSpeedLevels | 8 | uimsbf |
| } | | |
| if(RollSpeedLevelsFlag){ | | |
| RollSpeedLevels | 8 | uimsbf |
| } | | |
| if(PitchAccelLevelsFlag){ | | |
| PitchAccelLevels | 8 | uimsbf |
| } | | |
| if(YawAccelLevelsFlag){ | | |
| YawAccelLevels | 8 | uimsbf |
| } | | |
| if(RollAccelLevelsFlag){ | | |
| RollAccelLevels | 8 | uimsbf |
| } | | |
| } | | |

Table 49 shows descriptor components semantics regarding the rigid body motion type sensory device.

TABLE 49

| Names, | Description, |
|---|---|
| RigidBodyMotionCapabilityType, | Tool for describing the capability of Rigid body motion effect., |
| MoveTowardCapabilityFlag, | This field, which is only present in the binary representation, |
| | signals the presence of the activation attribute. A value of “1” |
| | means the attribute shall be used and “0” means the attribute |
| | shall not be used., |
| InclineCapabilityFlag, | This field, which is only present in the binary representation, |
| | signals the presence of the activation attribute. A value of “1” |
| | means the attribute shall be used and “0” means the attribute |
| | shall not be used., |
| SensoryDeviceCapabilityBase, | SensoryDeviceCapabilityBase extends |
| | dia:TeminalCapabilityBaseType and provides a base |
| | abstract type for a subset of types defined as part of the |
| | sensory device capability metadata types. For details of |
| | dia:TerminalCapabilityBaseType, refer to the Part 7 of |
| | ISO/IEC 21000., |
| MoveTowardCapability, | Describes the capability for move toward motion effect., |
| InclineCapability, | Describes the capability for Incline motion effect., |
| MoveTowardCapabilityType, | Tool for describing a capability on move toward motion effect., |
| MaxXDistanceFlag, | This field, which is only present in the binary representation, |
| | signals the presence of the activation attribute. A value of “1” |
| | means the attribute shall be used and “0” means the attribute |
| | shall not be used., |
| MaxYDistanceFlag, | This field, which is only present in the binary representation, |
| | signals the presence of the activation attribute. A value of “1” |
| | means the attribute shall be used and “0” means the attribute |
| | shall not be used., |
| MaxZDistanceFlag, | This field, which is only present in the binary representation, |
| | signals the presence of the activation attribute. A value of “1” |
| | means the attribute shall be used and “0” means the attribute |
| | shall not be used., |
| distanceUnitFlag, | This field, which is only present in the binary representation, |
| | signals the presence of the activation attribute. A value of “1” |
| | means the attribute shall be used and “0” means the attribute |
| | shall not be used., |
| MaxXSpeedFlag, | This field, which is only present in the binary representation, |
| | signals the presence of the activation attribute. A value of “1” |
| | means the attribute shall be used and “0” means the attribute |
| | shall not be used., |
| MaxYSpeedFlag, | This field, which is only present in the binary representation, |
| | signals the presence of the activation attribute. A value of “1” |
| | means the attribute shall be used and “0” means the attribute |
| | shall not be used., |
| MaxZSpeedFlag, | This field, which is only present in the binary representation, |
| | signals the presence of the activation attribute. A value of “1” |
| | means the attribute shall be used and “0” means the attribute |
| | shall not be used., |
| speedUnitFlag, | This field, which is only present in the binary representation, |
| | signals the presence of the activation attribute. A value of “1” |
| | means the attribute shall be used and “0” means the attribute |
| | shall not be used., |
| MaxXAccelFlag, | This field, which is only present in the binary representation, |
| | signals the presence of the activation attribute. A value of “1” |
| | means the attribute shall be used and “0” means the attribute |
| | shall not be used., |
| MaxYAccelFlag, | This field, which is only present in the binary representation, |
| | signals the presence of the activation attribute. A value of “1” |
| | means the attribute shall be used and “0” means the attribute |
| | shall not be used., |
| MaxZAccelFlag, | This field, which is only present in the binary representation, |
| | signals the presence of the activation attribute. A value of “1” |
| | means the attribute shall be used and “0” means the attribute |
| | shall not be used., |
| accelUnitFlag, | This field, which is only present in the binary representation, |
| | signals the presence of the activation attribute. A value of “1” |
| | means the attribute shall be used and “0” means the attribute |
| | shall not be used., |
| XDistanceLevelsFlag, | This field, which is only present in the binary representation, |
| | signals the presence of the activation attribute. A value of “1” |
| | means the attribute shall be used and “0” means the attribute |
| | shall not be used., |
| YDistanceLevelsFlag, | This field, which is only present in the binary representation, |
| | signals the presence of the activation attribute. A value of “1” |
| | means the attribute shall be used and “0” means the attribute |
| | shall not be used., |
| ZDistanceLevelsFlag, | This field, which is only present in the binary representation, |
| | signals the presence of the activation attribute. A value of “1” |
| | means the attribute shall be used and “0” means the attribute |
| | shall not be used., |
| XSpeedLevelsFlag, | This field, which is only present in the binary representation, |
| | signals the presence of the activation attribute. A value of “1” |
| | means the attribute shall be used and “0” means the attribute |
| | shall not be used., |
| YSpeedLevelsFlag, | This field, which is only present in the binary representation, |
| | signals the presence of the activation attribute. A value of “1” |
| | means the attribute shall be used and “0” means the attribute |
| | shall not be used., |
| ZSpeedLevelsFlag, | This field, which is only present in the binary representation, |
| | signals the presence of the activation attribute. A value of “1” |
| | means the attribute shall be used and “0” means the attribute |
| | shall not be used., |
| XAccelLevelsFlag, | This field, which is only present in the binary representation, |
| | signals the presence of the activation attribute. A value of “1” |
| | means the attribute shall be used and “0” means the attribute |
| | shall not be used., |
| YAccelLevelsFlag, | This field, which is only present in the binary representation, |
| | signals the presence of the activation attribute. A value of “1” |
| | means the attribute shall be used and “0” means the attribute |
| | shall not be used., |
| ZAccelLevelsFlag, | This field, which is only present in the binary representation, |
| | signals the presence of the activation attribute. A value of “1” |
| | means the attribute shall be used and “0” means the attribute |
| | shall not be used., |
| MaxXDistance, | Describes the maximum distance on x-axis that the device can |
| | provide in terms of centimeter., |
| | EXAMPLE The value ‘10’ means the device can move maximum 10 cm on x- |
| | axis., |
| | NOTE The value 0 means the device can't provide x-axis movement., |
| MaxYDistance, | Describes the maximum distance on y-axis that the device can |
| | provide in terms of centimeter., |
| MaxZDistance, | Describes the maximum distance on z-axis that the device can |
| | provide in terms of centimeter., |
| distanceUnit, | Specifies the unit of the description of MaxXDistance, |
| | MaxYDistance, and MaxZDistance attributes as a reference |
| | to a classification scheme term provided by UnitTypeCS defined |
| | in A.2.1 of ISO/IEC 23005-6, if any unit other than cm |
| | (centimeter) is used. These three attributes shall have the same |
| | unit., |
| MaxXSpeed, | Describes the maximum speed on x-axis that the device can |
| | provide in terms of centimeter per second., |
| MaxYSpeed, | Describes the maximum speed on y-axis that the device can |
| | provide in terms of centimeter per second., |
| MaxZSpeed, | Describes the maximum speed on z-axis that the device can |
| | provide in terms of centimeter per second., |
| speedUnit, | Specifies the unit of the description of MaxXSpeed, |
| | MaxYSpeed, and MaxZSpeed attributes as a reference to a |
| | classification scheme term provided by UnitTypeCS defined in |
| | A.2.1 of ISO/IEC 23005-6, if any unit other than cm/sec |
| | (centimeter per second) is used. These three attributes shall |
| | have the same unit., |
| MaxXAccel, | Describes the maximum acceleration on x-axis that the device |
| | can provide in terms of centimeter per square second., |
| MaxYAccel, | Describes the maximum acceleration on y-axis that the device |
| | can provide in terms of centimeter per square second., |
| MaxZAccel, | Describes the maximum acceleration on z-axis that the device |
| | can provide in terms of centimeter per second square., |
| accelUnit, | Specifies the unit of the description of MaxXAccel, |
| | MaxYAccel, and MaxZAccel attributes as a reference to a |
| | classification scheme term provided by UnitTypeCS defined in |
| | A.2.1 of ISO/IEC 23005-6, if any unit other than cm/sec, |
| | (centimeter per second square) is used. These three attributes |
| | shall have the same unit., |
| XDistanceLevels, | Describes the number of distance levels that the device can |
| | provide in between maximum and minimum distance on x-axis., |
| | EXAMPLE The value 5 means the device can provide 5 steps |
| | from minimum to maximum distance in x-axis., |
| YDistanceLevels, | Describes the number of distance levels that the device can |
| | provide in between maximum and minimum distance on y-axis., |
| ZDistanceLevels, | Describes the number of distance levels that the device can |
| | provide in between maximum and minimum distance on z-axis., |
| XSpeedLevels, | Describes the number of speed levels that the device can |
| | provide in between maximum and minimum speed on x-axis., |
| YSpeedLevels, | Describes the number of speed levels that the device can |
| | provide in between maximum and minimum speed on y-axis., |
| ZSpeedLevels, | Describes the number of speed levels that the device can |
| | provide in between maximum and minimum speed on z-axis., |
| XAccelLevels, | Describes the number of acceleration that the device can |
| | provide in between maximum and minimum acceleration on x- |
| | axis., |
| YAccelLevels, | Describes the number of acceleration that the device can |
| | provide in between maximum and minimum acceleration on y- |
| | axis., |
| ZAccelLevels, | Describes the number of acceleration that the device can |
| | provide in between maximum and minimum acceleration on z- |
| | axis., |
| InclineCapabilityType, | Tool for describing a capability on move toward motion effect., |
| MaxPitchAngleFlag, | This field, which is only present in the binary representation, |
| | signals the presence of the activation attribute. A value of “1” |
| | means the attribute shall be used and “0” means the attribute |
| | shall not be used., |
| MaxYawAngleFlag, | This field, which is only present to the binary representation, |
| | signals the presence of the activation attribute. A value of “1” |
| | means the attribute shall be used and “0” means the attribute |
| | shall not be used., |
| MaxRollAngleFlag, | This field, which is only present in the binary representation, |
| | signals the presence of the activation attribute. A value of “1” |
| | means the attribute shall be used and “0” means the attribute |
| | shall not be used., |
| MaxPitchSpeedFlag, | This field, which is only present in the binary representation, |
| | signals the presence of the activation attribute. A value of “1” |
| | means the attribute shall be used and “0” means the attribute |
| | shall not be used., |
| MaxYawSpeedFlag, | This field, which is only present in the binary representation, |
| | signals the presence of the activation attribute. A value of “1” |
| | means the attribute shall be used and “0” means the attribute |
| | shall not be used., |
| MaxRollSpeedFlag, | This field, which is only present in the binary representation, |
| | signals the presence of the activation attribute. A value of “1” |
| | means the attribute shall be used and “0” means the attribute |
| | shall not be used., |
| speedUnitFlag, | This field, which is only present in the binary representation, |
| | signals the presence of the activation attribute. A value of “1” |
| | means the attribute shall be used and “0” means the attribute |
| | shall not be used., |
| MaxPitchAccelFlag, | This field, which is only present in the binary representation, |
| | signals the presence of the activation attribute. A value of “1” |
| | means the attribute shall be used and “0” means the attribute |
| | shall not be used., |
| MaxYawAccelFlag, | This field, which is only present in the binary representation, |
| | signals the presence of the activation attribute. A value of “1” |
| | means the attribute shall be used and “0” means the attribute |
| | shall not be used., |
| MaxRollAccelFlag, | This field, which is only present in the binary representation, |
| | signals the presence of the activation attribute. A value of “1” |
| | means the attribute shall be used and “0” means the attribute |
| | shall not be used., |
| accelUnitFlag, | This field, which is only present in the binary representation, |
| | signals the presence of the activation attribute. A value of “1” |
| | means the attribute shall be used and “0” means the attribute |
| | shall not be used., |
| PitchAngleLevelsFlag, | This field, which is only present in the binary representation, |
| | signals the presence of the activation attribute. A value of “1” |
| | means the attribute shall be used and “0” means the attribute |
| | shall not be used., |
| YawAngleLevelsFlag, | This field, which is only present in the binary representation, |
| | signals the presence of the activation attribute. A value of “1” |
| | means the attribute shall be used and “0” means the attribute |
| | shall not be used., |
| RollAngleLevelsFlag, | This field, which is only present in the binary representation, |
| | signals the presence of the activation attribute. A value of “1” |
| | means the attribute shall be used and “0” means the attribute |
| | shall not be used., |
| PitchSpeedLevelsFlag, | This field, which is only present in the binary representation, |
| | signals the presence of the activation attribute. A value of “1” |
| | means the attribute shall be used and “0” means the attribute |
| | shall not be used., |
| YawSpeedLevelsFlag, | This field, which is only present in the binary representation, |
| | signals the presence of the activation attribute. A value of “1” |
| | means the attribute shall be used and “0” means the attribute |
| | shall not be used., |
| RollSpeedLevelsFlag, | This field, which is only present in the binary representation, |
| | signals the presence of the activation attribute. A value of “1” |
| | means the attribute shall be used and “0” means the attribute |
| | shall not be used., |
| PitchAccelLevelsFlag, | This field, which is only present in the binary representation, |
| | signals the presence of the activation attribute. A value of “1” |
| | means the attribute shall be used and “0” means the attribute |
| | shall not be used., |
| YawAccelLevelsFlag, | This field, which is only present in the binary representation, |
| | signals the presence of the activation attribute. A value of “1” |
| | means the attribute shall be used and “0” means the attribute |
| | shall not be used., |
| RollAccelLevelsFlag, | This field, which is only present in the binary representation, |
| | signals the presence of the activation attribute. A value of “1” |
| | means the attribute shall be used and “0” means the attribute |
| | shall not be used., |
| MaxPitchAngle, | Describes the maximum angle of x-axis rotation in degrees that |
| | the device can provide., |
| | NOTE The rotation angle is increased with counter-clock wise., |
| MaxYawAngle, | Describes the maximum angle of y-axis rotation in degrees that |
| | the device can provide., |
| | NOTE The rotation angle is increased with clock wise., |
| MaxRollAngle, | Describes the maximum angle of z-axis rotation in degrees that |
| | the device can provide., |
| | NOTE The rotation angle is increased with counter-clock wise., |
| MaxPitchSpeed, | Describes the maximum speed of x-axis rotation that the device |
| | can provide in terms of degree per second., |
| MaxYawSpeed, | Describes the maximum speed of y-axis rotation that the device |
| | can provide in terms of degree per second., |
| MaxRollSpeed, | Describes the maximum speed of z-axis rotation that the device |
| | can provide in terms of degree per second., |
| speedUnit, | Specifies the common unit of the description of |
| | MaxPitchSpeed, MaxYawSpeed, and MaxRollSpeed attributes |
| | as a reference to a classification scheme term provided by |
| | UnitTypeCS defined in A.2.1 of ISO/IEC 23005-6, if any unit |
| | other than degreeper sencod is used., |
| MaxPitchAccel, | Describes the maximum acceleration of x-axis rotation that the |
| | device can provide in terms of degree per second square., |
| MaxYawAccel, | Describes the maximum acceleration of y-axis rotation that the |
| | device can provide in terms of degree per second square., |
| MaxRollAccel, | Describes the maximum acceleration of z-axis rotation that the |
| | device can provide in terms of degree per second square., |
| accelUnit, | Specifies the common unit of the description of |
| | MaxPitchAccel, MaxYawAccel, and MaxRollAccel attributes |
| | as a reference to a classification scheme term provided by |
| | UnitTypeCS defined in A.2.1 of ISO/IEC 23005-6, if any unit |
| | other than degree per sencod square is used., |
| PitchAngleLevels, | Describes the number of rotation angle levels that the device |
| | can provide in between maximum and minimum angle of x-axis |
| | rotation., |
| | EXAMPLE The value 5 means the device can provide 5 steps |
| | from minimum to maximum rotation angle on x-axis., |
| YawAngleLevels, | Describes the number of rotation angle levels that the device |
| | can provide in between maximum and minimum angle of y-axis |
| | rotation., |
| RollAngleLevels, | Describes the number of rotation angle levels that the device |
| | can provide in between maximum and minimum angle of z-axis |
| | rotation., |
| PitchSpeedLevels, | Describes the number of rotation speed levels that the device |
| | can provide in between maximum and minimum speed of x-axis |
| | rotation., |
| | EXAMPLE The value 5 means the device can provide 5 steps |
| | from minimum to maximum rotation angle on x-axis., |
| YawSpeedLevels, | Describes the number of rotation speed levels that the device |
| | can provide in between maximum and minimum speed of y-axis |
| | rotation., |
| RollSpeedLevels, | Describes the number of rotation speed levels that the device |
| | can provide in between maximum and minimum speed of z-axis |
| | rotation., |
| PitchAccelLevels, | Describes the number of rotation acceleration levels that the |
| | device can provide in between maximum and minimum |
| | acceleration of x-axis rotation., |
| YawAccelLevels, | Describes the number of rotation acceleration levels that the |
| | device can provide in between maximum and minimum |
| | acceleration of y-axis rotation., |
| RollAccelLevels, | Describes the number of rotation acceleration levels that the |
| | device can provide in between maximum and minimum |
| | acceleration of z-axis rotation., |

The encoding unit 533 may encode preference information, that is, information on a user preference with respect to a sensory effect, into USP metadata. That is, the encoding unit 533 may generate USP metadata by encoding the preference information. The encoding unit 533 may include at least one of an XML encoder and a binary encoder.

According to embodiments, the encoding unit 533 may generate the USP metadata by encoding the preference information into XML metadata.

Also, the encoding unit 533 may generate the USP metadata by encoding the preference information into binary metadata.

In addition, the encoding unit 533 may generate fourth metadata by encoding the preference information into XML metadata, and generate the USP metadata by encoding the fourth metadata into binary metadata.

The sensory device 530 may further include an input unit 534.

The input unit 534 may be input with the preference information from the user of the sensory device 530.

The USP metadata may include USP base type which denotes basic information on a preference of the user with respect to the sensory effect. The sensory device preference base type may be metadata regarding the preference information commonly applied to all types of the sensory device 530.

Table 50 shows an XML representation syntax regarding the USP base type.

```
TABLE 50
<!-- ################################################ -->
<!-- UserSensory Preference base type -->
<!-- ################################################ -->
<complexType name=“UserSensoryPreferenceBaseType” abstract=“true”>
  <complexContent>
    <extension base=“dia:UserCharacteristicBaseType”>
      <attributeGroup ref=“cidl:userSensoryPrefBaseAttributes”/>
    </extension>
  </complexContent>
</complexType>
```

Table 51 shows a binary representation syntax regarding the USP base type.

TABLE 51

| UserSensoryPreferenceBaseType { | Number of bits | Mnemonic |
|---|---|---|
| UserCharacteristicBase | | UserCharacteristicBaseType |
| userSensoryPrefBaseAttributes | | userSensoryPrefBaseAttributesType |
| } | | |

Table 52 shows descriptor components semantics regarding the USP base type.

TABLE 52

| Names [symbol] | Description [symbol] |
|---|---|
| UserSensoryPreferenceBaseType [symbol] | UserSensoryPreferenceBaseType |
| | extends |
| | dia:UserCharacteristicBaseType |
| | as defined in Part 7 of ISO/IEC |
| | 21000 and provides a base abstract |
| | type for a subset of types defined |
| | as part of the sensory device |
| | capability metadata types. [symbol] |
| UserCharacteristicBase [symbol] | [symbol] |
| userSensoryPrefBaseAttributes [symbol] | Describes a group of common |
| | attributes for the describing user |
| | preferences on sensory experience. [symbol] |

The USP metadata may include USP base attributes which denote groups regarding common attributes of the sensory device 530.

Table 53 shows an XML representation syntax regarding the USP base attributes.

```
TABLE 53
<!-- ################################################  -->
<!-- User Sensory Preference Base Attributes -->
<!-- ################################################  -->
<attributeGroup name=“userSensoryPrefBaseAttributes”>
  <attribute name=“adaptationMode” type=“cidl:adaptationModeType”
  use=“optional”/>
  <attribute name=“activate” type=“boolean” use=“optional”/>
</attributeGroup>
<!-- User Preference of Adaptation Mode Types  -->
<simpleType name=“adaptationModeType”>
  <restriction base=“string”>
      <enumeration value=“strict”/>
      <enumeration value=“scalable”/>
  </restriction>
</simpleType>
```

Table 54 shows a binary representation syntax regarding the USP base attributes.

TABLE 54

| | Number | |
|---|---|---|
| userSensoryPrefBaseAttributesType { | of bits | Mnemonic |
| adaptationModeFlag | 1 | bslbf |
| activateFlag | 1 | bslbf |
| if(adaptationModeFlag){ | | |
| adaptationMode | | adaptationModeType |
| } | | |
| if(activateFlag){ | | |
| activate | 1 | bslbf |
| } | | |
| } | | |
| adaptationModeType { | | |
| adaptationMode | 2 | bslbf |
| } | | |

Table 55 shows an adaptation mode type regarding the USP base attributes.

TABLE 55

| adaptationModeType [symbol] | adaptationMode [symbol] |
|---|---|
| 00 [symbol] | strict [symbol] |
| 01 [symbol] | scalable [symbol] |
| 10-11 [symbol] | Reserved [symbol] |

Table 56 shows descriptor components semantics regarding the USP base attributes.

TABLE 56

| Names [symbol] | Description [symbol] |
|---|---|
| userSensoryPrefBaseAttributesType [symbol] | Describes a group of common attributes for the describing |
| | user preferences on sensory experience. [symbol] |
| adaptationModeFlag [symbol] | This field, which is only present in the binary representation, |
| | signals the presence of the activation attribute. A value of |
| | “1” means the attribute shall be used and “0” means the |
| | attribute shall not be used. [symbol] |
| activateFlag [symbol] | This field, which is only present in the binary representation, |
| | signals the presence of the activation attribute. A value of |
| | “1” means the attribute shall be used and “0” means the |
| | attribute shall not be used. [symbol] |
| adaptationMode [symbol] | Describes the user's preference on the adaptation method for |
| | the sensory effect. [symbol] |
| | EXAMPLE The value “strict” means the user prefer to |
| | render sensory effect exactly as described. Otherwise the |
| | value “scalable” means to render sensory effect with scaled |
| | intensity according to the device capacity. [symbol] |
| activate [symbol] | Describes whether the effect shall be activated. A value of |
| | true means the effect shall be activated and false means the |
| | effect shall be deactivated. [symbol] |
| adaptationModeType [symbol] | Tool for describing the adaptation mode with enumeration set. |
| | When its value is strict, it means that when the input value |
| | is out of range, the output should be equal to the maximum |
| | value that the device is able to operate. When its value is |
| | scalable, it means that the output shall be linearly scaled |
| | into the range that the device can operate. [symbol] |

Hereinafter, the preference information regarding each type of the sensory device 530 will be described in detail.

Table 57 shows an XML representation syntax of the preference information regarding the light type sensory device according to example embodiments.

```
TABLE 57
  <!-- ################################################ -->
  <!-- Light Preference type -->
  <!-- ################################################ -->
  <complexType name=“LightPrefType”>
    <complexContent>
        <extension base=“cidl:UserSensoryPreferenceBaseType”>
            <sequence>
                <element name=“UnfavorableColor”
type=“mpegvct:colorType” minOccurs=“0”
maxOccurs=“unbounded”/>
            </sequence>
            <attribute name=“maxIntensity” type=“integer”
            use=“optional”/>
            <attribute name=“unit” type=“mpegvct:unitType”
            use=“optional”/>
        </extension>
    </complexContent>
  </complexType>
```

Table 58 shows a binary representation syntax of the preference information regarding the light type sensory device according to embodiments.

TABLE 58

| | | Number | |
|---|---|---|---|
| LightPrefType { | | of bits | Mnemonic |
| UnfavorableColorFlag | | 1 | bslbf |
| | maxIntensityFlag | 1 | bslbf |

| | | |
|---|---|---|
| unitFlag | 1 | bslbf |

| | |
|---|---|
| UserSensoryPreferenceBase | UserSensoryPreferenceBaseType |

if(UnfavorableColorFlag){

| | |
|---|---|
| LoopUnfavorableColor | vluimsbf5 |

for(k=0;k<

LoopUnfavorableColor;k++){

| | |
|---|---|
| UnfavorableColor[k] | ColorType |

}

}

if(maxIntensityFlag){

| | | |
|---|---|---|
| maxIntensity | 10 | simsbf |

}
if(unitFlag){

| | |
|---|---|
| unit | unitType |

}

}

Table 59 shows a binary representation syntax of a unit CS.

TABLE 59

| unitType [symbol] | Term ID of unit [symbol] |
|---|---|
| 00000000 [symbol] | micrometer [symbol] |
| 00000001 [symbol] | mm [symbol] |
| 00000010 [symbol] | cm [symbol] |
| 00000011 [symbol] | meter [symbol] |
| 00000100 [symbol] | km [symbol] |
| 00000101 [symbol] | inch [symbol] |
| 00000110 [symbol] | yard [symbol] |
| 00000111 [symbol] | mile [symbol] |
| 00001000 [symbol] | mg [symbol] |
| 00001001 [symbol] | gram [symbol] |
| 00001010 [symbol] | kg [symbol] |
| 00001011 [symbol] | ton [symbol] |
| 00001100 [symbol] | micrometerpersec [symbol] |
| 00001101 [symbol] | mmpersec [symbol] |
| 00001110 [symbol] | cmpersec [symbol] |
| 00001111 [symbol] | meterpersec [symbol] |
| 00010000 [symbol] | Kmpersec [symbol] |
| 00010001 [symbol] | inchpersec [symbol] |
| 00010010 [symbol] | yardpersec [symbol] |
| 00010011 [symbol] | milepersec [symbol] |
| 00010100 [symbol] | micrometerpermin [symbol] |
| 00010101 [symbol] | mmpermin [symbol] |
| 00010110 [symbol] | cmpermin [symbol] |
| 00010111 [symbol] | meterpermin [symbol] |
| 00011000 [symbol] | kmpermin [symbol] |
| 00011001 [symbol] | inchpermin [symbol] |
| 00011010 [symbol] | yardpermin [symbol] |
| 00011011 [symbol] | milepermin [symbol] |
| 00011100 [symbol] | micrometerperhour [symbol] |
| 00011101 [symbol] | mmperhour [symbol] |
| 00011110 [symbol] | cmperhour [symbol] |
| 00011111 [symbol] | meterperhour [symbol] |
| 00100000 [symbol] | kmperhour [symbol] |
| 00100001 [symbol] | inchperhour [symbol] |
| 00100010 [symbol] | yardperhour [symbol] |
| 00100011 [symbol] | mileperhour [symbol] |
| 00100100 [symbol] | micrometerpersecsquare [symbol] |
| 00100101 [symbol] | mmpersecsquare [symbol] |
| 00100110 [symbol] | cmpersecsquare [symbol] |
| 00100111 [symbol] | meterpersecsquare [symbol] |
| 00101000 [symbol] | kmpersecsquare [symbol] |
| 00101001 [symbol] | inchpersecsquare [symbol] |
| 00101010 [symbol] | yardpersecsquare [symbol] |
| 00101011 [symbol] | milepersecsquare [symbol] |
| 00101100 [symbol] | micormeterperminsquare [symbol] |
| 00101101 [symbol] | mmperminsquare [symbol] |
| 00101110 [symbol] | cmperminsquare [symbol] |
| 00101111 [symbol] | meterperminsquare [symbol] |
| 00110000 [symbol] | kmpersminsquare [symbol] |
| 00110001 [symbol] | inchperminsquare [symbol] |
| 00110010 [symbol] | yardperminsquare [symbol] |
| 00111011 [symbol] | mileperhoursquare [symbol] |
| 00111100 [symbol] | Newton [symbol] |
| 00111101 [symbol] | Nmm [symbol] |
| 00111110 [symbol] | Npmm [symbol] |
| 00111111 [symbol] | Hz [symbol] |
| 01000000 [symbol] | KHz [symbol] |
| 01000001 [symbol] | MHz [symbol] |
| 01000010 [symbol] | GHz [symbol] |
| 01000011 [symbol] | volt [symbol] |
| 01000100 [symbol] | millivolt [symbol] |
| 01000101 [symbol] | ampere [symbol] |
| 01000110 [symbol] | milliampere [symbol] |
| 01000111 [symbol] | milliwatt [symbol] |
| 01001000 [symbol] | watt [symbol] |
| 01001001 [symbol] | kilowatt [symbol] |
| 01001010 [symbol] | lux [symbol] |
| 01001011 [symbol] | celsius [symbol] |
| 01001100 [symbol] | fahrenheit [symbol] |
| 01001101 [symbol] | radian [symbol] |
| 01001110 [symbol] | degree [symbol] |
| 01001111 [symbol] | radpersec [symbol] |
| 01010000 [symbol] | degpersec [symbol] |
| 01010001 [symbol] | radpersecsquare [symbol] |
| 01010010 [symbol] | degpersecsquare [symbol] |
| 01010011 [symbol] | Npermmsquare [symbol] |
| 01011100-11111111 [symbol] | Reserved [symbol] |

Table 60 shows descriptor components semantics of the preference information regarding the light type sensory device.

TABLE 60

| Names [symbol] | Description [symbol] |
|---|---|
| LightPrefType [symbol] | Tool for describing a user preference on light effect. [symbol] |
| UnfavorableColorFlag [symbol] | This field, which is only present in the binary representation, |
| | signals the presence of the activation attribute. A value of “1” |
| | means the attribute shall be used and “0” means the attribute |
| | shall not be used. [symbol] |
| maxIntensityFlag [symbol] | This field, which is only present in the binary representation, |
| | signals the presence of the activation attribute, A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute, |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| LoopUnfavorableColor [symbol] | This field, which is only present in the. binary representation, |
| | specifies the number of UnfavorableColor contained in the |
| | description. [symbol] |
| UnfavorableColor [symbol] | Describes the list of user's detestable colors as a reference to a |
| | classification scheme term or as RGB value. A CS that may be |
| | used for this purpose is the ColorCS defined in A.2.2 of ISO/IEC |
| | 23005-6. [symbol] |
| | EXAMPLE urn:mpeg:mpeg-v:01-SI-ColorCS-NS:alice_blue would |
| | describe the color Alice blue. [symbol] |
| maxIntensity [symbol] | Describes the maximum desirable intensity of the light effect in |
| | terms of illumination with respect to [10⁻⁵ lux, 130 klux]. [symbol] |
| unit [symbol] | Specifies the unit of the maxIntensity value as a reference to |
| | a classification scheme term provided by UnitTypeCS defined in |
| | A.2.1 of ISO/IEC 23005-6, if a unit other than the default unit |
| | specified in the semantics of the maxIntensity is used. [symbol] |

Table 61 shows an XML representation syntax of the preference information regarding the flash type sensory device.

```
TABLE 61
<!-- ################################################ -->
<!-- Flash Preference type -->
<!-- ################################################ -->
<complexType name=“FlashPrefType”>
    <complexContent>
        <extension base=“sepv:LightPrefType”>
            <attribute name=“maxFrequency” type=“positiveInteger”
            use=“optional”/>
            <attribute name=“freqUnit” type=“mpegvct:unitType”
            use=“optional”/>
        </extension>
    </complexContent>
</complexType>
```

Table 62 shows a binary representation syntax of the preference information regarding the flash type sensory device.

TABLE 62

| | | |
|---|---|---|
| | Number | |
| FlashPrefType { | of bits | Mnemonic |

| | | |
|---|---|---|
| maxFrequencyFlag | 1 | bslbf |

| | | |
|---|---|---|
| freqUnitFlag | 1 | bslbf |

| | |
|---|---|
| LightPref | LightPrefType |

if(maxFrequencyFlag){

| | | |
|---|---|---|
| maxFrequency | 8 | uimsbf |

}
if(freqUnitFlag){

| | |
|---|---|
| freqUnit | unitType |

}

}

Table 63 shows descriptor components semantics of the preference information regarding the flash type sensory device.

TABLE 63

| Names [symbol] | Description [symbol] |
|---|---|
| FlashPrefType [symbol] | Tool for describing a user preference on light effect. [symbol] |
| maxFrequencyFlag [symbol] | This field, which is only present in the binary representation, |
| | signals the presence of the. activation attribute. A value of “1” |
| | means the attribute shall be used and “0” means the attribute |
| | shall not be used. [symbol] |
| freqUnitFlag [symbol] | This field, which is only present in the binary representation, |
| | signals the presence of the activation attribute. A value of “1” |
| | means the attribute shall be used and “0” means the attribute |
| | shall not be used. [symbol] |
| LightPref [symbol] | Describes a user preference on light effect. [symbol] |
| maxFrequency [symbol] | Describes the maximum allowed number of flickering in times |
| | per second. [symbol] |
| | EXAMPLE The value 10 means it will flicker 10 times for |
| | each second. [symbol] |
| freqUnit [symbol] | Specifies the unit of the maxFrequency value as a reference to |
| | a classification scheme term provided by UnitTypeCS defined in |
| | A.2.1 of ISO/IEC 23005-6, if a unit other than the default unit |
| | specified in the semantics of the maxFrequency is used. [symbol] |

Table 64 shows an XML representation syntax of the preference information regarding the heating type sensory device.

```
TABLE 64
<!-- ################################################ -->
<!-- Heating Preference type -->
<!-- ################################################ -->
<complexType name=“HeatingPrefType”>
    <complexContent>
        <extension base=“cidl:UserSensoryPreferenceBaseType”>
            <attribute name=“minIntensity” type=“integer”
            use=“optional”/>
            <attribute name=“maxIntensity” type=“integer”
            use=“optional”/>
            <attribute name=“unit” type=“mpegvct:unitType”
            use=“optional”/>
        </extension>
    </complexContent>
</complexType>
```

Table 65 shows a binary representation syntax of the preference information regarding the heating type sensory device.

TABLE 65

| | | Number | |
|---|---|---|---|
| Heating PrefType { | | of bits | Mnemonic |
| | minIntensityFlag | 1 | bslbf |

| | | |
|---|---|---|
| maxIntensityFlag | 1 | bslbf |
| unitFlag | 1 | bslbf |

| | |
|---|---|
| UserSensoryPreferenceBase | UserSensoryPreferenceBaseType |

if(minIntensityFlag){

| | | |
|---|---|---|
| minIntensity | 10 | simsbf |

}
if(maxIntensityFlag){

| | | |
|---|---|---|
| maxIntensity | 10 | simsbf |

}
if(unitFlag){

| | |
|---|---|
| unit | unitType |

}

}

Table 66 shows descriptor components semantics of the preference information regarding the heating type sensory device.

TABLE 66

| Names [symbol] | Description [symbol] |
|---|---|
| HeatingPrefType [symbol] | Tool for describing a user preference on heating effect. [symbol] |
| minIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| maxIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| minIntensity [symbol] | Describes the highest desirable temperature of the heating |
| | effect with respect to the Celsius scale (or Fahrenheit). [symbol] |
| maxIntensity [symbol] | Describes the lowest desirable temperature of the heating effect |
| | with respect to the Celsius scale (or Fahrenheit). [symbol] |
| unit [symbol] | Specifies the unit of the maxIntensity and minIntensity |
| | value as a reference to a classification scheme term provided by |
| | UnitTypeCS defined in A.2.1 of ISO/IEC 23005-6. [symbol] |

Table 67 shows an XML representation syntax of the preference information regarding the cooling type sensory device.

```
TABLE 67
<!-- ################################################ -->
<!-- Cooling Preference type -->
<!-- ################################################ -->
<complexType name=“CoolingPrefType”>
    <complexContent>
        <extension base=“cidl:UserSensoryPreferenceBaseType”>
            <attribute name=“minIntensity” type=“integer”
            use=“optional”/>
            <attribute name=“maxIntensity” type=“integer”
            use=“optional”/>
            <attribute name=“unit” type=“mpegvct:unitType”
            use=“optional”/>
        </extension>
    </complexContent>
</complexType>
```

Table 68 shows a binary representation syntax of the preference information regarding the cooling type sensory device.

TABLE 68

| | | Number | |
|---|---|---|---|
| CoolingPrefType { | | of bits | Mnemonic |
| | minIntensityFlag | 1 | bslbf |

| | | |
|---|---|---|
| maxIntensityFlag | 1 | bslbf |
| unitFlag | 1 | bslbf |

| | |
|---|---|
| UserSensoryPreferenceBase | UserSensoryPreferenceBaseType |

if(minIntensityFlag){

| | | |
|---|---|---|
| minIntensity | 10 | simsbf |

}
if(maxIntensityFlag){

| | | |
|---|---|---|
| maxIntensity | 10 | simsbf |

}
if(unitFlag){

| | |
|---|---|
| unit | unitType |

}

}

Table 69 shows descriptor components semantics of the preference information regarding the cooling type sensory device.

TABLE 69

| Names [symbol] | Description [symbol] |
|---|---|
| CoolingPrefType [symbol] | Tool for describing a user preference on cooling effect. [symbol] |
| minIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| maxIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| minIntensity [symbol] | Describes the lowest desirable temperature of the cooling effect |
| | with respect to the Celsius scale (or Fahrenheit). [symbol] |
| maxIntensity [symbol] | Describes the highest desirable temperature of the cooling |
| | effect with respect to the Celsius scale (or Fahrenheit). [symbol] |
| unit [symbol] | Specifies the unit of the maxIntensity and minIntensity |
| | value as a reference to a classification scheme term provided by |
| | UnitTypeCS defined in A.2.1 of ISO/IEC 23005-6. [symbol] |

Table 70 shows an XML representation syntax of the preference information regarding the wind type sensory device.

```
TABLE 70
<!-- ################################################ -->
<!-- Wind Preference type -->
<!-- ################################################ -->
<complexType name=“WindPrefType”>
    <complexContent>
        <extension base=“cidl:UserSensoryPreferenceBaseType”>
            <attribute name=“maxIntensity” type=“integer”
            use=“optional”/>
            <attribute name=“unit” type=“mpegvct:unitType”
            use=“optional”/>
        </extension>
    </complexContent>
</complexType>
```

Table 71 shows a binary representation syntax of the preference information regarding the wind type sensory device.

TABLE 71

| | | Number | |
|---|---|---|---|
| WindPrefType { | | of bits | Mnemonic |
| | maxIntensityFlag | 1 | bslbf |
| | unitFlag | 1 | bslbf |

| | |
|---|---|
| UserSensoryPreferenceBase | UserSensoryPreferenceBaseType |

if(maxIntensityFlag){

| | | |
|---|---|---|
| maxIntensity | 10 | simsbf |

}
if(unitFlag){

| | |
|---|---|
| unit | unitType |

}

}

Table 72 shows descriptor components semantics of the preference information regarding the wind type sensory device.

TABLE 72

| Names [symbol] | Description [symbol] |
|---|---|
| WindPrefType [symbol] | Tool for describing a user preference on a wind effect. [symbol] |
| maxIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| maxIntensity [symbol] | Describes the maximum desirable intensity of the wind effect in |
| | terms of strength with respect to the Beaufort scale. [symbol] |
| unit [symbol] | Specifies the unit of the maxIntensity value as a reference to |
| | a classification scheme term provided by UnitTypeCS defined in |
| | A.2.1 of ISO/IEC 23005-6, if a unit other than the default unit |
| | specified in the semantics of the maxIntensity is used. [symbol] |

Table 73 shows an XML representation syntax of the preference information regarding the vibration type sensory device.

```
TABLE 73
<!-- ################################################ -->
<!-- Vibration Preference type -->
<!-- ################################################ -->
<complexType name=“VibrationPrefType”>
    <complexContent>
        <extension base=“cidl:UserSensoryPreferenceBaseType”>
            <attribute name=“maxIntensity” type=“integer”
            use=“optional”/>
            <attribute name=“unit” type=“mpegvct:unitType”
            use=“optional”/>
        </extension>
    </complexContent>
</complexType>
```

Table 74 shows a binary representation syntax of the preference information regarding the vibration type sensory device.

TABLE 74

| | | Number | |
|---|---|---|---|
| VibrationPrefType { | | of bits | Mnemonic |
| | maxIntensityFlag | 1 | bslbf |
| | unitFlag | 1 | bslbf |

| | |
|---|---|
| UserSensoryPreferenceBase | UserSensoryPreferenceBaseType |

if(maxIntensityFlag){

| | | |
|---|---|---|
| maxIntensity | 10 | simsbf |

}
if(unitFlag){

| | |
|---|---|
| unit | unitType |

}

}

Table 75 shows descriptor components semantics of the preference information regarding the vibration type sensory device.

TABLE 75

| Names [symbol] | Description [symbol] |
|---|---|
| VibrationPrefType [symbol] | Tool for describing a user preference on vibration effect. [symbol] |
| maxIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value, of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| maxIntensity [symbol] | Describes the maximum desirable intensity of the vibration |
| | effect in terms of strength with respect to the Richter magnitude |
| | scale. [symbol] |
| unit [symbol] | Specifies the unit of the maxIntensity value as a reference to |
| | a classification scheme term provided by UnitTypeCS defined in |
| | A.2.1 of ISO/IEC 23005-6, if a unit other than the default unit |
| | specified in the semantics of the maxIntensity is used. [symbol] |

Table 76 shows an XML representation syntax of the preference information regarding the scent type sensory device.

```
TABLE 76
  <!-- ################################################ -->
  <!-- Scent Preference type -->
  <!-- ################################################ -->
  <complexType name=“ScentPrefType”>
    <complexContent>
        <extension base=“cidl:UserSensoryPreferenceBaseType”>
            <sequence>
                <element name=“UnfavorableScent”
type=“mpeg7:termReferenceType” minOccurs=“0”
maxOccurs=“unbounded”/>
            </sequence>
            <attribute name=“maxIntensity” type=“integer”
            use=“optional”/>
            <attribute name=“unit” type=“mpegvct:unitType”
            use=“optional”/>
        </extension>
    </complexContent>
  </complexType>
```

Table 77 shows a binary representation syntax of the preference information regarding the scent type sensory device.

TABLE 77

| | | Number | |
|---|---|---|---|
| ScentPrefType { | | of bits | Mnemonic |
| UnfavorableScentFlag | | 1 | bslbf |
| | maxIntensityFlag | 1 | bslbf |

| | | |
|---|---|---|
| unitFlag | 1 | bslbf |

| | |
|---|---|
| UserSensoryPreferenceBase | UserSensoryPreferenceBaseType |

if(UnfavorableScentFlag){

| | |
|---|---|
| LoopUnfavorableScent | vluimsbf5 |

for(k=0;k<

LoopUnfavorableScent;k++){

| | |
|---|---|
| UnfavorableScent[k] | ColorType |

}

}

if(maxIntensityFlag){

| | | |
|---|---|---|
| maxIntensity | 10 | simsbf |

}
if(unitFlag){

| | |
|---|---|
| unit | unitType |

}

}

Table 78 shows a binary representation syntax of the scent type.

TABLE 78

| scentType [symbol] | Term ID of scent [symbol] |
|---|---|
| 0000 [symbol] | rose [symbol] |
| 0001 [symbol] | acacia [symbol] |
| 0010 [symbol] | chrysanthemum [symbol] |
| 0011 [symbol] | lilac [symbol] |
| 0100 [symbol] | mint [symbol] |
| 0101 [symbol] | jasmine [symbol] |
| 0110 [symbol] | pine_tree [symbol] |
| 0111 [symbol] | orange [symbol] |
| 1000 [symbol] | grape [symbol] |
| 1001-1111 [symbol] | Reserved [symbol] |

Table 79 shows descriptor components semantics of the preference information regarding the scent type sensory device.

TABLE 79

| Names [symbol] | Description [symbol] |
|---|---|
| ScentPrefType [symbol] | Tool for describing a user preference on scent effect. [symbol] |
| UnfavorableScentFlag [symbol] | This field, which is only present in the binary representation, |
| | signals the presence of the activation attribute. A value of “1” |
| | means the attribute shall be used and “0” means the attribute |
| | shall not be used. [symbol] |
| maxIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| LoopUnfavorableScent [symbol] | This field, which is only present in the binary representation, |
| | specifies the number of UnfavorableScent contained in the |
| | description. [symbol] |
| UnfavorableScent [symbol] | Describes the list of user's detestable scent. A CS that may be |
| | used for this purpose is the ScentCS defined in A.2.4 of ISO/IEC |
| | 23005-6. [symbol] |
| maxIntensity [symbol] | Describes the maximum desirable intensity of the scent effect in |
| | terms of milliliter/hour. [symbol] |
| unit [symbol] | Specifies the unit of the maxIntensity value as a reference to |
| | a classification scheme term provided by UnitTypeCS defined in |
| | A.2.1 of ISO/IEC 23005-6, if a unit other than the default unit |
| | specified in the semantics of the maxIntensity is used. [symbol] |

Table 80 shows an XML representation syntax of the preference information regarding the fog type sensory device.

```
TABLE 80
<!-- ################################################ -->
<!-- Fog Preference type -->
<!-- ################################################ -->
<complexType name=“FogPrefType”>
    <complexContent>
        <extension base=“cidl:UserSensoryPreferenceBaseType”>
            <attribute name=“maxIntensity” type=“integer”
            use=“optional”/>
            <attribute name=“unit” type=“mpegvct:unitType”
            use=“optional”/>
        </extension>
    </complexContent>
</complexType>
```

Table 81 shows a binary representation syntax of the preference information regarding the fog type sensory device.

TABLE 81

| | Num- | |
|---|---|---|
| | ber | |
| | of | |
| FogPrefType { | bits | Mnemonic |
| maxIntensityFlag | 1 | bslbf |
| unitFlag | 1 | bslbf |
| UserSensoryPreferenceBase | | UserSensoryPreferenceBaseType |
| if(maxIntensityFlag){ | | |
| maxIntensity | 10 | simsbf |
| } | | |
| if(unitFlag){ | | |
| unit | | unitType |
| } | | |
| } | | |

Table 82 shows descriptor components semantics of the preference information regarding the fog type sensory device.

TABLE 82

| Names [symbol] | Description [symbol] |
|---|---|
| FogPrefType [symbol] | Tool for describing a preference on fog effect. [symbol] |
| maxIntensityFlag [symbol] | This field, which is only present in the binary representation, |
| | signals the presence of the activation attribute. A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| maxIntensity [symbol] | Describes the maximum desirable intensity of the fog effect in |
| | terms of milliliter/hour. [symbol] |
| unit [symbol] | Specifies the unit of the maxIntensity value as a reference to |
| | a classification scheme term provided by UnitTypeCS defined in |
| | A.2.1 of ISO/IEC 23005-6, if a unit other than the default unit |
| | specified in the semantics of the maxIntensity is used. [symbol] |

Table 83 shows an XML representation syntax of the preference information regarding the sprayer type sensory device.

```
TABLE 83
<!-- ################################################ -->
<!-- Spraying Preference type -->
<!-- ################################################ -->
<complexType name=“SprayingPrefType”>
    <complexContent>
        <extension base=“cidl:UserSensoryPreferenceBaseType”>
            <attribute name=“sprayingType”
            type=“mpeg7:termReferenceType”/>
            <attribute name=“maxIntensity” type=“integer”
            use=“optional”/>
            <attribute name=“unit” type=“mpegvct:unitType”
            use=“optional”/>
        </extension>
    </complexContent>
</complexType>
```

Table 84 shows a binary representation syntax of the preference information regarding the sprayer type sensory device.

TABLE 84

| | Num- | |
|---|---|---|
| | ber | |
| | of | |
| SprayingPrefType{ | bits | Mnemonic |
| sprayingFlag | 1 | bslbf |
| maxIntensityFlag | 1 | bslbf |
| unitFlag | 1 | bslbf |
| UserSensoryPreferenceBase | | UserSensoryPreferenceBaseType |
| if(sprayingFlag){ | | |
| spraying | | SprayingType |
| } | | |
| if(maxIntensityFlag){ | | |
| maxIntensity | 10 | simsbf |
| } | | |
| if(unitFlag){ | | |
| unit | | unitType |
| } | | |
| } | | |

Table 85 shows a binary representation syntax of the sprayer type.

TABLE 85

| SprayingType [symbol] | Term ID of Spraying [symbol] |
|---|---|
| 00 [symbol] | water [symbol] |
| 01-11 [symbol] | Reserved [symbol] |

Table 86 shows descriptor components semantics of the preference information regarding the sprayer type sensory device.

TABLE 86

| Names [symbol] | Description [symbol] |
|---|---|
| SprayingPrefType [symbol] | Tool for describing a preference on fog effect. [symbol] |
| sprayingFlag [symbol] | This field, which only present in the binary representation, |
| | signals the presence of the activation attribute. A value of “1” |
| | means the attribute shall be used and “0” means the attribute |
| | shall not be used. [symbol] |
| maxIntensityFlag [symbol] | This field, which is only present in the binary representation, |
| | signals the presence of the activation attribute, A value of “1” |
| | means the attribute shall be used and “0” means the attribute |
| | shall not be used. [symbol] |
| unitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| spraying [symbol] | Describes the type of the sprayed material as a reference to a |
| | classification scheme term. A CS that may be used for this |
| | purpose is the SprayingTypeCS defined in Annex A.2.7 of |
| | ISO/IEC 23005-6. [symbol] |
| maxIntensity [symbol] | Destribes the maximum desirable intensity of the fog effect in |
| | terms of milliliter/hour. [symbol] |
| unit [symbol] | Specifies the unit of the maxIntensity value as a reference to |
| | a classification scheme term provided by UnitTypeCS defined in |
| | A.2.1 of ISO/IEC 23005-6, if a unit other than the default unit |
| | specified in the semantics of the maxIntensity is used. [symbol] |

Table 87 shows an XML representation syntax of the preference information regarding the color correction type sensory device.

```
TABLE 87
<!-- ################################################ -->
<!-- Definition of Color Correction Preference Type -->
<!-- ################################################ -->
<complexType name=“ColorCorrectionPrefType”>
    <complexContent>
        <extension base=“cidl:UserSensoryPreferenceBaseType”/>
    </complexContent>
</complexType>
```

Table 88 shows a binary representation syntax of the preference information regarding the color correction type sensory device.

TABLE 88

| | Number | |
|---|---|---|
| ColorCorrectionPrefType { | of bits | Mnemonic |
| UserSensoryPreferenceBase | | UserSensoryPreferenceBaseType |
| } | | |

Table 89 shows descriptor components semantics of the preference information regarding the color correction type sensory device.

TABLE 89

| Names [symbol] | Description [symbol] |
|---|---|
| ColorCorrectionPrefType [symbol] | Specifies whether the user prefers to use |
| | color correction functionality of the device |
| | or not by using activate attribute. Any |
| | information given by other attributes |
| | is ignored. [symbol] |
| UserSensoryPreferenceBase [symbol] | UserSensoryPreferenceBaseType extends |
| | dia:UserCharacteristicBaseType as defined |
| | in Part 7 of ISO/IEC 21000 and provides |
| | a base abstract type for a subset of |
| | types defined as part of the sensory |
| | device capability metadata types. [symbol] |

Table 90 shows an XML representation syntax of the preference information regarding the tactile type sensory device.

```
TABLE 90
<!-- ################################################ -->
<!-- Tactile Preference type -->
<!-- ################################################ -->
<complexType name=“TactilePrefType”>
    <complexContent>
        <extension base=“cidl:UserSensoryPreferenceBaseType”>
            <attribute name=“maxTemperature” type=“float”
            use=“optional”/>
            <attribute name=“minTemperature” type=“float”
            use=“optional”/>
            <attribute name=“maxCurrent” type=“float”
            use=“optional”/>
            <attribute name=“maxVibration” type=“float”
            use=“optional”/>
            <attribute name=“tempUnit” type=“mpegvct:unitType”
            use=“optional”/>
            <attribute name=“currentUnit” type=“mpegvct:unitType”
            use=“optional”/>
            <attribute name=“vibrationUnit” type=“mpegvct:unitType”
            use=“optional”/>
        </extension>
    </complexContent>
</complexType>
```

Table 91 shows a binary representation syntax of the preference information regarding the tactile type sensory device.

TABLE 91

| | Number | |
|---|---|---|
| TactilePrefType { | of bits | Mnemonic |
| maxTemperatureFlag | 1 | bslbf |
| minTemperatureFlag | 1 | bslbf |
| maxCurrentFlag | 1 | bslbf |
| maxVibrationFlag | 1 | bslbf |
| tempUnitFlag | 1 | bslbf |
| currentUnitFlag | 1 | bslbf |
| vibrationUnitFlag | 1 | bslbf |
| UserSensoryPreferenceBase | | UserSensoryPreferenceBaseType |
| if(maxTemperatureFlag){ | | |
| maxTemperature | 32 | fsbf |
| } | | |
| if(minTemperatureFlag){ | | |
| minTemperature | 32 | fsbf |
| } | | |
| if(maxCurrentFlag){ | | |
| maxCurrent | 32 | fsbf |
| } | | |
| if(maxVibrationFlag){ | | |
| maxVibration | 32 | fsbf |
| } | | |
| if(tempUnitFlag){ | | |
| tempUnit | | unitType |
| } | | |
| if(currentUnitFlag){ | | |
| currentUnit | | unitType |
| } | | |
| if(vibrationUnitFlag){ | | |
| vibrationUnit | | unitType |
| } | | |
| } | | |

Table 92 shows descriptor components semantics of the preference information regarding the tactile type sensory device.

TABLE 92

| Names [symbol] | Description [symbol] |
|---|---|
| TactilePrefType [symbol] | Tool for describing a user preference on tactile effect. [symbol] |
| maxTemperatureFlag [symbol] | This field, which is only present in the binary representation, |
| | signals the presence of the activation attribute. A value of “1” |
| | means the attribute shall be used and “0” means the attribute |
| | shall not be used. [symbol] |
| minTemperatureFlag [symbol] | This field, which is only present in the binary representation, |
| | signals the presence of the activation attribute. A value of “1” |
| | means the attribute shall be used and “0” means the attribute |
| | shall not be used. [symbol] |
| maxCurrentFlag [symbol] | This field, which is only present in the binary representation, |
| | signals the presence of the activation attribute. A value of “1” |
| | means the attribute shall be used and “0” means the attribute |
| | shall not be used. [symbol] |
| maxVibrationFlag [symbol] | This field, which is only present in the binary representation, |
| | signals the presence of the activation attribute. A value of “1” |
| | means the attribute shall be used and “0” means the attribute |
| | shall not be used. [symbol] |
| tempUnitFlag [symbol] | This field, which is only present in the binary representation, |
| | signals the presence of the activation attribute. A value of “1” |
| | means the attribute shall be used and “0” means the attribute |
| | shall not be used. [symbol] |
| currentUnitFlag [symbol] | This field, which is only present in the binary representation, |
| | signals the presence of the activation attribute. A value of “1” |
| | means the attribute shall be used and “0” means the attribute |
| | shall not be used. [symbol] |
| vibrationUnitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| maxTemperature [symbol] | Describes the maximum desirable temperature regarding how |
| | hot the tactile effect may be achieved, (Celsius) [symbol] |
| minTemperature [symbol] | Describes the minimum desirable temperature regarding how |
| | cold the tactile effect may be achieved, (Celsius) [symbol] |
| maxCurrent [symbol] | Describes the maximum desirable electic current, (mA) [symbol] |
| maxVibration [symbol] | Describes the maximum desirable vibration, (mm) [symbol] |
| tempUnit [symbol] | Specifies the unit of intensity, as a reference to a |
| | classification scheme term provide by UnitTypeCS defined in |
| | A.2.1 of ISO/IEC 23005-6. If the unit is not specified, the default |
| | unit is Celsius. [symbol] |
| currentUnit [symbol] | Specifies the unit of the intensity, as a reference to a |
| | classification scheme term provided by UnitTypeCS defined in |
| | A.2.1 of ISO/IEC 23005-6. If the unit is not specified, the default |
| | unit is milli-ampere. [symbol] |
| vibrationUnit [symbol] | Specifies the unit of the intensity, as a reference to a |
| | classification scheme term provided by UnitTypeCS defined in |
| | A.2.1 of ISO/IEC 23005-6. |

Table 93 shows an XML representation syntax of the preference information regarding the kinesthetic type sensory device.

```
TABLE 93
  <!-- ################################################ -->
  <!-- Kinesthetic Preference type -->
  <!-- ################################################ -->
  <complexType name=“KinestheticPrefType”>
    <complexContent>
        <extension base=“cidl:UserSensoryPreferenceBaseType”>
            <sequence>
                <element name=“maxForce”
type=“mpegvct:Float3DVectorType” minOccurs=“0”/>
                <element name=“maxTorque”
type=“mpegvct:Float3DVectorType” minOccurs=“0”/>
            </sequence>
            <attribute name=“forceUnit” type=“mpegvct:unitType”
            use=“optional”/>
            <attribute name=“torqueUnit” type=“mpegvct:unitType”
            use=“optional”/>
        </extension>
    </complexContent>
  </complexType>
```

Table 94 shows a binary representation syntax of the preference information regarding the kinesthetic type sensory device.

TABLE 94

| | Num- | |
|---|---|---|
| | ber | |
| | of | |
| KinestheticPrefType { | bits | Mnemonic |
| maxForceFlag | 1 | bslbf |
| maxTorqueFlag | 1 | bslbf |
| forceUnitFlag | 1 | bslbf |
| torqueUnitFlag | 1 | bslbf |
| UserSensoryPreferenceBase | | UserSensoryPreferenceBaseType |
| if(maxForceFlag){ | | |
| maxForce | | Float3DVectorType |
| } | | |
| if(maxTorqueFlag){ | | |
| maxTorque | | Float3DVectorType |
| } | | |
| if(forceUnitFlag) { | | |
| forceUnit | | unitType |
| } | | |
| if(torqueUnitFlag) { | | |
| torqueUnit | | unitType |
| } | | |
| } | | |
| Float3DVectorType { | | |
| X | 32 | fsbf |
| Y | 32 | fsbf |
| Z | 32 | fsbf |
| } | | |

Table 95 shows descriptor components semantics of the preference information regarding the kinesthetic type sensory device.

TABLE 95

| Names [symbol] | Description [symbol] |
|---|---|
| KinestheticPrefType [symbol] | Tool for describing a user preference on Kinesthetic effect |
| | (forcefeedback effect). [symbol] |
| maxForceFlag [symbol] | This field, which is only present in the binary representation, |
| | signals the presence of the activation attribute. A value of “1” |
| | means the attribute shall be used and “0” means the attribute |
| | shall not be used. [symbol] |
| maxTorqueFlag [symbol] | This field, which is only present in the binary representation, |
| | signals the presence of the activation attribute. A value of “1” |
| | means the attribute shall be used and “0” means the attribute |
| | shall not be used. [symbol] |
| forceUnitFlag [symbol] | This field, which is only present in the binary representation, |
| | signals the presence of the activation attribute. A value of “1” |
| | means the attribute shall be used and “0” means the attribute |
| | shall not be used. [symbol] |
| torqueUnitFlag [symbol] | This field, which is only present in the binary representation, |
| | signals the presence of the activation attribute. A value of “1” |
| | means the attribute shall be used and “0” means the attribute |
| | shall not be used. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| maxForce [symbol] | Describes the maximum desirable force for each direction of 3 |
| | dimensional axis (x, y and z). (N). [symbol] |
| maxTorque [symbol] | Describes the maximum desirable torque for each direction of 3 |
| | dimensional axis (x, y and z). (Nmm). [symbol] |
| forceUnit [symbol] | Specifies the unit of the intensity, as a reference to a |
| | classification scheme term provided by UnitTypeCS defined in |
| | A.2.1 of ISO/IEC 23005-6. If the unit is not specified the default |
| | unit is newton(N). [symbol] |
| torqueUnit [symbol] | Specifies the unit of the intensity, as a reference to a |
| | classification scheme term provided by UnitTypeCS defined in |
| | A.2.1 of ISO/IEC 23005-6. If the unit is not specified, the default |
| | unit is newton millimeter (Nmm). [symbol] |
| Float3DVectorType [symbol] | Tool for describing a 3D position vector. [symbol] |
| X [symbol] | Describes the sensed value in x-axis in the unit. [symbol] |
| Y [symbol] | Describes the sensed value in y-axis in the unit. [symbol] |
| Z [symbol] | Describes the sensed value in z-axis in the unit. [symbol] |

Table 96 shows an XML representation syntax of the preference information regarding the rigid body motion type sensory device.

```
TABLE 96
  <!-- ################################################ -->
  <!-- RigidBodyMotion Preference type -->
  <!-- ################################################ -->
  <complexType name=“RigidBodyMotionPrefType”>
    <complexContent>
        <extension base=“cidl:UserSensoryPreferenceBaseType”>
            <sequence minOccurs=“1” maxOccurs=“7”>
                <element name=“MotionPreference”
type=“sepv:MotionPreferenceBaseType”/>
            </sequence>
        </extension>
    </complexContent>
  </complexType>
  <!-- ################################################  -->
  <!-- Motion Preference base type -->
  <!-- ################################################  -->
  <complexType name=“MotionPreferenceBaseType” abstract=“true”>
    <attribute name=“unfavor” type=“boolean” use=“optional” default=“0”/>
  </complexType>
  <!-- ################################################ -->
  <!-- Move Toward Preference type -->
  <!-- ################################################ -->
  <complexType name=“MoveTowardPreferenceType”>
    <complexContent>
        <extension base=“sepv:MotionPreferenceBaseType”>
            <attribute name=“MaxMoveDistance” type=“unsignedInt” use=“optional”/>
            <attribute name=“MaxMoveSpeed” type=“float” use=“optional”/>
            <attribute name=“MaxMoveAccel” type=“float” use=“optional”/>
            <attribute name=“distanceUnit” type=“mpegvct:unitType” use=“optional”/>
            <attribute name=“speedUnit” type=“mpegvct:unitType” use=“optional”/>
            <attribute name=“accelUnit” type=“mpegvct:unitType” use=“optional”/>
        </extension>
    </complexContent>
  </complexType>
  <!-- ################################################ -->
  <!-- Incline Preference type -->
  <!-- ###################################0  ############# -->
  <complexType name=“InclinePreferenceType”>
    <complexContent>
        <extension base=“sepv:MotionPreferenceBaseType”>
            <attribute name=“MaxRotationAngle” type=“float” use=“optional”/>
            <attribute name=“MaxRotationSpeed” type=“float” use=“optional”/>
            <attribute name=“MaxRotationAccel” type=“float” use=“optional”/>
            <attribute name=“angleUnit” type=“mpegvct:unitType” use=“optional”/>
            <attribute name=“speedUnit” type=“mpegvct:unitType” use=“optional”/>
            <attribute name=“accelUnit” type=“mpegvct:unitType” use=“optional”/>
        </extension>
    </complexContent>
  </complexType>
  <!-- ################################################ -->
  <!-- Wave Preference type -->
  <!-- ################################################ -->
  <complexType name=“WavePreferenceType”>
    <complexContent>
        <extension base=“sepv:MotionPreferenceBaseType”>
            <attribute name=“MaxWaveDistance” type=“float” use=“optional”/>
            <attribute name=“MaxWaveSpeed” type=“float” use=“optional”/>
            <attribute name=“distanceUnit” type=“mpegvct:unitType” use=“optional”/>
            <attribute name=“speedUnit” type=“mpegvct:unitType” use=“optional”/>
        </extension>
    </complexContent>
  </complexType>
  <!-- ################################################ -->
  <!-- Collide Preference type -->
  <!-- ################################################ -->
  <complexType name=“CollidePreferenceType”>
    <complexContent>
        <extension base=“sepv:MotionPreferenceBaseType”>
            <attribute name=“MaxCollideSpeed” type=“float” use=“optional”/>
            <attribute name=“speedUnit” type=“mpegvct:unitType” use=“optional”/>
        </extension>
    </complexContent>
  </complexType>
  <!-- ################################################ -->
  <!-- Turn Preference type -->
  <!-- ################################################ -->
  <complexType name=“TurnPreferenceType”>
    <complexContent>
        <extension base=“sepv:MotionPreferenceBaseType”>
            <attribute name=“MaxTurnSpeed” type=“float” use=“optional”/>
            <attribute name=“speedUnit” type=“mpegvct:unitType” use=“optional”/>
        </extension>
    </complexContent>
  </complexType>
  <!-- ################################################ -->
  <!-- Shake Preference type -->
  <!-- ################################################ -->
  <complexType name=“ShakePreferenceType”>
    <complexContent>
        <extension base=“sepv:MotionPreferenceBaseType”>
            <attribute name=“MaxShakeDistance” type=“float” use=“optional”/>
            <attribute name=“MaxShakeSpeed” type=“float” use=“optional”/>
            <attribute name=“distanceUnit” type=“mpegvct:unitType” use=“optional”/>
            <attribute name=“speedUnit” type=“mpegvct:unitType” use=“optional”/>
        </extension>
    </complexContent>
  </complexType>
  <!-- ################################################ -->
  <!-- Spin Preference type -->
  <!-- ################################################ -->
  <complexType name=“SpinPreferenceType”>
    <complexContent>
        <extension base=“sepv:MotionPreferenceBaseType”>
            <attribute name=“MaxSpinSpeed” type=“float” use=“optional”/>
            <attribute name=“speedUnit” type=“mpegvct:unitType” use=“optional”/>
        </extension>
    </complexContent>
  </complexType>
```

Table 97 shows a binary representation syntax of the preference information regarding the rigid body motion type sensory device.

TABLE 97

| | Num- | |
|---|---|---|
| | ber | |
| | of | |
| RigidBodyMotionPrefType { | bits | Mnemonic |
| UserSensoryPreferenceBase | | UserSensoryPreferenceBaseType |
| LoopMotionPreference | 3 | uimsbf |
| for(k=0;k< | | |
| LoopMotionPreference;k++){ | | |
| MotionPreference[k] | | MotionPreferenceBaseType |
| } | | |
| } | | |
| MotionPreferenceBaseType { | | |
| unfavorFlag | 1 | bslbf |
| if(unfavorFlag){ | | |
| unfavor | 1 | bslbf |
| } | | |
| } | | |
| MoveTowardPreferenceType { | | |
| MaxMoveDistanceFlag | 1 | bslbf |
| MaxMoveSpeedFlag | 1 | bslbf |
| MaxMoveAccelFlag | 1 | bslbf |
| distanceUnitFlag | 1 | bslbf |
| speedUnitFlag | 1 | bslbf |
| accelUnitFlag | 1 | bslbf |
| MotionPreferenceBase | | MotionPreferenceBaseType |
| if(MaxMoveDistanceFlag){ | | |
| MaxMoveDistance | 8 | uimsbf |
| } | | |
| if(MaxMoveSpeedFlag){ | | |
| MaxMoveSpeed | 32 | fsbf |
| } | | |
| if(MaxMoveAccelFlag){ | | |
| MaxMoveAccel | 32 | fsbf |
| } | | |
| if(distanceUnitFlag){ | | |
| distanceUnit | | unitType |
| } | | |
| if(speedUnitFlag){ | | |
| speedUnit | | unitType |
| } | | |
| if(accelUnitFlag){ | | |
| accelUnit | | unitType |
| } | | |
| } | | |
| InclinePreferenceType { | | |
| MaxRotationAngleFlag | 1 | bslbf |
| MaxRotationSpeedFlag | 1 | bslbf |
| MaxRotationAccelFlag | 1 | bslbf |
| angleUnitFlag | 1 | bslbf |
| speedUnitFlag | 1 | bslbf |
| accelUnitFlag | 1 | bslbf |
| MotionPreferenceBase | | MotionPreferenceBaseType |
| if(MaxRotationAngleFlag){ | | |
| MaxRotationAngle | 32 | fsbf |
| } | | |
| if(MaxRotationSpeedFlag){ | | |
| MaxRotationSpeed | 32 | fsbf |
| } | | |
| if(MaxRotationAccelFlag){ | | |
| MaxRotationAccel | 32 | fsbf |
| } | | |
| if(angleUnitFlag){ | | |
| angleUnit | | unitType |
| } | | |
| if(speedUnitFlag){ | | |
| speedUnit | | unitType |
| } | | |
| if(accelUnitFlag){ | | |
| accelUnit | | unitType |
| } | | |
| } | | |
| WavePreferenceType { | | |
| MaxWaveDistanceFlag | 1 | bslbf |
| MaxWaveSpeedFlag | 1 | bslbf |
| distanceUnitFlag | 1 | bslbf |
| speedUnitFlag | 1 | bslbf |
| MotionPreferenceBase | | MotionPreferenceBaseType |
| if(MaxWaveDistanceFlag){ | | |
| MaxWaveDistance | 32 | fsbf |
| } | | |
| if(MaxWaveSpeedFlag){ | | |
| MaxWaveSpeed | 32 | fsbf |
| } | | |
| if(distanceUnitFlag){ | | |
| distanceUnit | | unitType |
| } | | |
| if(speedUnitFlag){ | | |
| speedUnit | | unitType |
| } | | |
| } | | |
| CollidePreferenceType { | | |
| MaxCollideSpeedFlag | | |
| speedUnitFlag | | |
| MotionPreferenceBase | | MotionPreferenceBaseType |
| if(MaxCollideSpeedFlag){ | | |
| MaxCollideSpeed | 32 | fsbf |
| } | | |
| if(speedUnitFlag){ | | |
| speedUnit | | unitType |
| } | | |
| } | | |
| TurnPreferenceType { | | |
| MaxTurnSpeedFlag | 1 | bslbf |
| speedUnitFlag | 1 | bslbf |
| MotionPreferenceBase | | MotionPreferenceBaseType |
| if(MaxTurnSpeedFlag){ | | |
| MaxTurnSpeed | 32 | fsbf |
| } | | |
| if(speedUnitFlag){ | | |
| speedUnit | | unitType |
| } | | |
| } | | |
| ShakePreferenceType { | | |
| MaxShakeDistanceFlag | 1 | bslbf |
| MaxShakeSpeedFlag | 1 | bslbf |
| distanceUnitFlag | 1 | bslbf |
| speedUnitFlag | 1 | bslbf |
| MotionPreferenceBase | | MotionPreferenceBaseType |
| if(MaxShakeDistanceFlag){ | | |
| MaxShakeDistance | 32 | fsbf |
| } | | |
| if(MaxShakeSpeedFlag){ | | |
| MaxShakeSpeed | 32 | fsbf |
| } | | |
| if(distanceUnitFlag){ | | |
| distanceUnit | | unitType |
| } | | |
| if(speedUnitFlag){ | | |
| speedUnit | | unitType |
| } | | |
| } | | |
| SpinPreferenceType { | | |
| MaxSpinSpeedFlag | 1 | bslbf |
| speedUnitFlag | 1 | bslbf |
| MotionPreferenceBase | | MotionPreferenceBaseType |
| if(MaxSpinSpeedFlag){ | | |
| MaxSpinSpeed | 32 | fsbf |
| } | | |
| if(speedUnitFlag){ | | |
| speedUnit | | unitType |
| } | | |
| } | | |

Table 98 shows descriptor components semantics of the preference information regarding the rigid body motion type sensory device.

TABLE 98

| Names [symbol] | Description [symbol] |
|---|---|
| RigidBodyMotionPrefType [symbol] | Tool for describing a user preference on Rigid body motion |
| | effect. [symbol] |
| UserSensoryPreferenceBase [symbol] | UserSensoryPreferenceBaseType extends |
| | dia:UserCharacteristicBaseType as defined in Part 7 of |
| | ISO/IEC 21000 and provides a base abstract type for a subset of |
| | types defined as part of the sensory device capability metadata |
| | types. [symbol] |
| LoopMotionPreference [symbol] | This field, which is only present in the binary representation, |
| | specifies the number of MotionPreference contained in the |
| | description. [symbol] |
| MotionPreference [symbol] | Describes the user preference for various types of rigid body |
| | motion effect. This element shall be instantiated by typing any |
| | specific extended type of MotionPreferenceBaseType. [symbol] |
| MotionPreferenceBaseType [symbol] | Provides base type for the type hierarchy of individual motion |
| | related preference types. [symbol] |
| unfavorFlag [symbol] | This field, which is only present in the binary representation, |
| | signals the presence of the activation attribute. A value of “1” |
| | means the attribute shall be used and “0” means the attribute |
| | shall not be used. [symbol] |
| unfavor [symbol] | Describes the user's distasteful motion effect. [symbol] |
| | EXAMPLE The value “true” means the user has a dislike for the |
| | specific motion sensory effect. [symbol] |
| MoveTowardPreferenceType [symbol] | Tool for describing a user preference on move toward effect. [symbol] |
| MaxMoveDistanceFlag [symbol] | This field, which is only present in the binary representation, |
| | signals the presence of the activation attribute. A value of “1” |
| | means the attribute shall be used and “0” means the attribute |
| | shall not be used. [symbol] |
| MaxMoveSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnit [symbol] | Specifies the unit of the speed, as a reference to a classification |
| | scheme term provided by UnitTypeCS defined in A.2.1 of |
| | ISO/IEC 23005-6. [symbol] |
| accelUnit [symbol] | Specifies the unit of the acceleration, as a reference to a |
| | classification scheme term provided by UnitTypeCS defined in |
| | A.2.1 of ISO/IEC 23005-6. [symbol] |
| InclinePreferenceType [symbol] | Tool for describing a user preference on motion chair incline |
| | effect. [symbol] |
| MaxRotationAngleFlag [symbol] | This field, which is only present in the binary representation, |
| | signals the presence of the activation attribute. A value of “1” |
| | means the attribute shall be used and “0” means the attribute |
| | shall not be used. [symbol] |
| MaxRotationSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| MaxRotationAccelFlag [symbol] | This field, which is only present in the binary representation, |
| | signals the presence of the activation attribute. A value of “1” |
| | means the attribute shall be used and “0” means the attribute |
| | shall not be used. [symbol] |
| angleUnitFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MaxMoveAccelFlag [symbol] | This field, which is only present in the binary representation, |
| | signals the presence of the activation attribute. A value of “1” |
| | means the attribute shall be used and “0” means the attribute |
| | shall not be used. [symbol] |
| distanceUnitFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| accelUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxMoveDistance [symbol] | Describes the maximum desirable distance of the move effect |
| | with respect to the centimeter. [symbol] |
| | EXAMPLE The value ‘10’ means the user does not want the |
| | chair move more than 10 cm. [symbol] |
| MaxMoveSpeed [symbol] | Describes the maximum desirable speed of move effect with |
| | respect to the centimeter per second. [symbol] |
| | EXAMPLE The value ‘10’ means the user does not want the |
| | chair speed exceed more than 10 cm/s. [symbol] |
| MaxMoveAccel [symbol] | Describes the maximum desirable acceleration of move effect |
| | with respect to the centimeter per square second. [symbol] |
| distanceUnit [symbol] | Specifies the unit of the distance, as a reference to a |
| | classification scheme term provided by UnitTypeCS defined in |
| | A.2.1 of ISO/IEC 23005-6. [symbol] |
| accelUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxRotationAngle [symbol] | Describes the maximum desirable rotation angle of incline |
| | effect. [symbol] |
| MaxRotationSpeed [symbol] | Describes the maximum desirable rotation speed of incline |
| | effect with respect to the degree per second. [symbol] |
| | EXAMPLE The value ‘10’ means the user does not want the |
| | chair speed exceed more than 10 degree/s. [symbol] |
| MaxRotationAccel [symbol] | Describes the maximum desirable rotation acceleration of incline |
| | effect with respect to the degree per second. [symbol] |
| angleUnit [symbol] | Specifies the unit of the angle, as a reference to a classification |
| | scheme term provided by UnitTypeCS defined in A.2.1 of |
| | ISO/IEC 23005-6. [symbol] |
| speedUnit [symbol] | Specifies the unit of the speed, as a reference to a classification |
| | scheme term provided by UnitTypeCS defined in A.2.1 of |
| | ISO/IEC 23005-6. [symbol] |
| accelUnit [symbol] | Specifies the unit of the acceleration, as a reference to a |
| | classification scheme term provided by UnitTypeCS defined in |
| | A.2.1 of ISO/IEC 23005-6. [symbol] |
| WavePreferenceType [symbol] | Tool for describing a user preference on wave effect. [symbol] |
| MaxWaveDistanceFlag [symbol] | This field, which is only present in the binary representation, |
| | signals the presence of the activation attribute. A value of “1” |
| | means the attribute shall be used and “0” means the attribute |
| | shall not be used. [symbol] |
| MaxWaveSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| distanceUnitFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxWaveDistance [symbol] | Describes the maximum desirable distance of wave effect with |
| | respect to the centimeter. [symbol] |
| | NOTE Observe the maximum distance among the distance of |
| | yawing, rolling and pitching. [symbol] |
| MaxWaveSpeed [symbol] | Describes the maximum desirable speed of wave effect in terms |
| | of cycle per second. [symbol] |
| | NOTE Observe the maximum speed among the speed of yawing, |
| | rolling and pitching. [symbol] |
| distanceUnit [symbol] | Specifies the unit of the distance, as a reference to a |
| | classification scheme term provided by UnitTypeCS defined in |
| | A.2.1 of ISO/IEC 23005-6. [symbol] |
| speedUnit [symbol] | Specifies the unit of the speed, as a reference to a classification |
| | scheme term provided by UnitTypeCS defined in A.2.1 of |
| | ISO/IEC 23005-6. [symbol] |
| CollidePreferenceType [symbol] | Tool for describing a user preference on motion chair collision |
| | effect. [symbol] |
| MaxCollideSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxCollideSpeed [symbol] | Describes the maximum desirable speed of collision effect with |
| | respect to the centimeter per second. [symbol] |
| | EXAMPLE The value ‘10’ means the user does not want the |
| | chair speed exceed more than 10 cm/s. [symbol] |
| speedUnit [symbol] | Specifies the unit of the speed, as a reference to a classification |
| | scheme term provided by UnitTypeCS defined in A.2.1 of |
| | ISO/IEC 23005-6. [symbol] |
| TurnPreferenceType [symbol] | Tool for describing a user preference on turn effect. [symbol] |
| MaxTurnSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxTurnSpeed [symbol] | Describes the maximum desirable speed of turn effect with |
| | respect to the degree per second. [symbol] |
| | EXAMPLE The value ‘10’ means the user does not want the |
| | chair speed exceed more than 10 degree/s. [symbol] |
| speedUnit [symbol] | Specifies the unit of the speed, as a reference to a classification |
| | scheme term provided by UnitTypeCS defined in A.2.1 of |
| | ISO/IEC 23005-6. [symbol] |
| ShakePreferenceType [symbol] | Tool for describing a user preference on motion chair shake |
| | effect. [symbol] |
| MaxShakeDistanceFlag [symbol] | This field, which is only present in the binary representation, |
| | signals the presence of the activation attribute. A value of “1” |
| | means the attribute shall be used and “0” means the attribute |
| | shall not be used. [symbol] |
| MaxShakeSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| distanceUnitFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxShakeDistance [symbol] | Describes the maximum desirable distance of the shake effect |
| | with respect to the centimeter. [symbol] |
| | EXAMPLE The value ‘10’ means the user does not want the |
| | chair shake more than 10 cm. [symbol] |
| MaxShakeSpeed [symbol] | Describes the maximum desirable speed of shake effect in terms |
| | of cycle per second. [symbol] |
| | EXAMPLE The value ‘1’ means the motion chair shake speed |
| | can't exceed1 cycle/sec. [symbol] |
| distanceUnit [symbol] | Specifies the unit of the distance, as a reference to a |
| | classification scheme term provided by UnitTypeCS defined in |
| | A.2.1 of ISO/IEC 23005-6. [symbol] |
| speedUnit [symbol] | Specifies the unit of the speed, as a reference to a classification |
| | scheme term provided by UnitTypeCS defined in A.2.1 of |
| | ISO/IEC 23005-6. [symbol] |
| SpinPreferenceType [symbol] | Tool for describing a user preference on motion chair spin |
| | effect. [symbol] |
| MaxSpinSpeedFlag [symbol] | This field, which is only present in the binary representation, |
| | signals the presence of the activation attribute. A value of “1” |
| | means the attribute shall be used and “0” means the attribute |
| | shall not be used. [symbol] |
| speedUnitFlag [symbol] | This field, which is only present in the binary representation, |
| | signals the presence of the activation attribute. A value of “1” |
| | means the attribute shall be used and “0” means the attribute |
| | shall not be used. [symbol] |
| MotionPreferenceBase [symbol] | Provides base type for the type hierarchy of individual motion |
| | related preference types. [symbol] |
| MaxSpinSpeed [symbol] | Describes the maximum desirable speed of spin effect in terms |
| | of cycle per second. [symbol] |
| | EXAMPLE The value ‘1’ means the motion chair spin speed |
| | can't exceed1 cycle/sec. [symbol] |
| speedUnit [symbol] | Specifies the unit of the speed, as a reference to a classification |
| | scheme term provided by UnitTypeCS defined in A.2.1 of |
| | ISO/IEC 23005-6. |

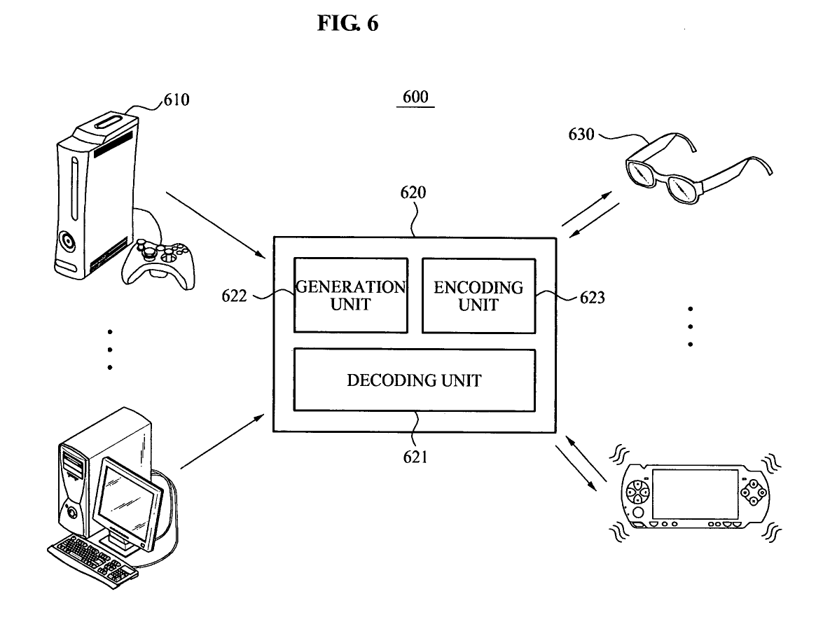

FIG. 6 illustrates a structure of a sensory effect controlling device 620 according to embodiments.

Referring to FIG. 6, the sensory effect controlling device 620 includes a decoding unit 621, a generation unit 622, and an encoding unit 623.

The decoding unit 621 may decode SEM and SDCap metadata. The sensory effect controlling device 620 may receive the SEM from the sensory media reproducing device 610 and receive the SDCap metadata from the sensory device 630.

The decoding unit 621 may extract the sensory effect by decoding the SEM. Also, the decoding unit 621 may extract capability information regarding capability of the sensory device 630 by decoding the SDCap metadata.

The decoding unit 621 may include at least one of an XML decoder and a binary decoder. According to embodiments, the decoding unit 621 may include the XML decoder 221 of FIG. 2, the binary decoder 321 of FIG. 3, and the binary decoder 421 and the XML decoder 422 of FIG. 4.

The generation unit 622 may generate command information for controlling the sensory device 630 based on the decoded SEM and the decoded SDCap metadata.

The command information may be information for controlling execution of an effect event corresponding to the sensory effect information by the sensory device 630.

The sensory effect controlling device 620 may further include a receiving unit (not shown).

The receiving unit may receive USP metadata from the sensory device 630.

Here, the decoding unit 621 may decode the USP metadata. That is, the decoding unit 621 may extract preference information, that is, information on a user preference with respect to a sensory effect, by decoding the USP metadata.

The generation unit 622 may generate command information for controlling the sensory device 630 based on the decoded sensory effect metadata, the decoded SDCap metadata, and the decoded USP metadata.

The encoding unit 623 may encode the command information into SDCmd metadata. That is, the encoding unit 623 may generate the SDCmd metadata by encoding the command information. The encoding unit 623 may include at least one of an XML encoder and a binary encoder.

The encoding unit 623 may generate the property device command metadata by encoding the command information into XML metadata.

Also, the encoding unit 623 may generate the property device command metadata by encoding the command information into binary metadata.

In addition, the encoding unit 623 may generate first metadata by encoding the command information into XML metadata, and generate the SDCmd metadata by encoding the first metadata.

The SDCmd metadata may include a sensory device command base type which denotes basic command information for control of the sensory device 630. The sensory device command base type may be metadata regarding the command information commonly applied to all types of the sensory device 630.

Table 99 shows an XML representation syntax of the sensory device command base type.

TABLE 99

```
<!-- ################################################  -->
<!-- Device command base type -->
<!-- ################################################  -->
<complexType name=“DeviceCommandBaseType” abstract=“true”>
    <sequence>
        <element name=“TimeStamp”
        type=“mpegvct:TimeStampType”/>
    </sequence>
    <attributeGroup ref=“iidl:DeviceCmdBaseAttributes”/>
</complexType>
```

Table 100 shows a binary representation syntax of the sensory device command base type.

TABLE 100

| DeviceCommandBaseType{ | Number of bits | Mnemonic |
|---|---|---|
| TimeStamp | | TimeStampType |
| DeviceCmdBaseAttributes | | DeviceCmdBaseAttributesType |
| } | | |
| TimeStampType{ | | |
| TimeStampSelect | 2 | bslbf |
| if(TimeStampSelect==00){ | | |
| AbsoluteTimeStamp | | AbsoluteTimeStampType |
| } else if | | |
| (TimeStampSelect==01){ | | |
| ClockTickTimeStamp | | ClockTickTimeStampType |
| } else if | | |
| (TimeStampSelect==10){ | | |
| ClockTickTimeDeltaStamp | | ClockTickTimeDeltaStampType |
| } | | |
| } | | |

Table 101 shows descriptor components semantics of the sensory device command base type.

TABLE 101

| Names [symbol] | Description [symbol] |
|---|---|
| TimeStamp [symbol] | Provides the timing information for the device |
| | command to be executed. As defined in Part 6 of |
| | ISO/IEC 23005, there is a choice of selection among |
| | three timing schemes, which are absolute time, clock |
| | tick time, and delta of clock tick time [symbol] |
| DeviceCommandBase [symbol] | Provides the topmost type of the base type hierarchy [symbol] |
| | which each individual device command can inherit. [symbol] |
| TimeStampType [symbol] | This field, which is only present in the binary |
| | representation, describes which time stamp scheme shall |
| | be used, “00” means that the absolute time stamp type |
| | shall be used, “01” means that the clock tick time stamp |
| | type shall be used, and “10” means that the clock tick time |
| | delta stamp type shall be used. [symbol] |
| AbsoluteTimeStamp [symbol] | The absolute time stamp is defined in A.2.3 of ISO/IEC |
| | 23005-6. [symbol] |
| ClockTickTimeStamp [symbol] | The clock tick time stamp is defined in A.2.3 of ISO/IEC |
| | 23005-6. [symbol] |
| ClockTickTimeDeltaStamp [symbol] | The Clock tick time delta stamp, which value is the time |
| | delta between the present and the past time, is defined in |
| | A.2.3 of ISO/IEC 23005-6. [symbol] |
| DeviceCmdBaseAttributes [symbol] | Describes a group of attributes for the commands. [symbol] |

The SDCmd metadata may include sensory device command base attributes that denote groups regarding common attributes of the command information.

Table 102 shows an XML representation syntax regarding the sensory device command base type according to embodiments.

```
TABLE 102
<!-- ################################################ -->
<!-- Definition of Device Command Base Attributes -->
<!-- ################################################ -->
<attributeGroup name=“DeviceCmdBaseAttributes”>
      <attribute name=“id” type=“ID” use=“optional”/>
      <attribute name=“deviceIdRef” type=“anyURI” use=“optional”/>
      <attribute name=“activate” type=“boolean” use=“optional”
      default=“true”/>
</attributeGroup>
```

Table 103 shows a binary representation syntax regarding the sensory device command base type according to embodiments.

TABLE 103

| DeviceCmdBaseAttributesType | | |
|---|---|---|
| { | Number of bits | Mnemonic |
| idFlag | 1 | bslbf |
| deviceIdRefFlag | 1 | bslbf |
| activateFlag | 1 | bslbf |
| If(idFlag) { | | |
| id | See ISO 10646 | UTF-8 |
| } | | |
| if(deviceIdRefFlag) { | | |
| deviceIdRefLength | | vluimsbf5 |
| deviceIdRef | 8 * deviceIdRefLength | bslbf |
| } | | |
| if(activateFlag) { | | |
| activate | 1 | bslbf |
| } | | |
| } | | |

Table 104 shows descriptor components semantics regarding the sensory device command base type according to embodiments.

TABLE 104

| Names [symbol] | Description [symbol] |
|---|---|
| DeviceCmdBaseAttributesType [symbol] | Provides the topmost type of the base type hierarchy |
| | which the attributes of each individual device |
| | command can inherit. [symbol] |
| idFlag [symbol] | This field, which is only present in the binary |
| | representation, signals the presence of the id |
| | attribute. A value of “1” means the attribute shall |
| | be used and “0” means the attribute shall not be used. [symbol] |
| deviceIdRefFlag [symbol] | This field, which is only present in the binary |
| | representation, signals the presence of the sensor ID |
| | reference attribute. A value of “1” means the |
| | attribute shall be used and “0” means the attribute |
| | shall not be used. [symbol] |
| activateFlag [symbol] | This field, which is only present in the binary |
| | representation, signals the presence of the activation |
| | attribute. A value of “1” means the attribute shall |
| | be used and “0” means the attribute shall not be used. [symbol] |
| id [symbol] | id to identify the sensed information with respect to a |
| | light sensor. [symbol] |
| deviceIdRefLength [symbol] | This field, which is only present in the binary |
| | representation, specifies the length of the following |
| | deviceIdRef attribute. [symbol] |
| deviceIdRef [symbol] | References a device that has generated the command |
| | included in this specific device command. [symbol] |
| activate [symbol] | Describes whether the device is activated. A value of |
| | “1” means the sensor is activated and “0” means the |
| | sensor is deactivated. [symbol] |

Hereinafter, command information regarding each type of the sensory device will be described in detail.

Table 105 shows an XML representation syntax regarding the light type sensory device.

```
TABLE 105
<!-- ################################################ -->
<!-- Definition of DCV Light Type -->
<!-- ################################################ -->
<complexType name=“LightType”>
    <complexContent>
          <extension base=“iidl:DeviceCommandBaseType”>
                <attribute name=“color” type=“mpegvct:colorType”
                use=“optional”/>
                <attribute name=“intensity” type=“integer”
                use=“optional”/>
          </extension>
    </complexContent>
</complexType>
```

Table 106 shows a binary representation syntax regarding the light type sensory device.

TABLE 106

| LightType{ | Number of bits | Mnemonic |
|---|---|---|
| colorFlag | 1 | bslbf |
| intensityFlag | 1 | bslbf |
| DeviceCommandBase | | DeviceCommandBaseType |
| if(colorFlag) { | | |
| color | | colorType |
| } | | |
| if(intensityFlag) { | | |
| intensity | 7 | uimsbf |
| } | | |
| } | | |

Table 107 shows a binary representation syntax of a color CS.

TABLE 107

| colorType [symbol] | Term ID of color [symbol] |
|---|---|
| 000000000 [symbol] | alice_blue [symbol] |
| 000000001 [symbol] | alizarin [symbol] |
| 000000010 [symbol] | amaranth [symbol] |
| 000000011 [symbol] | amaranth_pink [symbol] |
| 000000100 [symbol] | amber [symbol] |
| 000000101 [symbol] | amethyst [symbol] |
| 000000110 [symbol] | apricot [symbol] |
| 000000111 [symbol] | aqua [symbol] |
| 000001000 [symbol] | aquamarine [symbol] |
| 000001001 [symbol] | army_green [symbol] |
| 000001010 [symbol] | asparagus [symbol] |
| 000001011 [symbol] | atomic_tangerine [symbol] |
| 000001100 [symbol] | auburn [symbol] |
| 000001101 [symbol] | azure_color_wheel [symbol] |
| 000001110 [symbol] | azure_web [symbol] |
| 000001111 [symbol] | baby_blue [symbol] |
| 000010000 [symbol] | beige [symbol] |
| 000010001 [symbol] | bistre [symbol] |
| 000010010 [symbol] | black [symbol] |
| 000010011 [symbol] | blue [symbol] |
| 000010100 [symbol] | blue_pigment [symbol] |
| 000010101 [symbol] | blue_ryb [symbol] |
| 000010110 [symbol] | blue_green [symbol] |
| 000010111 [symbol] | blue-green [symbol] |
| 000011000 [symbol] | blue-violet [symbol] |
| 000011001 [symbol] | bondi_blue [symbol] |
| 000011010 [symbol] | brass [symbol] |
| 000011011 [symbol] | bright_green [symbol] |
| 000011100 [symbol] | bright_pink [symbol] |
| 000011101 [symbol] | bright_turquoise [symbol] |
| 000011110 [symbol] | brilliant_rose [symbol] |
| 000011111 [symbol] | brink_pink [symbol] |
| 000100000 [symbol] | bronze [symbol] |
| 000100001 [symbol] | brown [symbol] |
| 000100010 [symbol] | buff [symbol] |
| 000100011 [symbol] | burgundy [symbol] |
| 000100100 [symbol] | burnt_orange [symbol] |
| 000100101 [symbol] | burnt_sienna [symbol] |
| 000100110 [symbol] | burnt_umber [symbol] |
| 000100111 [symbol] | camouflage_green [symbol] |
| 000101000 [symbol] | caput_mortuum [symbol] |
| 000101001 [symbol] | cardinal [symbol] |
| 000101010 [symbol] | carmine [symbol] |
| 000101011 [symbol] | carmine_pink [symbol] |
| 000101100 [symbol] | carnation_pink [symbol] |
| 000101101 [symbol] | Carolina_blue [symbol] |
| 000101110 [symbol] | carrot_orange [symbol] |
| 000101111 [symbol] | celadon [symbol] |
| 000110000 [symbol] | cerise [symbol] |
| 000110001 [symbol] | cerise_pink [symbol] |
| 000110010 [symbol] | cerulean [symbol] |
| 000110011 [symbol] | cerulean_blue [symbol] |
| 000110100 [symbol] | champagne [symbol] |
| 000110101 [symbol] | charcoal [symbol] |
| 000110110 [symbol] | chartreuse_traditional [symbol] |
| 000110111 [symbol] | chartreuse_web [symbol] |
| 000111000 [symbol] | cherry_blossom_pink [symbol] |
| 000111001 [symbol] | chestnut [symbol] |
| 000111010 [symbol] | chocolate [symbol] |
| 000111011 [symbol] | cinnabar [symbol] |
| 000111100 [symbol] | cinnamon [symbol] |
| 000111101 [symbol] | cobalt [symbol] |
| 000111110 [symbol] | Columbia_blue [symbol] |
| 000111111 [symbol] | copper [symbol] |
| 001000000 [symbol] | copper_rose [symbol] |
| 001000001 [symbol] | coral [symbol] |
| 001000010 [symbol] | coral_pink [symbol] |
| 001000011 [symbol] | coral_red [symbol] |
| 001000100 [symbol] | corn [symbol] |
| 001000101 [symbol] | cornflower_blue [symbol] |
| 001000110 [symbol] | cosmic_latte [symbol] |
| 001000111 [symbol] | cream [symbol] |
| 001001000 [symbol] | crimson [symbol] |
| 001001001 [symbol] | cyan [symbol] |
| 001001010 [symbol] | cyan_process [symbol] |
| 001001011 [symbol] | dark_blue [symbol] |
| 001001100 [symbol] | dark_brown [symbol] |
| 001001101 [symbol] | dark_cerulean [symbol] |
| 001001110 [symbol] | dark_chestnut [symbol] |
| 001001111 [symbol] | dark_coral [symbol] |
| 001010000 [symbol] | dark_goldenrod [symbol] |
| 001010001 [symbol] | dark_green [symbol] |
| 001010010 [symbol] | dark_khaki [symbol] |
| 001010011 [symbol] | dark_magenta [symbol] |
| 001010100 [symbol] | dark_pastel_green [symbol] |
| 001010101 [symbol] | dark_pink [symbol] |
| 001010110 [symbol] | dark_scarlet [symbol] |
| 001010111 [symbol] | dark_salmon [symbol] |
| 001011000 [symbol] | dark_slate_gray [symbol] |
| 001011001 [symbol] | dark_spring_green [symbol] |
| 001011010 [symbol] | dark_tan [symbol] |
| 001011011 [symbol] | dark_turquoise [symbol] |
| 001011100 [symbol] | dark_violet [symbol] |
| 001011101 [symbol] | deep_carmine_pink [symbol] |
| 001011110 [symbol] | deep_cerise [symbol] |
| 001011111 [symbol] | deep_chestnut [symbol] |
| 001100000 [symbol] | deep_fuchsia [symbol] |
| 001100001 [symbol] | deep_lilac [symbol] |
| 001100010 [symbol] | deep_magenta [symbol] |
| 001100011 [symbol] | deep_magenta [symbol] |
| 001100100 [symbol] | deep_peach [symbol] |
| 001100101 [symbol] | deep_pink [symbol] |
| 001100110 [symbol] | denim [symbol] |
| 001100111 [symbol] | dodger_blue [symbol] |
| 001101000 [symbol] | ecru [symbol] |
| 001101001 [symbol] | egyptian_blue [symbol] |
| 001101010 [symbol] | electric_blue [symbol] |
| 001101011 [symbol] | electric_green [symbol] |
| 001101100 [symbol] | elctric_indigo [symbol] |
| 001101101 [symbol] | electric_lime [symbol] |
| 001101110 [symbol] | electric_purple [symbol] |
| 001101111 [symbol] | emerald [symbol] |
| 001110000 [symbol] | eggplant [symbol] |
| 001110001 [symbol] | falu_red [symbol] |
| 001110010 [symbol] | fern_green [symbol] |
| 001110011 [symbol] | firebrick [symbol] |
| 001110100 [symbol] | flax [symbol] |
| 001110101 [symbol] | forest_green [symbol] |
| 001110110 [symbol] | french_rose [symbol] |
| 001110111 [symbol] | fuchsia [symbol] |
| 001111000 [symbol] | fuchsia_pink [symbol] |
| 001111001 [symbol] | gamboge [symbol] |
| 001111010 [symbol] | gold_metallic [symbol] |
| 001111011 [symbol] | gold_web_golden [symbol] |
| 001111100 [symbol] | golden_brown [symbol] |
| 001111101 [symbol] | golden_yellow [symbol] |
| 001111110 [symbol] | goldenrod [symbol] |
| 001111111 [symbol] | grey-asparagus [symbol] |
| 010000000 [symbol] | green_colour_wheel_x11_green [symbol] |
| 010000001 [symbol] | green_html/css_green [symbol] |
| 010000010 [symbol] | green_pigment [symbol] |
| 010000011 [symbol] | green_ryb [symbol] |
| 010000100 [symbol] | green_yellow [symbol] |
| 010000101 [symbol] | grey [symbol] |
| 010000110 [symbol] | han_purple [symbol] |
| 010000111 [symbol] | harlequin [symbol] |
| 010001000 [symbol] | heliotrope [symbol] |
| 010001001 [symbol] | Hollywood_cerise [symbol] |
| 010001010 [symbol] | hot_magenta [symbol] |
| 010001011 [symbol] | hot_pink [symbol] |
| 010001100 [symbol] | indigo_dye [symbol] |
| 010001101 [symbol] | international_klein_blue [symbol] |
| 010001110 [symbol] | international_orange [symbol] |
| 010001111 [symbol] | Islamic_green [symbol] |
| 010010000 [symbol] | ivory [symbol] |
| 010010001 [symbol] | jade [symbol] |
| 010010010 [symbol] | kelly_green [symbol] |
| 010010011 [symbol] | khaki [symbol] |
| 010010100 [symbol] | khaki_x11_light_khaki [symbol] |
| 010010101 [symbol] | lavender_floral [symbol] |
| 010010110 [symbol] | lavender_web [symbol] |
| 010010111 [symbol] | lavender_blue [symbol] |
| 010011000 [symbol] | lavender_blush [symbol] |
| 010011001 [symbol] | lavender_grey [symbol] |
| 010011010 [symbol] | lavender_magenta [symbol] |
| 010011011 [symbol] | lavender_pink [symbol] |
| 010011100 [symbol] | lavender_purple [symbol] |
| 010011101 [symbol] | lavender_rose [symbol] |
| 010011110 [symbol] | lawn_green [symbol] |
| 010011111 [symbol] | lemon [symbol] |
| 010100000 [symbol] | lemon_chiffon [symbol] |
| 010100001 [symbol] | light_blue [symbol] |
| 010100010 [symbol] | light_pink [symbol] |
| 010100011 [symbol] | lilac [symbol] |
| 010100100 [symbol] | lime_color_wheel [symbol] |
| 010100101 [symbol] | lime_web_x11_green [symbol] |
| 010100110 [symbol] | lime_green [symbol] |
| 010100111 [symbol] | linen [symbol] |
| 010101000 [symbol] | magenta [symbol] |
| 010101001 [symbol] | magenta_dye [symbol] |
| 010101010 [symbol] | magenta_process [symbol] |
| 010101011 [symbol] | magic_mint [symbol] |
| 010101100 [symbol] | magnolia [symbol] |
| 010101101 [symbol] | malachite [symbol] |
| 010101110 [symbol] | maroon_html/css [symbol] |
| 010101111 [symbol] | marron_x11 [symbol] |
| 010110000 [symbol] | maya_blue [symbol] |
| 010110001 [symbol] | mauve [symbol] |
| 010110010 [symbol] | mauve_taupe [symbol] |
| 010110011 [symbol] | medium_blue [symbol] |
| 010110100 [symbol] | medium_carmine [symbol] |
| 010110101 [symbol] | medium_lavender_magenta [symbol] |
| 010110110 [symbol] | medum_purple [symbol] |
| 010110111 [symbol] | medium_spring_green [symbol] |
| 010111000 [symbol] | midnight_blue [symbol] |
| 010111001 [symbol] | midnight_green_eagle_green [symbol] |
| 010111010 [symbol] | mint_green [symbol] |
| 010111011 [symbol] | misty_rose [symbol] |
| 010111100 [symbol] | moss_green [symbol] |
| 010111101 [symbol] | mountbatten_pink [symbol] |
| 010111110 [symbol] | mustard [symbol] |
| 010111111 [symbol] | myrtle [symbol] |
| 011000000 [symbol] | navajo_while [symbol] |
| 011000001 [symbol] | navy_blue [symbol] |
| 011000010 [symbol] | ochre [symbol] |
| 011000011 [symbol] | office_green [symbol] |
| 011000100 [symbol] | old_gold [symbol] |
| 011000101 [symbol] | old_lace [symbol] |
| 011000110 [symbol] | old_lavender [symbol] |
| 011000111 [symbol] | old_rose [symbol] |
| 011001000 [symbol] | olive [symbol] |
| 011001001 [symbol] | olive_drab [symbol] |
| 011001010 [symbol] | olivine [symbol] |
| 011001011 [symbol] | orange_color_wheel [symbol] |
| 011001100 [symbol] | orange_ryb [symbol] |
| 011001101 [symbol] | orange_web [symbol] |
| 011001110 [symbol] | orange_peel [symbol] |
| 011001111 [symbol] | orange-red [symbol] |
| 011010000 [symbol] | orchid [symbol] |
| 011010001 [symbol] | pale_blue [symbol] |
| 011010010 [symbol] | pale_brown [symbol] |
| 011010011 [symbol] | pale_carmine [symbol] |
| 011010100 [symbol] | pale_chestnut [symbol] |
| 011010101 [symbol] | pale_cornflower_blue [symbol] |
| 011010110 [symbol] | pale_magenta [symbol] |
| 011010111 [symbol] | pale_pink [symbol] |
| 011011000 [symbol] | pale_red-violet [symbol] |
| 011011001 [symbol] | papaya_whip [symbol] |
| 011011010 [symbol] | pastel_green [symbol] |
| 011011011 [symbol] | pastel_pink [symbol] |
| 011011100 [symbol] | peach [symbol] |
| 011011101 [symbol] | peach-orange [symbol] |
| 011011110 [symbol] | peach-yellow [symbol] |
| 011011111 [symbol] | pear [symbol] |
| 011100000 [symbol] | periwinkle [symbol] |
| 011100001 [symbol] | persian_blue [symbol] |
| 011100010 [symbol] | persian_green [symbol] |
| 011100011 [symbol] | persian_indigo [symbol] |
| 011100100 [symbol] | persian_orange [symbol] |
| 011100101 [symbol] | persian_red [symbol] |
| 011100110 [symbol] | persian_pink [symbol] |
| 011100111 [symbol] | persian_rose [symbol] |
| 011101000 [symbol] | persimmon [symbol] |
| 011101001 [symbol] | pine_green [symbol] |
| 011101010 [symbol] | pink [symbol] |
| 100001011 [symbol] | sapphire [symbol] |
| 100001100 [symbol] | scarlet [symbol] |
| 100001101 [symbol] | school_bus_yellow [symbol] |
| 100001110 [symbol] | sea_green [symbol] |
| 100001111 [symbol] | seashell [symbol] |
| 100010000 [symbol] | selective_yellow [symbol] |
| 100010001 [symbol] | sepia [symbol] |
| 100010010 [symbol] | shamrock_green [symbol] |
| 100010011 [symbol] | shocking_pink [symbol] |
| 100010100 [symbol] | silver [symbol] |
| 100010101 [symbol] | sky_blue [symbol] |
| 100010110 [symbol] | slate_grey [symbol] |
| 100010111 [symbol] | smalt_dark_power_blue [symbol] |
| 100011000 [symbol] | spring_bud [symbol] |
| 100011001 [symbol] | spring_green [symbol] |
| 100011010 [symbol] | steel_blue [symbol] |
| 100011011 [symbol] | tan [symbol] |
| 100011100 [symbol] | tangerine [symbol] |
| 100011101 [symbol] | tangerine_yellow [symbol] |
| 100011110 [symbol] | taupe [symbol] |
| 100011111 [symbol] | tea_green [symbol] |
| 100100000 [symbol] | tea_rose_orange [symbol] |
| 100100001 [symbol] | tea_rose_rose [symbol] |
| 100100010 [symbol] | teal [symbol] |
| 100100011 [symbol] | tenne_tawny [symbol] |
| 100100100 [symbol] | terra_cotta [symbol] |
| 100100101 [symbol] | thistle [symbol] |
| 100100110 [symbol] | tomato [symbol] |
| 100100111 [symbol] | turquoise [symbol] |
| 100101000 [symbol] | tyrian_purple [symbol] |
| 011101011 [symbol] | pink-orange [symbol] |
| 011101100 [symbol] | platinum [symbol] |
| 011101101 [symbol] | plum_web [symbol] |
| 011101110 [symbol] | powder_blue_web [symbol] |
| 011101111 [symbol] | puce [symbol] |
| 011110000 [symbol] | prussian_blue [symbol] |
| 011110001 [symbol] | psychedelic_purple [symbol] |
| 011110010 [symbol] | pumpkin [symbol] |
| 011110011 [symbol] | purple_html/css [symbol] |
| 011110100 [symbol] | purble_x11 [symbol] |
| 011110101 [symbol] | purble_taupe [symbol] |
| 011110110 [symbol] | raw_umber [symbol] |
| 011110111 [symbol] | razzmatazz [symbol] |
| 011111000 [symbol] | red [symbol] |
| 011111001 [symbol] | red_pigment [symbol] |
| 011111010 [symbol] | red_ryb [symbol] |
| 011111011 [symbol] | red_violet [symbol] |
| 011111100 [symbol] | rich_carmine [symbol] |
| 011111101 [symbol] | robin_egg_blue [symbol] |
| 011111110 [symbol] | rose [symbol] |
| 011111111 [symbol] | rose_madder [symbol] |
| 100000000 [symbol] | rose_taupe [symbol] |
| 100000001 [symbol] | royal_blue [symbol] |
| 100000010 [symbol] | royal_purple [symbol] |
| 100000011 [symbol] | ruby [symbol] |
| 100000100 [symbol] | russet [symbol] |
| 100000101 [symbol] | rust [symbol] |
| 100000110 [symbol] | safety_orange_blaze_orange [symbol] |
| 100000111 [symbol] | saffron [symbol] |
| 100001000 [symbol] | salmon [symbol] |
| 100001001 [symbol] | sandy_brown [symbol] |
| 100001010 [symbol] | sangria [symbol] |
| 100101001 [symbol] | ultramarine [symbol] |
| 100101010 [symbol] | ultra_pink [symbol] |
| 100101011 [symbol] | united_nation_blue [symbol] |
| 100101100 [symbol] | vegas_gold [symbol] |
| 100101101 [symbol] | vermilion [symbol] |
| 100101110 [symbol] | violet [symbol] |
| 100101111 [symbol] | violet_web [symbol] |
| 100110000 [symbol] | violet_ryb [symbol] |
| 100110001 [symbol] | viridian [symbol] |
| 100110010 [symbol] | wheat [symbol] |
| 100110011 [symbol] | white [symbol] |
| 100110100 [symbol] | wisteria [symbol] |
| 100110101 [symbol] | yellow [symbol] |
| 100110110 [symbol] | yellow_process [symbol] |
| 100110111 [symbol] | yellow_ryb [symbol] |
| 100111000 [symbol] | yellow_green [symbol] |
| 100111001-111111111 [symbol] | Reserved [symbol] |

Table 108 shows descriptor components semantics regarding the light type sensory device.

TABLE 108

| Names [symbol] | Description [symbol] |
|---|---|
| LightType [symbol] | Tool for describing a command for a lighting |
| | device to follow. [symbol] |
| colorFlag [symbol] | This field, which is only present in the binary |
| | representation, signals the presence of color |
| | attribute. A value of “1” means the attribute |
| | shall be used and “0” means the attribute shall |
| | not be used. [symbol] |
| intensityFlag [symbol] | This field, which is only present in the binary |
| | representation, signals the presence of |
| | device command attribute. A value of “1” |
| | means the attribute shall be used and “0” |
| | means the attribute shall not be used. [symbol] |
| DeviceCommandBase [symbol] | Provides the topmost type of the base type |
| | hierarchy which each individual device |
| | command can inherit. [symbol] |
| color [symbol] | Describes the list of colors which the lighting |
| | device can sense as a reference to a |
| | classification scheme term or as RGB value. |
| | A CS that may be used for this purpose is the |
| | colorCS defined in A.2.3 of ISO/IEC 23005-6 |
| | and use the binary representation defined |
| | above. [symbol] |
| intensity [symbol] | Describes the command value of the light |
| | device with respect to the default unit if the |
| | unit is not defined. Otherwise, use the unit type |
| | defined in the sensor capability. [symbol] |

Table 109 shows an XML representation syntax regarding the flash type sensory device.

```
TABLE 109
      <!-- ################################################ -->
      <!-- Definition of DCV Flash Type -->
      <!-- ################################################-->
      <complexType name=“FlashType”>
            <complexContent>
                  <extension base=“dcv:LightType”>
                        <attribute name=“frequency”
type=“positiveInteger” use=“optional”/>
                  </extension>
            </complexContent>
      </complexType>
```

Table 110 shows a binary representation syntax regarding the flash type sensory device.

TABLE 110

| FlashType{ | Number of bits | Mnemonic |
|---|---|---|
| frequencyFlag | 1 | bslbf |
| Light | | LightType |
| if(frequencyFlag) { | | |
| frequency | 8 | uimsbf |
| } | | |
| } | | |

Table 111 shows descriptor components semantics regarding the flash type sensory device.

TABLE 111

| Names [symbol] | Description [symbol] |
|---|---|
| FlashType [symbol] | Tool for describing a flash device command. [symbol] |
| frequencyFlag [symbol] | This field, which is only present in the binary |
| | representation, signals the presence of color attribute. |
| | A value of “1” means the attribute shall be used and |
| | “0”means the attribute shall not be used. [symbol] |
| Light [symbol] | Describes a command for a lighting device. [symbol] |
| frequency [symbol] | Describes the number of flickering in percentage with |
| | respect to the maximum frequency that the specific |
| | flash device can generate. [symbol] |

Table 112 shows an XML representation syntax regarding the heating type sensory device.

TABLE 112

```
<!-- ################################################ -->
<!-- Definition of DCV Heating Type -->
<!-- ################################################ -->
<complexType name=“HeatingType”>
    <complexContent>
          <extension base=“iidl:DeviceCommandBaseType”>
                <attribute name=“intensity” type=“integer”
                use=“optional”/>
          </extension>
    </complexContent>
</complexType>
```

Table 113 shows a binary representation syntax regarding the heating type sensory device.

TABLE 113

| HeatingType{ | Number of bits | Mnemonic |
|---|---|---|
| intensityFlag | 1 | bslbf |
| DeviceCommandBase | | DeviceCommandBaseType |
| if(intensityFlag) { | | |
| intensity | 7 | uimsbf |
| } | | |
| } | | |

Table 114 shows descriptor components semantics regarding the heating type sensory device.

TABLE 114

| Names [symbol] | Description [symbol] |
|---|---|
| HeatingType [symbol] | Tool for describing a command for heating |
| | device. [symbol] |
| intensityFlag [symbol] | This field, which is only present in the binary |
| | representation, signals the presence of device |
| | command attribute. A value of “1” means the |
| | attribute shall be used and “0” means the |
| | attribute shall not be used. [symbol] |
| DeviceCommandBase [symbol] | Provides the topmost type of the base type |
| | hierarchy which each individual device |
| | command can inherit. [symbol] |
| intensity [symbol] | Describes the command value of the light |
| | device with respect to the default unit if the |
| | unit is not defined. Otherwise, use the unit type |
| | defined in the sensor capability. [symbol] |

Table 115 shows an XML representation syntax regarding the cooling type sensory device.

TABLE 115

```
<!-- ################################################ -->
<!-- Definition of DCV Cooling Type -->
<!-- ################################################ -->
<complexType name=“CoolingType”>
    <complexContent>
          <extension base=“iidl:DeviceCommandBaseType”>
                <attribute name=“intensity” type=“integer”
                use=“optional”/>
          </extension>
    </complexContent>
</complexType>
```

Table 116 shows a binary representation syntax regarding the cooling type sensory device.

TABLE 116

| CoolingType{ | Number of bits | Mnemonic |
|---|---|---|
| intensityFlag | 1 | bslbf |
| DeviceCommandBase | | DeviceCommandBaseType |
| if(intensityFlag) { | | |
| intensity | 7 | uimsbf |
| } | | |
| } | | |

Table 117 shows descriptor components semantics regarding the cooling type sensory device.

TABLE 117

| Names [symbol] | Description [symbol] |
|---|---|
| Cooling Type [symbol] | Tool for describing a command for |
| | cooling device. [symbol] |
| intensityFlag [symbol] | This field, which is only present in the binary |
| | representation, signals the presence of device |
| | command attribute. A value of “1” means the |
| | attribute shall be used and “0” means |
| | the attribute shall not be used. [symbol] |
| DeviceCommandBase [symbol] | Provides the topmost type of the base |
| | type hierarchy which each individual device |
| | command can inherit. [symbol] |
| intensity [symbol] | Describes the command value of the light |
| | device with respect to the default unit if the |
| | unit is not defined. Otherwise, use the unit |
| | type defined in the sensor capability. [symbol] |

Table 118 shows an XML representation syntax regarding the wind type sensory device.

TABLE 118

```
<!-- ################################################ -->
<!-- Definition of DCV Wind Type -->
<!-- ################################################ -->
<complexType name=“WindType”>
    <complexContent>
          <extension base=“iidl:DeviceCommandBaseType”>
                <attribute name=“intensity” type=“integer”
                use=“optional”/>
          </extension>
    </complexContent>
</complexType>
```

Table 119 shows a binary representation syntax regarding the wind type sensory device.

TABLE 119

| | Number | |
|---|---|---|
| | of bits | Mnemonic |
| WindType{ | | |
| intensityFlag | 1 | bslbf |
| DeviceCommandBase | | DeviceCommandBaseType |
| if(intensityFlag) { | | |
| intensity | 7 | uimsbf |
| } | | |
| } | | |

Table 120 shows descriptor components semantics regarding the wind type sensory device.

TABLE 120

| Names [symbol] | Description [symbol] |
|---|---|
| WindType [symbol] | Tool for describing a wind device command. [symbol] |
| intensityFlag [symbol] | This field, which is only present in the |
| | binary representation, signals the presence of |
| | device command attribute. A value of “1” means |
| | the attribute shall be used and “0” means |
| | the attribute shall not be used. [symbol] |
| DeviceCommandBase [symbol] | Provides the topmost type of the base |
| | type hierarchy which each individual |
| | device command can inherit. [symbol] |
| intensity [symbol] | Describes the command value of the light |
| | device with respect to the default unit if the |
| | unit is not defined. Otherwise, use the unit type |
| | defined in the sensor capability. [symbol] |

Table 121 shows an XML representation syntax regarding the vibration type sensory device.

TABLE 121

```
<!-- ################################################ -->
<!-- Definition of DCV Vibration Type -->
<!-- ################################################ -->
<complexType name=“VibrationType”>
    <complexContent>
          <extension base=“iidl:DeviceCommandBaseType”>
                <attribute name=“intensity” type=“integer”
                use=“optional”/>
          </extension>
    </complexContent>
</complexType>
```

Table 122 shows an XML representation syntax regarding the vibration type sensory device.

TABLE 122

| | Number | |
|---|---|---|
| | of bits | Mnemonic |
| VibrationType{ | | |
| intensityFlag | 1 | bslbf |
| DeviceCommandBase | | DeviceCommandBaseType |
| if(intensityFlag) { | | |
| intensity | 7 | uimsbf |
| } | | |
| } | | |

Table 123 shows descriptor components semantics regarding the vibration type sensory device.

TABLE 123

| Names [symbol] | Description [symbol] |
|---|---|
| VibrationType [symbol] | Tool for describing a vibration device |
| | command. [symbol] |
| intensityFlag [symbol] | This field, which is only present in the |
| | binary representation, signals the presence |
| | of device command attribute. A value of “1” |
| | means the attribute shall be used and “0” |
| | means the attribute shall not be used. [symbol] |
| DeviceCommandBase [symbol] | Provides the topmost type of the base type |
| | hierarchy which each individual device |
| | command can inherit. [symbol] |
| intensity [symbol] | Describes the command value of the light |
| | device with respect to the default unit if the |
| | unit is not defined. Otherwise, use the unit |
| | type defined in the sensor capability. [symbol] |

Table 124 shows an XML representation syntax regarding the scent type sensory device.

TABLE 124

```
<!-- ################################################ -->
<!-- Definition of DCV Scent Type -->
<!-- ################################################ -->
<complexType name=“ScentType”>
    <complexContent>
          <extension base=“iidl:DeviceCommandBaseType”>
                <attribute name=“scent”
type=“mpeg7:termReferenceType” use=“optional”/>
                <attribute name=“intensity” type=“integer”
                use=“optional”/>
          </extension>
    </complexContent>
</complexType>
```

Table 125 shows a binary representation syntax regarding the scent type sensory device.

TABLE 125

| | Number | |
|---|---|---|
| | of bits | Mnemonic |
| ScentType{ | | |
| scentFlag | 1 | bslbf |
| intensityFlag | 1 | bslbf |
| DeviceCommandBase | | DeviceCommandBaseType |
| if(scentFlag) { | | |
| scent | | ScentCSType |
| } | | |
| if(intensityFlag) { | | |
| intensity | 7 | uimsbf |
| } | | |
| } | | |

Table 126 shows a binary representation syntax regarding the scent type.

TABLE 126

| ScentCSType [symbol] | Term ID of Spraying [symbol] |
|---|---|
| 0000 [symbol] | rose [symbol] |
| 0001 [symbol] | acacia [symbol] |
| 0010 [symbol] | chrysanthemum [symbol] |
| 0011 [symbol] | lilac [symbol] |
| 0100 [symbol] | mint [symbol] |
| 0101 [symbol] | jasmine [symbol] |
| 0110 [symbol] | pine_tree [symbol] |
| 0111 [symbol] | orange [symbol] |
| 1000 [symbol] | grape [symbol] |
| 1001-1111 [symbol] | Reserved [symbol] |

Table 127 shows descriptor components semantics regarding the scent type sensory device.

TABLE 127

| Names [symbol] | Description [symbol] |
|---|---|
| ScentType [symbol] | Tool for describing a scent device command. [symbol] |
| scentFlag [symbol] | This field, which is only present in the binary |
| | representation, signals the presence of |
| | device command attribute. A value of “1” |
| | means the attribute shall be used and “0” |
| | means the attribute shall not be used. [symbol] |
| intensityFlag [symbol] | This field, which is only present in the binary |
| | representation, signals the presence of |
| | device command attribute. A value of “1” |
| | means the attribute shall be used and “0” |
| | means the attribute shall not be used. [symbol] |
| DeviceCommandBase [symbol] | Provides the topmost type of the base type |
| | hierarchy which each individual device |
| | command can inherit. [symbol] |
| scent [symbol] | Describes the scent to use. A CS that may be |
| | used for this purpose is the ScentCS defined in |
| | the Annex A:2.4 of ISO/IEC 23005-6. [symbol] |
| intensity [symbol] | Describes the command value of the light |
| | device with respect to the default unit if the |
| | unit is not defined. Otherwise, use the unit type |
| | defined in the sensor capability. [symbol] |

Table 128 shows an XML representation syntax regarding the fog type sensory device.

TABLE 128

```
<!-- ################################################ -->
<!-- Definition of DCV Fog Type -->
<!-- ################################################ -->
<complexType name=“FogType”>
    <complexContent>
          <extension base=“iidl:DeviceCommandBaseType”>
                <attribute name=“intensity” type=“integer”
                use=“optional”/>
          </extension>
    </complexContent>
</complexType>
```

Table 129 shows a binary representation syntax regarding the fog type sensory device.

TABLE 129

| | Number | |
|---|---|---|
| | of bits | Mnemonic |
| FogType{ | | |
| intensityFlag | 1 | bslbf |
| DeviceCommandBase | | DeviceCommandBaseType |
| if(intensityFlag) { | | |
| intensity | 7 | uimsbf |
| } | | |
| } | | |

Table 130 shows descriptor components semantics regarding the fog type sensory device.

TABLE 130

| Names [symbol] | Description [symbol] |
|---|---|
| FogType [symbol] | Tool for describing a fog device command. [symbol] |
| intensityFlag [symbol] | This field, which is only present in the |
| | binary representation, signals the presence |
| | of device command attribute. A value of “1” |
| | means the attribute shall be used and “0” |
| | means the attribute shall not be used. [symbol] |
| DeviceCommandBase [symbol] | Provides the topmost type of the base type |
| | hierarchy which each individual device |
| | command can inherit. [symbol] |
| intensity [symbol] | Describes the command value of the light |
| | device with respect to the default unit if the |
| | unit is not defined. Otherwise, use the unit type |
| | defined in the sensor capability. [symbol] |

Table 131 shows an XML representation syntax regarding the sprayer type sensory device.

```
TABLE 131
      <!-- ################################################ -->
      <!-- Definition of DCV Sprayer Type -->
      <!-- ################################################ -->
      <complexType name=“SprayerType”>
          <complexContent>
                <extension base=“iidl:DeviceCommandBaseType”>
                      <attribute name=“sprayingType”
type=“mpeg7:termReferenceType”/>
                      <attribute name=“intensity” type=“integer”
                      use=“optional”/>
                </extension>
          </complexContent>
      </complexType>
```

Table 132 shows an XML representation syntax regarding the fog type sensory device.

TABLE 132

| | Number | |
|---|---|---|
| | of bits | Mnemonic |
| SprayerType{ | | |
| sprayingFlag | 1 | bslbf |
| intensityFlag | 1 | bslbf |
| DeviceCommandBase | | DeviceCommandBaseType |
| if(sprayingFlag) { | | |
| spraying | | SprayingType |
| } | | |
| if(intensityFlag) { | | |
| intensity | 7 | uimsbf |
| } | | |
| } | | |

Table 133 shows a binary representation syntax regarding the fog type.

TABLE 133

| SprayingType [symbol] | Term ID of Spraying [symbol] |
|---|---|
| 00 [symbol] | water [symbol] |
| 01-11 [symbol] | Reserved [symbol] |

Table 134 shows descriptor components semantics regarding the fog type sensory device.

TABLE 134

| Names [symbol] | Description [symbol] |
|---|---|
| SprayerType [symbol] | Tool for describing a liquid spraying |
| | device command. [symbol] |
| sprayingFlag [symbol] | This field, which is only present in the binary |
| | representation, signals the presence of |
| | device command attribute. A value of “1” |
| | means the attribute shall be used and “0” |
| | means the attribute shall not be used. [symbol] |
| intensityFlag [symbol] | This field, which is only present in the binary |
| | representation, signals the presence of |
| | device command attribute. A value of “1” |
| | means the attribute shall be used and “0” |
| | means the attribute shall not be used. [symbol] |
| DeviceCommandBase [symbol] | Provides the topmost type of the base type |
| | hierarchy which each individual device |
| | command can inherit. [symbol] |
| spraying [symbol] | Describes the type of the sprayed material as |
| | a reference to a classification scheme term. A |
| | CS that may be used for this purpose is the |
| | SprayingTypeCS defined in Annex A:2.7 of |
| | IS0/IEC 23005-6. [symbol] |
| intensity [symbol] | Describes the command value of the light |
| | device with respect to the default unit if the |
| | unit is not defined. Otherwise, use the unit type |
| | defined in the sensor capability. [symbol] |

Table 135 shows an XML representation syntax regarding the color correction type sensory device.

```
TABLE 135
      <!-- ################################################ -->
      <!-- Definition of DCV Color Correction Type -->
      <!-- ################################################ -->
      <complexType name=“ColorCorrectionType”>
          <complexContent>
                <extension base=“iidl:DeviceCommandBaseType”>
                      <sequence minOccurs=“0”
                      maxOccurs=“unbounded”>
                            <element name=“SpatialLocator”
type=“mpeg7:RegionLocatorType”/>
                      </sequence>
                </extension>
          </complexContent>
      </complexType>
```

Table 136 shows a binary representation syntax regarding the color correction type sensory device.

TABLE 136

| | Number | |
|---|---|---|
| | of bits | Mnemonic |
| ColorCorrectionType{ | | |
| intensityFlag | 1 | bslbf |
| DeviceCommandBase | | DeviceCommandBaseType |
| LoopSpatialLocator | | vluimsbf5 |
| for(k=0;k< | | |
| LoopSpatialLocator;k++){ | | |
| SpatialLocator[k] | | mpeg7:RegionLocatorType |
| } | | |
| if(intensityFlag){ | | |
| intensity | 7 | uimsbf |
| } | | |
| } | | |

Table 137 shows descriptor components semantics regarding the color correction type sensory device.

TABLE 137

| Names [symbol] | Description [symbol] |
|---|---|
| ColorCorrectionType [symbol] | Tool for commanding a display device to perform |
| | color correction. [symbol] |
| intensityFlag [symbol] | This field, which is only present in the binary |
| | representation, signals the presence of device |
| | command attribute. A value of “1” means |
| | the attribute shall be used and “0” means |
| | the attribute shall not be used. [symbol] |
| DeviceCommandBase [symbol] | Provides the topmost type of the base type |
| | hierarchy which each individual device |
| | command can inherit. [symbol] |
| LoopSpatialLocator [symbol] | This field, which is only present in the binary |
| | representation, specifies the number of |
| | SpatialLocator contained in the description. [symbol] |
| SpatialLocator [symbol] | Describes the spatial localization of the still |
| | region using SpatialLocatorType (optional), |
| | which indicates the regions in a video |
| | segment where the color correction effect |
| | is applied. The SpatialLocatorType |
| | is defined in ISO/IEC 15938-5. [symbol] |
| intensity [symbol] | Describes the command value of the light |
| | device with respect to the default unit if the |
| | unit is not defined. Otherwise, use the unit |
| | type defined in the sensor capability. [symbol] |

Table 138 shows an XML representation syntax regarding the tactile correction type sensory device.

```
TABLE 138
      <!-- ################################################ -->
      <!-- Definition of DCV Tactile Type -->
      <!-- ################################################ -->
      <complexType name=“TactileType”>
          <complexContent>
                <extension base=“iidl:DeviceCommandBaseType”>
                      <sequence>
                            <element name=“array_intensity”
type=“mpeg7:FloatMatrixType”/>
                      </sequence>
                </extension>
          </complexContent>
      </complexType>
```

Table 139 shows a binary representation syntax regarding the tactile correction type sensory device.

TABLE 139

| | Number | |
|---|---|---|
| TactileType{ | of bits | Mnemonic |
| DeviceCommandBase | | DeviceCommandBaseType |
| dimX | 16 | uimsbf |
| dimY | 16 | uimsbf |
| array_intensity | dimX * dimY * | fsbf |
| | 32 | |
| } | | |

Table 140 shows descriptor components semantics regarding the tactile correction type sensory device.

TABLE 140

| Names [symbol] | Description [symbol] |
|---|---|
| TactileType [symbol] | Tool for describing array-type tactile device |
| | command. A tactile device is composed of an |
| | array of actuators. [symbol] |
| DeviceCommandBase [symbol] | Provides the topmost type of the base type |
| | hierarchy which each individual device command |
| | can inherit. [symbol] |
| dimX [symbol] | This field, which is only present in the binary |
| | representation, specifies the x-direction size of |
| | ArrayIntensity. [symbol] |
| dimY [symbol] | This field, which is only present in the binary |
| | representation, specifies the y-direction size of |
| | ArrayIntensity. [symbol] |
| array_intensity [symbol] | Describes the intensities of array actuators in |
| | percentage with respect to the maximum intensity |
| | described in the device capability. If the intensity |
| | is not specified, this command shall be interpreted |
| | as turning on at the maximum intensity. [symbol] |

Table 141 shows an XML representation syntax regarding the kinesthetic correction type sensory device.

```
TABLE 141
      <!-- ################################################ -->
      <!-- Definition of DCV Kinesthetic Type -->
      <!-- ################################################ -->
      <complexType name=“KinestheticType”>
          <complexContent>
                <extension base=“iidl:DeviceCommandBaseType”>
                      <sequence>
                            <element name=“Position”
type=“mpegvct:Float3DVectorType” minOccurs=“0”/>
                            <element name=“Orientation”
type=“mpegvct:Float3DVectorType” minOccurs=“0”/>
                            <element name=“Force”
type=“mpegvct:Float3DVectorType” minOccurs=“0”/>
                            <element name=“Torque”
type=“mpegvct:Float3DVectorType” minOccurs=“0”/>
                      </sequence>
                </extension>
          </complexContent>
      </complexType>
```

Table 142 shows a binary representation syntax regarding the kinesthetic correction type sensory device.

TABLE 142

| | Number | |
|---|---|---|
| KinesthestheticType{ | of bits | Mnemonic |
| PositionFlag | 1 | bslbf |
| OrientationFlag | 1 | bslbf |
| ForceFlag | 1 | bslbf |
| TorqueFlag | 1 | bslbf |
| DeviceCommandBase | | DeviceCommandBaseType |
| if(PositionFlag){ | | |
| Position | | Float3DVectorType |
| } | | |
| if(OrientationFlag){ | | |
| Orientation | | Float3DVectorType |
| } | | |
| if(ForceFlag){ | | |
| Force | | Float3DVectorType |
| } | | |
| if(TorqueFlag){ | | |
| Torque | | Float3DVectorType |
| } | | |
| } | | |
| Float3DVectorType { | | |
| X | 32 | fsbf |
| Y | 32 | fsbf |
| Z | 32 | fsbf |
| } | | |

Table 143 shows descriptor components semantics regarding the kinesthetic correction type sensory device.

TABLE 143

| Names [symbol] | Description [symbol] |
|---|---|
| KinesthestheticType [symbol] | Describes a command for a kinesthetic device. [symbol] |
| PositionFlag [symbol] | This field, which is only present in the binary |
| | representation, signals the presence of device command attribute. |
| | A value of “1” means the attribute shall be |
| | used and “0” means the attribute shall not be used. [symbol] |
| OrientationFlag [symbol] | This field, which is only present in the binary |
| | representation, signals the presence of device command |
| | attribute. A value of “1” means the attribute shall be |
| | used and “0” means the attribute shall not be used. [symbol] |
| ForceFlag [symbol] | This field, which is only present in the binary |
| | representation, signals the presence of device command |
| | attribute. A value of “1” means the attribute shall be |
| | used and “0” means the attribute shall not be used. [symbol] |
| TorqueFlag [symbol] | This field, which is only present in the binary |
| | representation, signals the presence of device command |
| | attribute. A value if “1” means the attribute shall be |
| | used and “0” means the attribute shall not be used. [symbol] |
| DeviceCommandBase [symbol] | Provides the topmost type of the base type hierarchy |
| | which each individual device command can inherit. [symbol] |
| Position [symbol] | Describes the position that a kinesthetic device shall take |
| | in millimeters along each axis of X, Y, and Z, with respect |
| | to the idle position of the device. [symbol] |
| Orientation [symbol] | Describes the orientation that a kinesthetic device shall |
| | take in degrees along each axis of X, Y, and Z, with |
| | respect to the idle orientation of the device. [symbol] |
| Force [symbol] | Describes the force of kinesthetic effect in percentage |
| | with respect to the maximum force described in the device |
| | capability. If the Force is not specified, this command |
| | shall be interpreted as turning on at the maximum force. |
| | This element takes Float3DVectorType type defined in Part 6 |
| | of ISO/IEC 23005. [symbol] |
| Torque [symbol] | Describes the torque of kinesthetic effect in percentage |
| | with respect to the maximum torque described in the |
| | device capability. If the Torque is not specified, this |
| | command shall be interpreted as turning on at the |
| | maximum torque. This element takes Float3DVectorType |
| | type defined in Part of 6 of ISO/IEC 23005. [symbol] |
| Float3DVectorType [symbol] | Tool for describing a 3D vector [symbol] |
| X [symbol] | Describes the sensed value in x-axis. [symbol] |
| Y [symbol] | Describes the sensed value in y-axis. [symbol] |
| Z [symbol] | Describes the sensed value in z-axis. [symbol] |

Table 144 shows an XML representation syntax regarding the rigid body motion correction type sensory device.

```
TABLE 144
      <!-- ################################################ -->
      <!-- Definition of Rigid Body Motion Type -->
      <!-- ################################################ -->
      <complexType name=“RigidBodyMotionType”>
          <complexContent>
                <extension base=“iidl:DeviceCommandBaseType”>
                      <sequence>
                            <element name=“MoveToward”
type=“dcv:MoveTowardType” minOccurs=“0”/>
                            <element name=“Incline”
type=“dcv:InclineType” minOccurs=“0”/>
                      </sequence>
                      <attribute name=“duration” type=“float”/>
                </extension>
          </complexContent>
      </complexType>
      <complexType name=“MoveTowardType”>
          <attribute name=“directionX” type=“float”/>
          <attribute name=“directionY” type=“float”/>
          <attribute name=“directionZ” type=“float”/>
          <attribute name=“speedX” type=“float”/>
          <attribute name=“speedY” type=“float”/>
          <attribute name=“speedZ” type=“float”/>
          <attribute name=“accelerationX” type=“float”/>
          <attribute name=“accelerationY” type=“float”/>
          <attribute name=“accelerationZ” type=“float”/>
      </complexType>
      <complexType name=“InclineType”>
          <attribute name=“PitchAngle”
          type=“mpegvct:InclineAngleType” use=“optional”/>
          <attribute name=“YawAngle”
          type=“mpegvct:InclineAngleType” use=“optional”/>
          <attribute name=“RollAngle”
          type=“mpegvct:InclineAngleType” use=“optional”/>
          <attribute name=“PitchSpeed” type=“float” use=“optional”/>
          <attribute name=“YawSpeed” type=“float” use=“optional”/>
          <attribute name=“RollSpeed” type=“float” use=“optional”/>
          <attribute name=“PitchAcceleration” type=“float”
          use=“optional”/>
          <attribute name=“YawAcceleration” type=“float”
          use=“optional”/>
          <attribute name=“RollAcceleration” type=“float”
          use=“optional”/>
      </complexType>
```

Table 145 shows a binary representation syntax regarding the rigid body motion correction type sensory device.

TABLE 145

| | Number of | |
|---|---|---|
| RigidBodyMotionType{ | bits | Mnemonic |
| MoveTowardFlag | 1 | bslbf |
| InclineFlag | 1 | bslbf |
| durationFlag | 1 | bslbf |
| DeviceCommandBase | | DeviceCommandBaseType |
| if( MoveTowardFlag ) { | | |
| MoveToward | | MoveTowardTypes |
| } | | |
| if( InclineFlag ) { | | |
| Incline | | InclineType |
| } | | |
| if(durationFlag) { | | |
| duration | 32 | fsbf |
| } | | |
| } | | |
| MoveTowardType{ | | |
| directionXFlag | 1 | bslbf |
| directionYFlag | 1 | bslbf |
| directionZFlag | 1 | bslbf |
| speedXFlag | 1 | bslbf |
| speedYFlag | 1 | bslbf |
| speedZFlag | 1 | bslbf |
| accelerationXFlag | 1 | bslbf |
| accelerationYFlag | 1 | bslbf |
| accelerationZFlag | 1 | bslbf |
| if( directionXFlag){ | | |
| directionX | 32 | fsbf |
| } | | |
| if( directionYFlag){ | | |
| directionY | 32 | fsbf |
| } | | |
| if( directionZFlag){ | | |
| directionZ | 32 | fsbf |
| } | | |
| if(speedXFlag){ | | |
| speedX | 32 | fsbf |
| } | | |
| if(speedYFlag){ | | |
| speedY | 32 | fsbf |
| } | | |
| if(speedZFlag){ | | |
| speedZ | 32 | fsbf |
| } | | |
| if(accelerationXFlag){ | | |
| accelerationX | 32 | fsbf |
| } | | |
| if(accelerationYFlag){ | | |
| accelerationY | 32 | fsbf |
| } | | |
| if(accelerationZFlag){ | | |
| accelerationZ | 32 | fsbf |
| } | | |
| } | | |
| InclineType{ | | |
| PitchAngleFlag | 1 | bslbf |
| YawAngleFlag | 1 | bslbf |
| RollAngleFlag | 1 | bslbf |
| PitchSpeedFlag | 1 | bslbf |
| YawSpeedFlag | 1 | bslbf |
| RollSpeedFlag | 1 | bslbf |
| PitchAccelerationFlag | 1 | bslbf |
| YawAccelerationFlag | 1 | bslbf |
| RollAccelerationFlag | 1 | bslbf |
| if(PitchAngleFlag){ | | |
| PitchAngle | | InclineAngleType |
| } | | |
| if(YawAngleFlag){ | | |
| YawAngle | | InclineAngleType |
| } | | |
| if(RollAngleFlag){ | | |
| RollAngle | | InclineAngleType |
| } | | |
| if(PitchSpeedFlag){ | | |
| PitchSpeed | 32 | fsbf |
| } | | |
| if(YawSpeedFlag){ | | |
| YawSpeed | 32 | fsbf |
| } | | |
| if(RollSpeedFlag){ | | |
| RollSpeed | 32 | fsbf |
| } | | |
| if(PitchAccelerationFlag){ | | |
| PitchAcceleration | 32 | fsbf |
| } | | |
| if(YawAccelerationFlag){ | | |
| YawAcceleration | 32 | fsbf |
| } | | |
| if(RollAccelerationFlag){ | | |
| RollAcceleration | 32 | fsbf |
| } | | |
| } | | |

Table 146 shows a binary representation syntax of command information regarding the rigid body motion correction type sensory device according to other embodiments.

TABLE 146

| | Number | |
|---|---|---|
| RigidBodyMotionType{ | of bits | Mnemonic |
| FirstFlag | 1 | bslbf |
| MoveTowardFlag | 1 | bslbf |
| InclineFlag | 1 | bslbf |
| DeviceCommandBase | | DeviceCommandBase- |
| | | Type |
| if( FirstFlag ){ | 1 | bslbf |
| if( MoveTowardFlag ) { | | |
| MoveToward | | MoveTowardType |
| } | | |
| if( InclineFlag ) { | | |
| Incline | | InclineType |
| } | | |
| } else { | | |
| if( MoveTowardFlag ) { | | |
| MoveTowardMask | 9 | bslbf |
| NumOfModify | 3 | uimsbf |
| for( k=0;k<NumOfModify;k++ | | |
| ) { | | |
| MoveToward | | MoveTowardType |
| } | | |
| } | | |
| if( InclineFlag ) { | | |
| InclineMask | 9 | bslbf |
| NumOfModify | 3 | uimsbf |
| for( k=0;k<NumOfModify;k++ | | |
| ) { | | |
| Incline | | InclineType |
| } | | |
| } | | |
| } | | |
| } | | |

Table 147 shows descriptor components semantics of command information regarding the rigid body motion correction type sensory device according to embodiments.

TABLE 147

| Names [symbol] | Description [symbol] |
|---|---|
| RigidBodyMotionType [symbol] | Tool for describing a rigid body motion device |
| | command. [symbol] |
| MoveTowardFlag [symbol] | This field, which is only present in the binary |
| | representation, signals the presence of device |
| | command attribute. A value of “1” means |
| | the attribute shall be used and “0” means the |
| | attribute shall not be used. [symbol] |
| InclineFlag [symbol] | This field, which is only present in the binary |
| | representation, signals the presence of device |
| | command attribute. A value of “1” means |
| | the attribute shall be used and “0” means the |
| | attribute shall not be used. [symbol] |
| durationFlag [symbol] | This field, which is only present in the binary |
| | representation, signals the presence of device |
| | command attribute. A value of “1” means |
| | the attribute shall be used and “0” means the |
| | attribute shall not be used. [symbol] |
| DeviceCommandBase [symbol] | Provides the topmost type of the base type |
| | hierarchy which each individual device |
| | command can inherit. [symbol] |
| MoveToward [symbol] | Describes the destination axis values of move |
| | toward effect. The type is defined by |
| | dcv:MoveTowardType. [symbol] |
| Incline [symbol] | Describes the rotation angle of incline effect. |
| | The type is defined by dcv:InclineType. [symbol] |
| Duration [symbol] | Describes time period during which the rigid |
| | body object should continuously move. The |
| | object which reaches the destination |
| | described by the description of |
| | RigidBodyMotionType should stay at the |
| | destination until it receives another command |
| | with activate = “false”. [symbol] |
| MoveTowardType [symbol] | Tool for describing MoveToward commands |
| | for each axis. [symbol] |
| directionXFlag [symbol] | This field, which is only present in the binary |
| | representation, signals the presence of device |
| | command attribute. A value of “1” means |
| | the attribute shall be used and “0” means the |
| | attribute shall not be used. [symbol] |
| directionYFlag [symbol] | This field, which is only present in the binary |
| | representation, signals the presence of device |
| | command attribute. A value of “1” means |
| | the attribute shall be used and “0” means the |
| | attribute shall not be used. [symbol] |
| directionZFlag [symbol] | This field, which is only present in the binary |
| | representation, signals the presence of device |
| | command attribute. A value of “1” means |
| | the attribute shall be used and “0” means the |
| | attribute shall not be used. [symbol] |
| speedXFlag [symbol] | This field, which is only present in the binary |
| | representation, signals the presence of device |
| | command attribute. A value of “1” means |
| | the attribute shall be used and “0” means the |
| | attribute shall not be used. [symbol] |
| speedYFlag [symbol] | This field, which is only present in the binary |
| | representation, signals the presence of device |
| | command attribute. A value of “1” means |
| | the attribute shall be used and “0” means the |
| | attribute shall not be used. [symbol] |
| speedZFlag [symbol] | This field, which is only present in the binary |
| | representation, signals the presence of device |
| | command attribute. A value of “1” means |
| | the attribute shall be used and “0” means the |
| | attribute shall not be used. [symbol] |
| accelerationXFlag [symbol] | This field, which is only present in the binary |
| | representation, signals the presence of device |
| | command attribute. A value of “1” means |
| | the attribute shall be used and “0” means the |
| | attribute shall not be used. [symbol] |
| accelerationYFlag [symbol] | This field, which is only present in the binary |
| | representation, signals the presence of device |
| | command attribute. A value of “1” means |
| | the attribute shall be used and “0” means the |
| | attribute shall not be used. [symbol] |
| accelerationZFlag [symbol] | This field, which is only present in the binary |
| | representation, signals the presence of device |
| | command attribute. A value of “1” means |
| | the attribute shall be used and “0” means the |
| | attribute shall not be used. [symbol] |
| directionX [symbol] | Describes the position command on x-axis in |
| | terms of centimeter with respect to the |
| | current position. [symbol] |
| directionY [symbol] | Describes the position command on y-axis in |
| | terms of centimeter with respect to the |
| | current position. [symbol] |
| directionZ [symbol] | Describes the position command on z-axis in |
| | terms of centimeter with respect to the |
| | current position. [symbol] |
| speedX [symbol] | Describes the desired speed of the rigid body |
| | object on the x-axis in terms of percentage |
| | with respect to the maximum speed of the |
| | specific device which also be described in the |
| | device capability as defined in Part 2 of |
| | ISO/IEC 23005. [symbol] |
| SpeedY [symbol] | Describes the desired speed of the rigid body |
| | object on the y-axis in terms of percentage |
| | with respect to the maximum speed of the |
| | specific device which also be described in the |
| | device capability as defined in Part 2 of |
| | ISO/IEC 23005. [symbol] |
| speedZ [symbol] | Describes the desired speed of the rigid body |
| | object on the z-axis in terms of percentage |
| | with respect to the maximum speed of the |
| | specific device which also be described in the |
| | device capability as defined in Part 2 of |
| | ISO/IEC 23005. [symbol] |
| accelerationX [symbol] | Describes the desired acceleration of the rigid |
| | body object on the x-axis in terms of |
| | percentage with respect to the maximum |
| | acceleration of the specific device which may |
| | be described in the device capability as |
| | defined in Part 2 of ISO/IEC 23005. [symbol] |
| accelerationY- [symbol] | Describes the desired acceleration of the rigid |
| | body object on the y-axis in terms of |
| | percentage with respect to the maximum |
| | acceleration of the specific device which may |
| | be described in the device capability as |
| | defined in Part 2 of ISO/IEC 23005. [symbol] |
| accelerationZ- [symbol] | Describes the desired acceleration of the rigid |
| | body object on the z-axis in terms of |
| | percentage with respect to the maximum |
| | acceleration of the specific device which may |
| | be described in the device capability as |
| | defined in Part 2 of ISO/IEC 23005. [symbol] |
| InclineType [symbol] | Tool for describing Incline commands for each |
| | axis. [symbol] |
| PitchAngleFlag [symbol] | This field, which is only present in the binary |
| | representation, signals the presence of device |
| | command attribute. A value of “1” means |
| | the attribute shall be used and “0” means the |
| | attribute shall not be used. [symbol] |
| YawAngleFlag [symbol] | This field, which is only present in the binary |
| | representation, signals the presence of device |
| | command attribute. A value of “1” means |
| | the attribute shall be used and “0” means the |
| | attribute shall not be used. [symbol] |
| RollAngleFlag [symbol] | This field, which is only present in the binary |
| | representation, signals the presence of device |
| | command attribute. A value of “1” means |
| | the attribute shall be used and “0” means the |
| | attribute shall not be used. [symbol] |
| PitchSpeedFlag [symbol] | This field, which is only present in the binary |
| | representation, signals the presence of device |
| | command attribute. A value of “1” means |
| | the attribute shall be used and “0” means the |
| | attribute shall not be used. [symbol] |
| YawSpeedFlag [symbol] | This field, which is only present in the binary |
| | representation, signals the presence of device |
| | command attribute. A value of “1” means |
| | the attribute shall be used and “0” means the |
| | attribute shall not be used. [symbol] |
| RollSpeedFlag [symbol] | This field, which is only present in the binary |
| | representation, signals the presence of device |
| | command attribute. A value of “1” means |
| | the attribute shall be used and “0” means the |
| | attribute shall not be used. [symbol] |
| PitchAccelerationFlag [symbol] | This field, which is only present in the binary |
| | representation, signals the presence of device |
| | command attribute. A value of “1” means |
| | the attribute shall be used and “0” means the |
| | attribute shall not be used. [symbol] |
| YawAccelerationFlag [symbol] | This field, which is only present in the binary |
| | representation, signals the presence of device |
| | command attribute. A value of “1” means |
| | the attribute shall be used and “0” means the |
| | attribute shall not be used. [symbol] |
| RollAccelerationFlag [symbol] | This field, which is only present in the binary |
| | representation, signals the presence of device |
| | command attribute. A value of “1” means |
| | the attribute shall be used and “0” means the |
| | attribute shall not be used. [symbol] |
| PitchAngle [symbol] | Describes the angle to rotate in y-axis, |
| | Θ(pitch) in degrees between −180 and 180. [symbol] |
| YawAngle [symbol] | Describes the angle to rotate in z-axis, |
| | ψ(yaw) in degrees between −180 and 180. [symbol] |
| RollAngle [symbol] | Describes the angle to rotate in x-axis, o |
| | (roll), in degrees between −180, and 180. [symbol] |
| PitchSpeed [symbol] | Describes the desired speed (command) of |
| | rotation for pitch in terms of percentage with |
| | respect to the maximum angular speed of the |
| | specific device which may be described in the |
| | device capability as defined in Part 2 of |
| | ISO/IEC 23005. [symbol] |
| YawSpeed [symbol] | Describes the desired speed (command) of |
| | rotation for yaw in terms of percentage with |
| | respect to the maximum angular speed of the |
| | specific device which may be described in the |
| | device capability as defined in Part 2 of |
| | ISO/IEC 23005. [symbol] |
| RollSpeed [symbol] | Describes the desired speed (command) of |
| | rotation for roll in terms of percentage with |
| | respect to the maximum angular speed of the |
| | specific device which may be described in the |
| | device capability as defined in Part 2 of |
| | ISO/IEC 23005. [symbol] |
| PitchAcceleration [symbol] | Describes the desired acceleration (command) |
| | of rotation for pitch in terms of percentage |
| | with respect to the maximum angular |
| | acceleration of the specific device which may |
| | be described in the device capability as |
| | defined in Part 2 of ISO/IEC 23005. [symbol] |
| YawAcceleration [symbol] | Describes the desired acceleration (command) |
| | of rotation for yaw in terms of percentage |
| | with respect to the maximum angular |
| | acceleration of the specific device which may |
| | be described in the device capability as |
| | defined in Part 2 of ISO/IEC 23005. [symbol] |
| RollAcceleration [symbol] | Describes the desired acceleration (command) |
| | of rotation for roll in terms of percentage with |
| | respect to the maximum angular acceleration |
| | of the specific device which may be described |
| | in the device capability as defined in Part 2 of |
| | ISO/IEC 23005. [symbol] |
| FirstFlag [symbol] | This field, which is only present in the binary |
| | representation, signals the presence of device |
| | command attribute. A value of “1” means |
| | the attribute shall be used and “0” means the |
| | attribute shall not be used. [symbol] |
| MoveTowardMask [symbol] | This field, which is only present in the binary |
| | syntax, specifies a bit-field that indicates |
| | whether a MoveToward is assigned to the |
| | corresponding partition. [symbol] |
| NumOfModify [symbol] | This field which is only present in the binary |
| | representation, specifies the number of |
| | modified elements contained in the |
| | description. [symbol] |
| InclineMask [symbol] | This field, which is only present in the binary |
| | syntax, specifies a bit-field that indicates |
| | whether an Incline is assigned to the |
| | corresponding partition. [symbol] |

The color correction type may include an initialize color correction parameter type.

The initialize color correction parameter type may include a tone reproduction curves type, a conversion LUT type, an illuminant type, and an input device color gamut type.

Table 148 shows an XML representation syntax regarding the initialize color correction parameter type.

```
TABLE 148
      <!-- ############################################################### -->
      <!-- Definition of SDCmd Initialize Color Correction Parameter Type -->
      <!-- ############################################################### -->
      <complexType name=“InitializeColorCorrectionParameterType”>
          <complexContent>
                <extension base=“iidl:DeviceCommandBaseType”>
                      <sequence>
                            <element name=“ToneReproductionCurves”
type=“mpegvct:ToneReproductionCurvesType” minOccurs=“0”/>
                            <element name=“ConversionLUT”
type=“mpegvct:ConversionLUTType”/>
                            <element name=“ColorTemperature”
type=“mpegvct:IlluminantType” minOccurs=“0”/>
                            <element name=“InputDeviceColorGamut”
type=“mpegvct:InputDeviceColorGamutType” minOccurs=“0”/>
                            <element name=“IlluminanceOfSurround”
type=“mpeg7:unsigned12” minOccurs=“0”/>
                      </sequence>
                </extension>
          </complexContent>
      </complexType>
```

Table 149 shows a binary representation syntax regarding the initialize color correction parameter type.

TABLE 149

| | Number | |
|---|---|---|
| InitializeColorCorrectinParameterType{ | of bits | Mnemonic |
| ToneReproductionCurvesFlag | 1 | bslbf |
| ConversionLUTFlag | 1 | bslbf |
| ColorTemperatureFlag | 1 | bslbf |
| InputDeviceColorGamutFlag | 1 | bslbf |
| IlluminanceOfSurroundFlag | 1 | bslbf |
| DeviceCommandBase | | DeviceCommandBase- |
| | | Type |
| if(ToneReproductionCurvesFlag) | | |
| { | | |
| ToneReproductionCurves | | ToneReproduction- |
| | | CurvesType |
| } | | |
| if(ConversionLUTFlag) { | | |
| ConversionLUT | | ConversionLUTType |
| } | | |
| if(ColorTemperatureFlag) { | | |
| ColorTemperature | | IlluminantType |
| } | | |
| if(InputDeviceColorGamutFlag) { | | |
| InputDeviceColorGamut | | InputDeviceColor- |
| | | GamutType |
| } | | |
| if(IlluminanceOfSurroundFlag) { | | |
| IlluminanceOfSurround | 12 | uimsbf |
| } | | |
| } | | |

Table 150 shows a binary representation syntax of the tone reproduction curves type according to embodiments.

TABLE 150

| | Number | |
|---|---|---|
| ToneReproductionCurvesType { | of bits | Mnemonic |
| NumOfRecords | 8 | uimsbf |
| for(i=0;i< NumOfRecords;i++){ | | |
| DAC_Value | 8 | mpeg7:unsigned8 |
| RGB_Value | 32 * 3 | mpeg7:doubleVector |
| } | | |
| } | | |

Table 151 shows a binary representation syntax of the conversion LUT type according to embodiments.

TABLE 151

| ConversionLUTType { | Number of bits | Mnemonic |
|---|---|---|
| RGB2XYZ_LUT | 32 * 3 * 3 | mpeg7:DoubleMatrixType |
| RGBScalar_Max | 32 * 3 | mpeg7:doubleVector |
| Offset_Value | 32 * 3 | mpeg7:doubleVector |
| Gain_Offset_Gamma | 32 * 3 * 3 | mpeg7:DoubleMatrixType |
| InverseLUT | 32 * 3 * 3 | mpeg7:DoubleMatrixType |
| } | | |

Table 152 shows a binary representation syntax of the illuminant type according to embodiments.

TABLE 152

| IlluminantType { | Number of bits | Mnemonic |
|---|---|---|
| ElementType | 1 | bslbf |
| if(ElementType==00){ | | |
| XY_Value | 32 * 2 | dia:ChromaticityType |
| Y_Value | 7 | uimsbf |
| }else if(ElementType==01){ | | |
| Correlated_CT | 8 | uimsbf |
| } | | |
| } | | |

Table 153 shows a binary representation syntax of the input device color gamut type according to embodiments.

TABLE 153

| InputDeviceColorGamutType { | Number of bits | Mnemonic |
|---|---|---|
| typeLength | | vluimsbf5 |
| IDCG_Type | 8 * typeLength | bslbf |
| IDCG_Value | 32 * 3 * 2 | mpeg7:DoubleMatrix- |
| | | Type |
| } | | |

Table 154 shows descriptor components semantics of the initialize color correction parameter type.

TABLE 154

| Names [symbol] | Description [symbol] |
|---|---|
| InitializeColorCorrectinParameterType [symbol] | Tool for describing an initialize color |
| | correction parameter command. [symbol] |
| ToneReproductionCurvesFlag [symbol] | This field, which is only present in the binary |
| | representation, signals the presence of device |
| | command attribute. A value of “1” means |
| | the attribute shall be used and “0” means the |
| | attribute shall not be used. [symbol] |
| ConversionLUTFlag [symbol] | This field, which is only present in the binary |
| | representation, signals the presence of device |
| | command attribute. A value of “1” means |
| | the attribute shall be used and “0” means the |
| | attribute shall not be used. [symbol] |
| ColorTemperatureFlag [symbol] | This field, which is only present in the binary |
| | representation, signals the presence of device |
| | command attribute. A value of “1” means |
| | the attribute shall be used and “0” means the |
| | attribute shall not be used. [symbol] |
| InputDeviceColorGamutFlag [symbol] | This field, which is only present in the binary |
| | representation, signals the presence of device |
| | command attribute. A value of “1” means |
| | the attribute shall be used and “0” means the |
| | attribute shall not be used. [symbol] |
| IlluminanceOfSurroundFlag [symbol] | This field, which is only present in the binary |
| | representation, signals the presence of device |
| | command attribute. A value of “1” means |
| | the attribute shall be used and “0” means the |
| | attribute shall not be used. [symbol] |
| DeviceCommandBase [symbol] | Provides the topmost type of the base type |
| | hierarchy which each individual device |
| | command can inherit. [symbol] |
| ToneReproductionCurves [symbol] | This curve shows the characteristics (e.g., |
| | gamma curves for R, G and B channels) of the |
| | input display device. [symbol] |
| ConversionLUT [symbol] | A look-up table (matrix) converting an image |
| | between an image color space (e.g. RGB) and |
| | a standard connection space (e.g. CIE XYZ). [symbol] |
| ColorTemperature [symbol] | An element describing a white point setting |
| | (e.g., D65, D93) of the input display device. [symbol] |
| InputDeviceColorGamut [symbol] | An element describing an input display device |
| | color gamut, which is represented by |
| | chromaticity values of R, G, and B channels at |
| | maximum DAC values. [symbol] |
| IlluminanceOfSurround [symbol] | An element describing an illuminance level of |
| | viewing environment. The illuminance is |
| | represented by lux. [symbol] |

Table 155 shows descriptor components semantics of the tone reproduction curves type.

TABLE 155

| Names [symbol] | Description [symbol] |
|---|---|
| NumOfRecords [symbol] | This field, which is only present in the binary |
| | representation, specifies the number of record |
| | (DAC and RGB value) instances |
| | accommodated in the ToneReproductionCurves. [symbol] |
| DAC_Value [symbol] | An element describing discrete DAC values |
| | of input device. [symbol] |
| RGB_Value [symbol] | An element describing normalized gamma curve |
| | values with respect to DAC values. The order of |
| | describing the RGB_Value is R_{c}, G_{c}, B_{c}. [symbol] |

Table 156 shows descriptor components semantics of the conversion LUT type.

TABLE 156

| Names [symbol] | Description [symbol] |
|---|---|
| RGB2XYZ_LUT [symbol] | This look-up table (matrix) converts an image |
| | from RGB to CIE, XYZ. The size of the |
| | conversion matrix is 3 × 3 such as |
| | $[ \begin{matrix}{R}_{x} & {G}_{x} & {B}_{x} \\ {R}_{y} & {G}_{y} & {B}_{y} \\ {R}_{z} & {G}_{z} & {B}_{z}\end{matrix} ] .$ |
| | The way of describing the values in the |
| | binary representation is in the order of |
| | [Rₓ, Gₓ, Bₓ; R_{y}, G_{y}, B_{y}; R_{z}, G_{z}, B_{z}]. [symbol] |
| RGBScalar_Max [symbol] | An element describing maximum RGB scalar |
| | values for GOG transformation. The order of |
| | describing the RGBScalar_Max is |
| | Rₘₐₓ, Gₘₐₓ, Bₘₐₓ. [symbol] |
| Offset_Value [symbol] | An element describing offset values of input |
| | display device when the DAC is 0. The value |
| | is described in CIE XYZ form. The order of |
| | describing the Offset_Value is X, Y, Z. [symbol] |
| Gain_Offset_Gamma [symbol] | An element describing the gain, offset, gamma |
| | of RGB channels for GOG transformation. |
| | The size of the Gain_Offset_Gamma |
| | maxtrix is 3 × 3 such as |
| | $[ \begin{matrix}{Gain}_{r} & {Gain}_{g} & {Gain}_{b} \\ {Offset}_{r} & {Offset}_{g} & {Offset}_{b} \\ {Gamma}_{r} & {Gamma}_{g} & {Gamma}_{b}\end{matrix} ] .$ |
| | The way of describing the values in the binary |
| | representation is in the order of [Gainᵣ, Gain_{g}, |
| | Gain_{b}; Offsetᵣ, Offset_{g}, Offset_{b}; Gammaᵣ, |
| | Gamma_{g}, Gamma_{b}]. [symbol] |
| InverseLUT [symbol] | This look-up table (matrix) converts an image |
| | from CIE XYZ to RGB. [symbol] |
| | The size of the conversion matrix is 3 × 3 |
| | such as |
| | $[ \begin{matrix}{R}_{x}^{1} & {G}_{x}^{1} & {B}_{x}^{1} \\ {R}_{y}^{1} & {G}_{y}^{1} & {B}_{y}^{1} \\ {R}_{z}^{1} & {G}_{z}^{1} & {B}_{z}^{1}\end{matrix} ] .$ |
| | The way of describing the values of the binary |
| | representation is in the order of |
| | [Rₓ¹, Gₓ¹, Bₓ¹; R_{y}¹, G_{y}¹, B_{y}¹; R_{z}¹, G_{z}¹, B_{z}¹]. [symbol] |

Table 157 shows descriptor components semantics of the illuminant type.

TABLE 157

| Names [symbol] | Description [symbol] | | |
|---|---|---|---|
| ElementType [symbol] | This field, which is only present in the binary | | |
| | representation. | | |
| | describes which Illuminant scheme shall be used. [symbol] | | |
| | [symbol] | | |
| | In the binary description, the following mapping table | | |
| | is used. [symbol] | | |
| | Illuminant [symbol] | IlluminantType [symbol] | [symbol] |
| | 00 [symbol] | xy and Y value [symbol] | [symbol] |
| | 01 [symbol] | Correlated_CT [symbol] | [symbol] |

| | |
|---|---|
| XY_Value [symbol] | An element describing the chromaticity of the |
| | light source. |
| | The ChromaticityType is specified in ISO/IEC |
| | 21000-7. [symbol] |
| Y_Value [symbol] | An element describing the luminance of the light |
| | source between 0 and 100. [symbol] |
| Correlated_CT [symbol] | Indicates the correlated color temperature of the |
| | overall illumination. The value expression is |
| | obtained through quantizing the range [1667, |
| | 25000] into 28 bins in a non- |
| | uniform way as specified in ISO/IEC 15938-5. [symbol] |

Table 158 shows descriptor components semantics of the input device color gamut type.

TABLE 158

| Names [symbol] | Description [symbol] |
|---|---|
| typeLength [symbol] | This field which is only present in the binary represen- |
| | tation, specifies the length of each IDCG_Type |
| | instance in bytes. The value of this element is the size |
| | of the largest IDCG_Type instance, aligned to a byte |
| | boundary by bit stuffing using 0-7 ‘1’ bits. [symbol] |
| IDCG_Type [symbol] | An element describing the type of input device color |
| | gamut (e.g., NTSC, SMPTE). [symbol] |
| IDCG_Value [symbol] | An element describing the chromaticity values of RGB |
| | channels when the DAC values are maximum. |
| | The size of the IDCG_Value matrix is 3 × 2 such as |
| | $[ \begin{matrix}{x}_{r} & {y}_{r} \\ {x}_{g} & {y}_{g} \\ {x}_{b} & {y}_{b}\end{matrix} ] .$ |
| | The way of describing the values in the binary repre- |
| | sentation is in the order of [xᵣ, yᵣ, x_{g}, y_{g}, x_{b}, y_{b}] [symbol] |

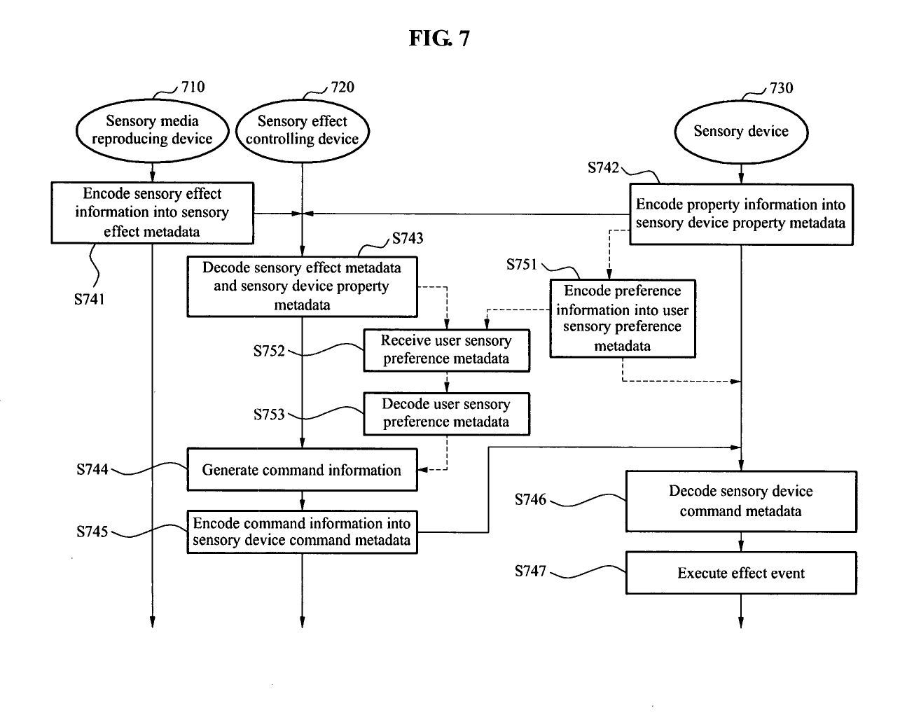

FIG. 7 illustrates a method of operating a sensory effect processing system according to embodiments.

Referring to FIG. 7, a sensory media reproducing device 710 may reproduce contents containing at least one sensory effect information.

In operation 741, the sensory media reproducing device 710 may encode the sensory effect information into SEM. In other words, the sensory media reproducing device 710 may generate the SEM by encoding the sensory effect information.

The sensory media reproducing device 710 may transmit the generated SEM to a sensory effect controlling device 720.

The sensory device 730 may encode capability information regarding capability of the sensory device 730 into SDCap metadata in operation 742. In other words, the sensory device 730 may generate the SDCap metadata by encoding the capability information.

In addition, the sensory device 730 may transmit the generated SDCap metadata to the sensory effect controlling device 720.

The sensory effect controlling device 720 may decode the SEM and the SDCap metadata in operation 743.

The sensory effect controlling device 720 may extract the sensory effect information by decoding the SEM. In addition, the sensory effect controlling device 720 may extract the capability information of the sensory device 730 by decoding the SDCap metadata.

The sensory effect controlling device 720 may generate command information for controlling the sensory device 730 based on the decoded SEM and the decoded SDCap metadata, in operation 744.

The sensory effect controlling device 720 may encode the generated command information into SDCmd metadata in operation 745. In other words, the sensory effect controlling device 720 may generate the SDCmd metadata by encoding the generated command information.

In addition, the sensory effect controlling device 720 may transmit the SDCmd metadata to the sensory device 730.

The sensory device 730 may receive the SDCmd metadata from the sensory effect controlling device 720 and decode the received SDCmd metadata in operation 746. That is, the sensory device 730 may extract the sensory effect information by decoding the SDCmd metadata.

Here, the sensory device 730 may execute an effect event corresponding to the sensory effect information in operation 747.

The sensory device 730 may extract the command information by decoding the SDCmd metadata. The sensory device 730 may execute the effect event corresponding to the sensory effect information based on the command information.

According to other embodiments, the sensory device 730 may encode preference information, that is, information on a user preference with respect to the sensory effect, into USP metadata in operation 751. In other words, the sensory device 730 may generate the USP metadata by encoding the preference information.

Also, the sensory device 730 may transmit the generated USP metadata to the sensory effect controlling device 720.

The sensory effect controlling device 720 may receive the SDCap metadata and the USP metadata from the sensory device 730 in operation 752.

Here, the sensory effect controlling device 720 may extract the preference information by decoding the USP metadata in operation 753.

Additionally, the sensory effect controlling device 720 may generate the command information based on the decoded SEM, the decoded SDCap metadata, and the decoded USP metadata. Depending on embodiments, the command information may include the sensory effect information.

A method of controlling the sensory effect according to embodiments may perform operations S743 and S745 by the sensory effect controlling device 720.

Also, the method of operating the sensory device may perform the operations S746 and S745 by the sensory device 730.

The methods according to the above-described embodiments may be recorded in non-transitory computer-readable media including program instructions to implement various operations embodied by a computer. The media may also include, alone or in combination with the program instructions, data files, data structures, and the like. The program instructions recorded on the media may be those specially designed and constructed for the purposes of the example embodiments, or they may be of the kind well-known and available to those having skill in the computer software arts. Examples of non-transitory computer-readable media include magnetic media such as hard disks, floppy disks, and magnetic tape; optical media such as CD ROM disks and DVDs; magneto-optical media such as optical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described example embodiments, or vice versa.

The computer-readable media may also be a distributed network, so that the program instructions are stored and executed in a distributed fashion. The program instructions may be executed by one or more processors or processing devices. The computer-readable media may also be embodied in at least one application specific integrated circuit (ASIC) or Field Programmable Gate Array (FPGA).

Although embodiments have been shown and described, it would be appreciated by those skilled in the art that changes may be made in these embodiments without departing from the principles and spirit of the disclosure, the scope of which is defined in the claims and their equivalents.

What is claimed is:

1. A device for controlling sensory effects, comprising:
a decoding unit to decode sensory effect metadata (SEM) and sensory device capability (SDCap) metadata using at least one processor;
a generation unit to generate command information which controls a sensory device based on the decoded SEM and the decoded SDCap metadata; and
an encoding unit to encode the command information into sensory device command (SDCmd) metadata.

2. The device of claim 1, further comprising a receiving unit to receive user sensory preference (USP) metadata from the sensory device,
wherein the decoding unit decodes the USP metadata, and
the generation unit generates the command information based on the decoded SEM, the decoded SDCap metadata, and the decoded user preference metadata.

3. The device of claim 1, wherein the encoding unit generates the SDCmd metadata by encoding the command information into extensible mark-up language (XML) metadata.

4. The device of claim 1, wherein the encoding unit generates the SDCmd metadata by encoding the command information into binary metadata.

5. The device of claim 1, wherein the encoding unit generates first metadata by encoding the command information into XML metadata, and generates the SDCmd metadata by encoding the first metadata into binary metadata.

6. A sensory device comprising:
a decoding unit to decode sensory device command (SDCmd) metadata containing at least one sensory effect information; and
a drive unit to execute an effect event corresponding to the at least one sensory effect information.

7. The sensory device of claim 6, wherein
the SDCmd metadata further comprises command information which controls execution of the effect event, and
the drive unit executes the effect event based on the command information.

8. The sensory device of claim 6, further comprising an encoding unit to encode capability information regarding capability of the sensory device into sensory device capability (SDCap) metadata.

9. The sensory device of claim 8, wherein the encoding unit encodes preference information which is information on a user preference with respect to the sensory effects, into user sensory preference (USP) metadata.

10. The sensory device of claim 9, further comprising an input unit to be input with the preference information.

11. The sensory device of claim 9, wherein the encoding unit generates the USP metadata by encoding the preference information into extensible mark-up language (XML) metadata.

12. The sensory device of claim 9, wherein the encoding unit generates the USP metadata by encoding the preference information into binary metadata.

13. The sensory device of claim 9, wherein the encoding unit generates second metadata by encoding the preference information into XML metadata, and generates the USP metadata by encoding the second metadata into binary metadata.

14. A method for controlling sensory effects, comprising:
decoding sensory effect metadata (SEM) and sensory device capability (SDCap) metadata using at least one processor;
generating command information which controls a sensory device based on the decoded SEM and the decoded SDCap metadata; and
encoding the command information into sensory device command (SDCmd) metadata.

15. A method for operating a sensory device, comprising:
decoding sensory device command (SDCmd) metadata containing at least one sensory effect information using at least one processor; and
executing an effect event corresponding to the at least one sensory effect information.

16. At least one non-transitory computer readable recording medium storing program instructions to that control at least one processor to implement the method of claim 14.

17. At least one non-transitory computer readable recording medium storing program instructions to that control at least one processor to implement the method of claim 15.

18. The device of claim 1, wherein the sensory device is one of a vibration joystick, a 4-dimensional (4D) theater seat, and virtual world goggles

19. The sensory device of claim 6, wherein the sensory device is one of a vibration joystick, a 4-dimensional (4D) theater seat, and virtual world goggles.
